(19) United States
(12) Patent Application Publication
(10) Pub. No.: US 2022/0102407 A1
(43) Pub. Date: Mar. 31, 2022

(54) SOLID-STATE IMAGING DEVICE AND ELECTRONIC APPARATUS

(71) Applicant: SONY SEMICONDUCTOR SOLUTIONS CORPORATION, Kanagawa (JP)

(72) Inventors: Ayaka IRISA, Kanagawa (JP); Yuichi SEKI, Kanagawa (JP); Yuji ISERI, Kanagawa (JP)

(21) Appl. No.: 17/419,176

(22) PCT Filed: Nov. 18, 2019
(86) PCT No.: PCT/JP2019/045157

§ 371 Date: Jun. 28, 2021

(30) Foreign Application Priority Data
Dec. 28, 2018 (JP) 2018-248678
Jul. 5, 2019 (JP) 2019-126168

(51) Int. Cl. H01L 27/146

(52) U.S. Cl. CPC H01L 27/14621; H01L 27/14627; H01L 27/14623

(57) ABSTRACT

To provide a solid-state imaging device that can achieve a higher image quality.

The solid-state imaging device includes a plurality of imaging pixels that is orderly arranged in accordance with a certain pattern.

The imaging pixels include: at least a semiconductor substrate in which a photoelectric conversion unit is formed; and a filter that transmits certain light and is formed on the light incidence face side of the semiconductor substrate. At least one of the plurality of imaging pixels is replaced with a ranging pixel having a filter that transmits the certain light, to form at least one ranging pixel. A partition wall is formed between the filter of the at least one ranging pixel and the filter adjacent to the filter of the at least one ranging pixel, and the partition wall contains a material that is almost the same as the material of the filter of the at least one imaging pixel replaced with the ranging pixel.

### TECHNICAL FIELD

The present technology relates to solid-state imaging devices and electronic apparatuses.

### BACKGROUND ART

In recent years, electronic cameras have become more and more popular, and the demand for solid-state imaging devices (image sensors) as the core components of electronic cameras is increasing. Furthermore, in terms of performance of solid-state imaging devices, technological development for achieving higher image quality and higher functionality is being continued. To achieve higher image quality with solid-state imaging devices, it is important to develop a technology for preventing the occurrence of crosstalk (color mixing) that causes image quality degradation.

For example, Patent Document 1 suggests a technique for preventing crosstalk in color filters and the resultant variation in sensitivity among the respective pixels.

### CITATION LIST

### Patent Document

### Patent Document 1: Japanese Patent Application Laid-Open No. 2018-133575

### SUMMARY OF THE INVENTION

### Problems to be Solved by the Invention

However, the technique suggested by Patent Document 1 may not be able to further increase the image quality with solid-state imaging devices.

Therefore, the present technology has been made in view of such circumstances, and the principal object thereof is to provide a solid-state imaging device capable of further increasing image quality, and an electronic apparatus equipped with the solid-state imaging device.

### Solutions to Problems

As a result of intensive studies conducted to achieve the above object, the present inventors have succeeded in further increasing image quality, and have completed the present technology.

Specifically, the present technology provides a solid-state imaging device that includes a plurality of imaging pixels that is orderly arranged in accordance with a certain pattern,

in which

the imaging pixels include: at least a semiconductor substrate in which a photoelectric conversion unit is formed; and a filter that transmits certain light and is formed on the light incidence face side of the semiconductor substrate,

at least one of the plurality of imaging pixels is replaced with a ranging pixel having a filter that transmits the certain light, to form at least one ranging pixel,

a partition wall is formed between the filter of the at least one ranging pixel and the filter adjacent to the filter of the at least one ranging pixel, and

the partition wall contains a material that is almost the same as the material of the filter of the at least one imaging pixel replaced with the ranging pixel.

In the solid-state imaging device according to the present technology, the partition wall may be formed in such a manner as to surround the at least one ranging pixel.

In the solid-state imaging device according to the present technology, the partition wall may be formed between the filter of the imaging pixel and the filter adjacent to the filter of the imaging pixel, in such a manner as to surround the imaging pixel.

In the solid-state imaging device according to the present technology, the width of the partition wall that is formed between the ranging pixel and the imaging pixel in such a manner as to surround the at least one ranging pixel may differs from or almost the same as the width of the partition wall that is formed between two of the imaging pixels in such a manner as to surround the imaging pixel.

In the solid-state imaging device according to the present technology, the partition wall portion may include a plurality of layers.

The partition wall may include a first organic film and a second organic film in this order from the light incident side.

In the solid-state imaging device according to the present technology, the first organic film may be formed with a light-transmitting resin film, and the light-transmitting resin film may be a resin film that transmits red light, blue light, green light, white light, cyan light, magenta light, or yellow light.

In the solid-state imaging device according to the present technology, the second organic film may be formed with a light-absorbing resin film, and the light-absorbing resin film may be a light-absorbing resin film that contains a carbon black pigment or a titanium black pigment.

The solid-state imaging device according to the present technology may include a light blocking film formed on the side opposite from the light incident side of the partition wall.

The light blocking film may be a metal film or an insulating film, and the light blocking film may include a first light blocking film and a second light blocking film in this order from the light incident side.

The second light blocking film may be formed to block the light to be received by the ranging pixel.

In the solid-state imaging device according to the present technology, the plurality of imaging pixels may include a pixel having a filter that transmits blue light, a pixel having a filter that transmits green light, and a pixel having a filter that transmits red light, and

the plurality of imaging pixels may be orderly arranged in accordance with the Bayer array.

In the solid-state imaging device according to the present technology, the pixel having the filter that transmits blue light may be replaced with the ranging pixel having the filter that transmits the certain light, to form the ranging pixel,

a partition wall may be formed between the filter of the ranging pixel and four of the filters that transmit green light and are adjacent to the filter of the ranging pixel, in such a manner as to surround the ranging pixel, and

the partition wall may contain a material that is almost the same as the material of the filter that transmits blue light.

In the solid-state imaging device according to the present technology, the pixel having the filter that transmits red light may be replaced with the ranging pixel having the filter that transmits the certain light, to form the ranging pixel,

a partition wall may be formed between the filter of the ranging pixel and four of the filters that transmit green light and are adjacent to the filter of the ranging pixel, in such a manner as to surround the ranging pixel, and

the partition wall may contain a material that is almost the same as the material of the filter that transmits red light.

In the solid-state imaging device according to the present technology, the pixel having the filter that transmits green light may be replaced with the ranging pixel having the filter that transmits the certain light, to form the ranging pixel,

a partition wall may be formed between the filter of the ranging pixel and two of the filters that transmit blue light and are adjacent to the filter of the ranging pixel, and between the filter of the ranging pixel and two of the filters that transmit red light and are adjacent to the filter of the ranging pixel, in such a manner as to surround the ranging pixel, and

the partition wall contains a material that is almost the same as the material of the filter that transmits green light.

In the solid-state imaging device according to the present technology, the filter of the ranging pixel may contain a material that transmits red light, blue light, green light, white light, cyan light, magenta light, or yellow light.

The present technology also provides a solid-state imaging device that includes a plurality of imaging pixels,

in which

the imaging pixels each include a photoelectric conversion unit formed in a semiconductor substrate, and a filter formed on a light incidence face side of the photoelectric conversion unit,

a ranging pixel is formed in at least one imaging pixel of the plurality of imaging pixels,

a partition wall is formed in at least part of a region between a filter of the ranging pixel and the filter of an imaging pixel adjacent to the ranging pixel, and

the partition wall contains a material forming the filter of one imaging pixel of the plurality of imaging pixels.

In the solid-state imaging device according to the present technology, the plurality of imaging pixels may include a first pixel, a second pixel, a third pixel, and a fourth pixel that are adjacent to one another in a first row, and a fifth pixel, a sixth pixel, a seventh pixel, and an eighth pixel that are adjacent to one another in a second row adjacent to the first row,

the first pixel may be adjacent to the fifth pixel,

the filters of the first pixel and the third pixel may include a filter that transmits light in a first wavelength band,

the filters of the second pixel, the fourth pixel, the fifth pixel, and the seventh pixel may include a filter that transmits light in a second wavelength band,

the filter of the eighth pixel may include a filter that transmits light in a third wavelength band,

the ranging pixel may be formed in the sixth pixel,

a partition wall may be formed at least in part of a region between the filter of the sixth pixel and the filter of a pixel adjacent to the sixth pixel, and

the partition wall may contain the material that forms the filter that transmits light in the third wavelength band.

In the solid-state imaging device according to the present technology,

the light in the first wavelength band may be red light, the light in the second wavelength band may be green light, and the light in the third wavelength band may be blue light.

In the solid-state imaging device according to the present technology,

the filter of the ranging pixel may include a different material from the partition wall or the filter of the imaging pixel adjacent to the ranging pixel.

In the solid-state imaging device according to the present technology,

the partition wall may be formed between the ranging pixel and the filter of the adjacent pixel, in such a manner as to surround at least part of the filter of the ranging pixel.

In the solid-state imaging device according to the present technology,

an on-chip lens may be provided on the light incidence face side of the filter.

In the solid-state imaging device according to the present technology,

the filter of the ranging pixel may contain one of the materials forming a color filter, a transparent film, and the on-chip lens.

The present technology also provides a solid-state imaging device that includes a plurality of imaging pixels that is orderly arranged in accordance with a certain pattern,

in which

the imaging pixels include: at least a semiconductor substrate in which a photoelectric conversion unit is formed; and a filter that transmits certain light and is formed on a light incidence face side of the semiconductor substrate,

at least one of the plurality of the imaging pixels is replaced with a ranging pixel having the filter that transmits the certain light, to form at least one ranging pixel,

a partition wall is formed between the filter of the at least one ranging pixel and the filter adjacent to the filter of the at least one ranging pixel, and

the partition wall contains a light-absorbing material.

The present technology further provides an electronic apparatus that includes a solid-state imaging device according to the present technology.

According to the present technology, a further increase in image quality can be achieved. Note that effects of the present technology are not limited to the effects described herein, and may include any of the effects described in the present disclosure.

### BRIEF DESCRIPTION OF DRAWINGS

FIG. 1 is a diagram showing an example configuration of a solid-state imaging device of a first embodiment to which the present technology is applied.

FIG. 2 is a diagram for explaining a method for manufacturing the solid-state imaging device of the first embodiment to which the present technology is applied.

FIG. 3 is a diagram for explaining the method for manufacturing the solid-state imaging device of the first embodiment to which the present technology is applied.

FIG. 4 is a diagram for explaining the method for manufacturing the solid-state imaging device of the first embodiment to which the present technology is applied.

FIG. 5 is a diagram for explaining the method for manufacturing the solid-state imaging device of the first embodiment to which the present technology is applied.

FIG. 6 is a diagram for explaining the method for manufacturing the solid-state imaging device of the first embodiment to which the present technology is applied.

FIG. 7 is a diagram for explaining the method for manufacturing the solid-state imaging device of the first embodiment to which the present technology is applied.

FIG. 8 is a diagram showing an example configuration of a solid-state imaging device of a second embodiment to which the present technology is applied.

FIG. 9 is a diagram for explaining a method for manufacturing the solid-state imaging device of the second embodiment to which the present technology is applied.

FIG. 10 is a diagram for explaining the method for manufacturing the solid-state imaging device of the second embodiment to which the present technology is applied.

FIG. 11 is a diagram for explaining the method for manufacturing the solid-state imaging device of the second embodiment to which the present technology is applied.

FIG. 12 is a diagram for explaining the method for manufacturing the solid-state imaging device of the second embodiment to which the present technology is applied.

FIG. 13 is a diagram for explaining the method for manufacturing the solid-state imaging device of the second embodiment to which the present technology is applied.

FIG. 14 is a diagram for explaining the method for manufacturing the solid-state imaging device of the second embodiment to which the present technology is applied.

FIG. 15 is a diagram showing an example configuration of a solid-state imaging device of a third embodiment to which the present technology is applied.

FIG. 16 is a diagram for explaining a method for manufacturing the solid-state imaging device of the third embodiment to which the present technology is applied.

FIG. 17 is a diagram for explaining the method for manufacturing the solid-state imaging device of the third embodiment to which the present technology is applied.

FIG. 18 is a diagram for explaining the method for manufacturing the solid-state imaging device of the third embodiment to which the present technology is applied.

FIG. 19 is a diagram for explaining the method for manufacturing the solid-state imaging device of the third embodiment to which the present technology is applied.

FIG. 20 is a diagram for explaining the method for manufacturing the solid-state imaging device of the third embodiment to which the present technology is applied.

FIG. 21 is a diagram showing an example configuration of a solid-state imaging device of a fourth embodiment to which the present technology is applied.

FIG. 22 is a diagram for explaining a method for manufacturing the solid-state imaging device of the fourth embodiment to which the present technology is applied.

FIG. 23 is a diagram for explaining the method for manufacturing the solid-state imaging device of the fourth embodiment to which the present technology is applied.

FIG. 24 is a diagram for explaining the method for manufacturing the solid-state imaging device of the fourth embodiment to which the present technology is applied.

FIG. 25 is a diagram for explaining the method for manufacturing the solid-state imaging device of the fourth embodiment to which the present technology is applied.

FIG. 26 is a diagram for explaining the method for manufacturing the solid-state imaging device of the fourth embodiment to which the present technology is applied.

FIG. 27 is a diagram showing an example configuration of a solid-state imaging device of a fifth embodiment to which the present technology is applied.

FIG. 28 is a diagram for explaining a method for manufacturing the solid-state imaging device of the fifth embodiment to which the present technology is applied.

FIG. 29 is a diagram for explaining the method for manufacturing the solid-state imaging device of the fifth embodiment to which the present technology is applied.

FIG. 30 is a diagram for explaining the method for manufacturing the solid-state imaging device of the fifth embodiment to which the present technology is applied.

FIG. 31 is a diagram for explaining the method for manufacturing the solid-state imaging device of the fifth embodiment to which the present technology is applied.

FIG. 32 is a diagram for explaining the method for manufacturing the solid-state imaging device of the fifth embodiment to which the present technology is applied.

FIG. 33 is a diagram showing an example configuration of a solid-state imaging device of a sixth embodiment to which the present technology is applied.

FIG. 34 is a diagram for explaining a method for manufacturing the solid-state imaging device of the sixth embodiment to which the present technology is applied.

FIG. 35 is a diagram for explaining the method for manufacturing the solid-state imaging device of the sixth embodiment to which the present technology is applied.

FIG. 36 is a diagram for explaining the method for manufacturing the solid-state imaging device of the sixth embodiment to which the present technology is applied.

FIG. 37 is a diagram for explaining the method for manufacturing the solid-state imaging device of the sixth embodiment to which the present technology is applied.

FIG. 38 is a diagram for explaining the method for manufacturing the solid-state imaging device of the sixth embodiment to which the present technology is applied.

FIG. 39 is a diagram for explaining the method for manufacturing the solid-state imaging device of the sixth embodiment to which the present technology is applied.

FIG. 40 is a diagram showing example configurations of solid-state imaging devices of seventh to ninth embodiments to which the present technology is applied.

FIG. 41 is a diagram showing an example configuration of a solid-state imaging device of a tenth embodiment to which the present technology is applied.

FIG. 42 is a diagram showing an example configuration of a solid-state imaging device of an eleventh embodiment to which the present technology is applied.

FIG. 43 is a diagram showing example configurations of solid-state imaging devices of the seventh to ninth embodiments (modifications) to which the present technology is applied.

FIG. 44 is a diagram for explaining a method for manufacturing a solid-state imaging device of the seventh embodiment to which the present technology is applied.

FIG. 45 is a diagram showing example configurations of solid-state imaging devices of the seventh embodiment (modifications) to which the present technology is applied.

FIG. 46 is a diagram showing an example configuration of a solid-state imaging device of the seventh embodiment (a modification) to which the present technology is applied.

FIG. 47 is a diagram showing an example configuration of a solid-state imaging device of the eighth embodiment (a modification) to which the present technology is applied.

FIG. 48 is a diagram showing an example configuration of a solid-state imaging device of the ninth embodiment (a modification) to which the present technology is applied.

FIG. 49 is a diagram showing an example configuration of a solid-state imaging device of the seventh embodiment (a modification) to which the present technology is applied.

FIG. 50 is a diagram showing an example configuration of a solid-state imaging device of the seventh embodiment (a modification) to which the present technology is applied.

FIG. 51 is a diagram showing an example configuration of a solid-state imaging device of the eighth embodiment (a modification) to which the present technology is applied.

FIG. 52 is a diagram showing an example configuration of a solid-state imaging device of the ninth embodiment (a modification) to which the present technology is applied.

FIG. 53 is a diagram showing an example configuration of a solid-state imaging device of the seventh embodiment (a modification) to which the present technology is applied.

FIG. 54 is a diagram showing an example configuration of a solid-state imaging device of the seventh embodiment (a modification) to which the present technology is applied.

FIG. 55 is a diagram for explaining a method for manufacturing solid-state imaging devices of the seventh and eighth embodiments to which the present technology is applied.

FIG. 56 is a graph showing resultant light leakage rate lowering effects.

FIG. 57 is a diagram showing outlines of example configurations of a stacked solid-state imaging device to which the present technology can be applied.

FIG. 58 is a cross-sectional view showing a first example configuration of a stacked solid-state imaging device 23020.

FIG. 59 is a cross-sectional view showing a second example configuration of the stacked solid-state imaging device 23020.

FIG. 60 is a cross-sectional view showing a third example configuration of the stacked solid-state imaging device 23020.

FIG. 61 is a cross-sectional view showing another example configuration of a stacked solid-state imaging device to which the present technology can be applied.

FIG. 62 is a cross-sectional view of a solid-state imaging device (image sensor) according to the present technology.

FIG. 63 is a plan view of the image sensor shown in FIG. 62.

FIG. 64A is a schematic plan view showing another component configuration in an image sensor according to the present technology.

FIG. 64B is a cross-sectional view showing principal components in a case where two ranging pixels (image-plane phase difference pixels) are disposed adjacent to each other.

FIG. 65 is a block diagram showing a peripheral circuit configuration of the light receiving unit shown in FIG. 62.

FIG. 66 is a cross-sectional view of a solid-state imaging device (image sensor) according to the present technology.

FIG. 67 is an example plan view of the image sensor shown in FIG. 66.

FIG. 68 is a plan view showing an example configuration of pixels to which the present technology is applied.

FIG. 69 is a circuit diagram showing an example configuration of pixels to which the present technology is applied.

FIG. 70 is a plan view showing an example configuration of pixels to which the present technology is applied.

FIG. 71 is a circuit diagram showing an example configuration of pixels to which the present technology is applied.

FIG. 72 is a conceptual diagram of a solid-state imaging device to which the present technology is applied.

FIG. 73 is a circuit diagram showing a specific configuration of circuits on the first semiconductor chip side and circuits on the second semiconductor chip side in the solid-state imaging device shown in FIG. 72.

FIG. 74 is a diagram showing examples of use of solid-state imaging devices of the first to sixth embodiments to which the present technology is applied.

FIG. 75 is a diagram for explaining the configurations of an imaging apparatus and an electronic apparatus that uses a solid-state imaging device to which the present technology is applied.

FIG. 76 is a functional block diagram showing an overall configuration according to Example Application 1 (an imaging apparatus (a digital still camera, a digital video camera, or the like)).

FIG. 77 is a functional block diagram showing an overall configuration according to Example Application 2 (a capsule-type endoscopic camera).

FIG. 78 is a functional block diagram showing an overall configuration according to another example of an endoscopic camera (an insertion-type endoscopic camera).

FIG. 79 is a functional block diagram showing an overall configuration according to Example Application 3 (a vision chip).

FIG. 80 is a functional block diagram showing an overall configuration according to Example Application 4 (a biological sensor).

FIG. 81 is a diagram schematically showing an example configuration of Example Application 5 (an endoscopic surgery system).

FIG. 82 is a block diagram showing an example of the functional configurations of a camera head and a CCU.

FIG. 83 is a block diagram schematically showing an example configuration of a vehicle control system in Example Application 6 (a mobile structure).

FIG. 84 is an explanatory diagram showing an example of installation positions of external information detectors and imaging units.

### MODES FOR CARRYING OUT THE INVENTION

The following is a description of preferred embodiments for carrying out the present technology. The embodiments described below are typical examples of embodiments of the present technology, and do not narrow the interpretation of the scope of the present technology. Note that “upper” means an upward direction or the upper side in the drawings, “lower” means a downward direction or the lower side in the drawings, “left” means a leftward direction or the left side in the drawings, and “right” means a rightward direction or the right side in the drawings, unless otherwise specified. Also, in the drawings, the same or equivalent components or members are denoted by the same reference numerals, and explanation of them will not be repeated.

Explanation will be made in the following order.

1. Outline of the present technology

2. First embodiment (Example 1 of a solid-state imaging device)

3. Second embodiment (Example 2 of a solid-state imaging device)

4. Third embodiment (Example 3 of a solid-state imaging device)

5. Fourth embodiment (Example 4 of a solid-state imaging device)

6. Fifth embodiment (Example 5 of a solid-state imaging device)

7. Sixth embodiment (Example 6 of a solid-state imaging device)

8. Seventh embodiment (Example 7 of a solid-state imaging device)

9. Eighth embodiment (Example 8 of a solid-state imaging device)

10. Ninth embodiment (Example 9 of a solid-state imaging device)

11. Tenth embodiment (Example 10 of a solid-state imaging device)

12. Eleventh embodiment (Example 11 of a solid-state imaging device)

13. Checking of light leakage rate lowering effects

14. Twelfth embodiment (examples of electronic apparatuses)

15. Examples of use of solid-state imaging devices to which the present technology is applied

16. Example applications of solid-state imaging devices to which the present technology is applied

### 1. Outline of the Present Technology

First, the outline of the present technology is described.

Focusing in a digital camera is performed with a dedicated chip independent of the solid-state imaging device that actually captures images. Therefore, the number of components in a module increases. Further, focusing is performed at a different place from the place at which focusing is actually desired. Therefore, a distance error is likely to occur.

To solve these problems, devices equipped with ranging pixels (image-plane phase difference pixels, for example) have recently become mainstream. Currently, image plane phase difference auto focus (phase difference AF) is used as a ranging method. A pixel (a phase difference pixel) for detecting image-plane phase differences is disposed in a chip of a solid-state imaging element.

Different pixels on right and left are then half blocked from light, and correlational calculation of a phase difference is performed on the basis of the sensitivities obtained from the respective pixels. In this manner, the distance to the object is determined. Therefore, if light leaks from adjacent pixels into the phase difference pixel, the leakage light turns into noise, and affects detection of image-plane phase differences. There also are cases where leakage from the phase difference pixel into the adjacent pixels may lead to deterioration of image quality. Since an image-plane phase difference pixel shields pixels from light, device sensitivity becomes lower. To compensate for this, a filter having a high optical transmittance is often used as an image-plane phase difference pixel. Therefore, light leakage into the pixels adjacent to an image-plane phase difference pixel increases, and a device sensitivity difference occurs between the pixels adjacent to the image-plane phase difference pixel and the pixels (non-adjacent pixels) distant from the phase difference pixel, which might result in deterioration of image quality.

To counter this, techniques for preventing unnecessary light from entering photodiodes by providing a light blocking portion between pixels have been developed.

However, in a solid-state imaging element including ranging pixels, the above techniques might cause a difference between color mixing from a ranging pixel into the adjacent pixels and color mixing from a non-ranging pixel into the adjacent pixels, resulting in deterioration of image quality. Furthermore, imaging characteristics might be degraded by color mixing caused by stray light entering from the invalid regions of microlenses.

The present technology has been developed in view of the above circumstances. The present technology relates to a solid-state imaging device that includes a plurality of imaging pixels that is orderly arranged in accordance with a certain pattern. The imaging pixels include: at least a semiconductor substrate in which a photoelectric conversion unit is formed; and a filter that transmits certain light and is formed on the light incidence face side of the semiconductor substrate. At least one of the plurality of imaging pixels is replaced with a ranging pixel having a filter that transmits certain light, to form at least one ranging pixel. A partition wall is formed between the filter of the at least one ranging pixel and the filter adjacent to the filter of the at least one ranging pixel, in such a manner as to surround the at least one ranging pixel. The partition wall contains a material that is almost the same as the material of the filter of the at least one imaging pixel. In the present technology, the plurality of imaging pixels orderly arranged in accordance with a certain pattern may be a plurality of pixels orderly arranged in accordance with the Bayer array, a plurality of pixels orderly arranged in accordance with the knight's code array, a plurality of pixels orderly arranged in a checkered pattern, a plurality of pixels orderly arranged in a striped array, or the like, for example. The plurality of imaging pixels may be formed with pixels capable of receiving light having any appropriate wavelength band. For example, the plurality of imaging pixels may include any appropriate combination of the following pixels: a W pixel having a transparent filter capable of transmitting a wide wavelength band, a B pixel having a blue filter capable of transmitting blue light, a G pixel having a green filter capable of transmitting green light, an R pixel having a red filter capable of transmitting red light, a C pixel having a cyan filter capable of transmitting cyan light, an M pixel having a magenta filter capable of transmitting magenta light, a Y pixel having a yellow filter capable of transmitting yellow light, an IR pixel having a filter capable of transmitting IR light, an UV pixel having a filter capable of transmitting UV, and the like.

According to the present technology, an appropriate partition wall is formed between a ranging pixel and an adjacent pixel, so that color mixing between the pixels can be prevented, and the difference between color mixing from a ranging pixel and color mixing from a regular pixel (an imaging pixel) can be reduced. It is also possible to block stray light entering from the invalid regions of microlenses, and improve imaging characteristics. Further, it is possible to improve the characteristics of flare and unevenness by eliminating color mixing between the pixels, and form the partition wall by lithography at the same time as the formation of the pixels without an increase in cost. Thus, a decrease in device sensitivity can be made smaller than that with a light blocking wall formed with a metal film.

Next, an example of the overall configuration of a solid-state imaging device to which the present technology can be applied is described.

<First Example Configuration>

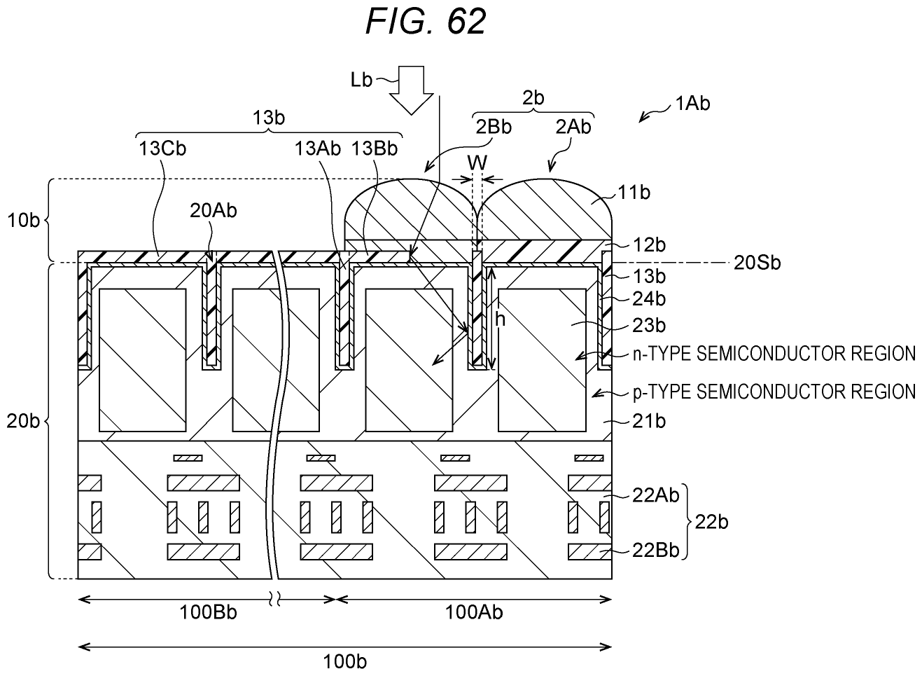

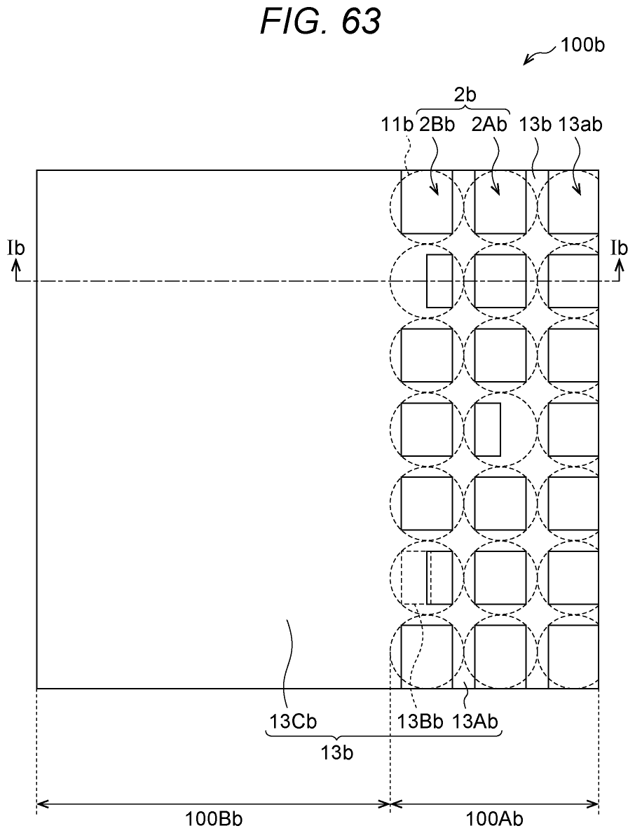

FIG. 62 shows a cross-sectional configuration of an image sensor (an image sensor 1Ab) according to a first example configuration to which the present technology can be applied. The image sensor 1Ab is a back-illuminated (back-light-receiving) solid-state imaging element (a CCD or a CMOS), for example, and a plurality of pixels 2b is two-dimensionally arranged on a substrate 21b as shown in FIG. 63. Note that FIG. 62 shows a cross-sectional configuration taken along the Ib-Ib line shown in FIG. 63. A pixel 2b is formed with an imaging pixel 2Ab (a 1-1st pixel) and an image-plane phase difference imaging pixel 2Bb (a 1-2nd pixel). In the first example configuration, a groove 20Ab is formed in each of the portions between the pixels 2b, which include the portion between an imaging pixel 2Ab and an image-plane phase difference imaging pixel 2Bb that are adjacent to each other, the portion between an imaging pixel 2Ab and an imaging pixel 2Ab that are adjacent to each other, and the portion between an image-plane phase difference imaging pixel 2Bb and an image-plane phase difference imaging pixel 2Bb that are adjacent to each other. A light blocking film 13Ab continuing to a light blocking film 13Bb for pupil division in an image-plane phase difference imaging pixel 2Bb is buried in the groove 20Ab between an adjacent imaging pixel 2Ab and the image-plane phase difference imaging pixel 2Bb.

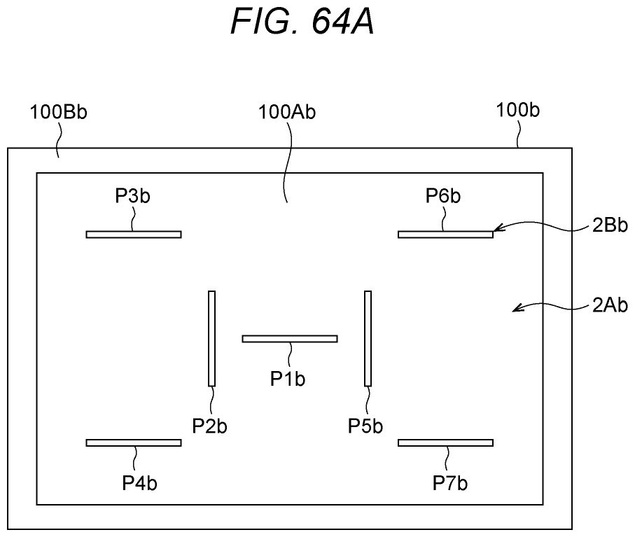

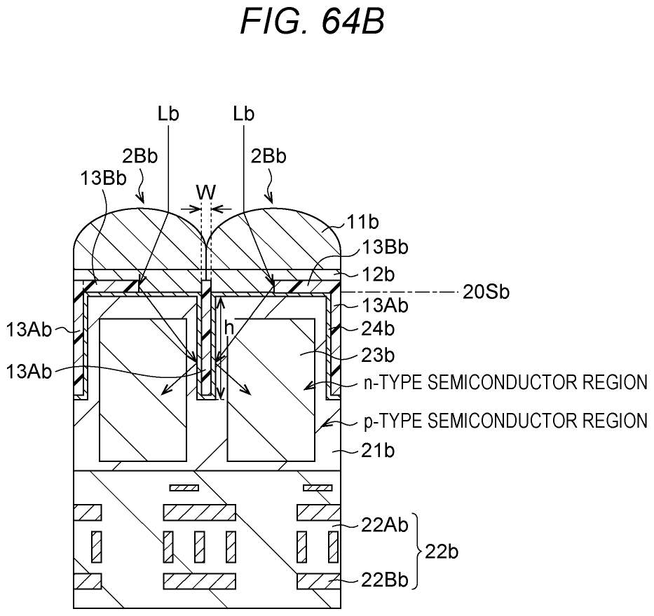

An imaging pixel 2Ab and an image-plane phase difference imaging pixel 2Bb each include a light receiving unit 20b including a photoelectric conversion element (a photodiode 23b), and a light collecting unit 10b that collects incident light toward the light receiving unit 20b. In the imaging pixel 2Ab, the photodiode 23b photoelectrically converts an object image formed by an imaging lens, to generate a signal for image generation. The image-plane phase difference imaging pixel 2Bb divides the pupil region of the imaging lens, and photoelectrically converts the object image supplied from the divided pupil region, to generate a signal for phase difference detection. The image-plane phase difference imaging pixels 2Bb are discretely disposed between the imaging pixels 2Ab as shown in FIG. 63. Note that the image-plane phase difference imaging pixels 2Bb are not necessarily disposed independently of one another as shown in FIG. 63, but may be disposed in parallel lines like P1 to P7 in a pixel unit 200 as shown in FIG. 64A, for example. Further, at a time of image-plane phase difference detection, signals obtained from a pair (two) of image-plane phase difference imaging pixels 2Bb are used. For example, as shown in FIG. 64B, two image-plane phase difference imaging pixels 2Bb are disposed adjacent to each other, and a light blocking film 13Ab is buried between these image-plane phase difference imaging pixels 2Bb. With this arrangement, deterioration of phase difference detection accuracy due to reflected light can be reduced. Note that the configuration shown in FIG. 64B corresponds to a specific example case where both the “1-1st pixel” and the “1-2nd pixel” are image-plane phase difference pixels in the present disclosure.

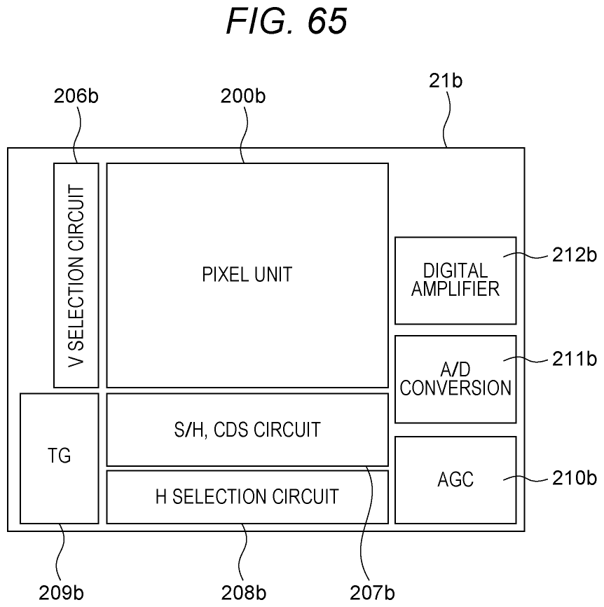

As described above, the respective pixels 2b are arranged two-dimensionally, to form a pixel unit 100b (see FIG. 65) on the Si substrate 21b. In this pixel unit 100b, an effective pixel region 100Ab formed with the imaging pixels 2Ab and the image-plane phase difference imaging pixels 2Bb, and an optical black (OPB) region 100Bb formed so as to surround the effective pixel region 100Ab are provided. The OPB region 100Bb is for outputting optical black that serves as the reference for black level. The OPB region 100Bb does not have any condensing members such as an on-chip lens 11b or a color filter formed therein, but has only the light receiving unit 20b such as the photodiodes 23b formed therein. Further, a light blocking film 13Cb for defining black level is provided on the light receiving unit 20b in the OPB region 100Bb.

In the first example configuration, a groove 20Ab is provided between each two pixels 2b on the light incident side of the light receiving unit 20b, as described above. That is, the grooves 20Ab are formed in a light receiving surface 20Sb, and the grooves 20Ab physically divide part of the light receiving unit 20b of each pixel 2b. The light blocking film 13Ab is buried in the grooves 20Ab, and this light blocking film 13Ab continues to the light blocking film 13Bb for pupil division of the image-plane phase difference imaging pixels 2Bb. The light blocking films 13Ab and 13Bb also continue to the light blocking film 13Cb provided in the OPB region 100Bb described above. Specifically, these light blocking films 13Ab, 13Bb, and 13Cb form a pattern in the pixel unit 100b as shown in FIG. 63.

The image sensor 1Ab may have an inner lens provided between the light receiving unit 20b of an image-plane phase difference imaging pixel 2Bb and the color filter 12b of the light collecting unit 10b.

The respective members constituting each pixel 2b are described below.

(Light Collecting Unit 10b)

The light collecting unit 10b is provided on the light receiving surface 20Sb of the light receiving unit 20b. The light collecting unit 10b has on-chip lenses 11b as optical functional layers arranged to face the light receiving unit 20b of the respective pixels 2b on the light incident side, and has color filters 12b provided between the on-chip lenses 11b and the light receiving unit 20b.

An on-chip lens 11b has a function of collecting light toward the light receiving unit 20b (specifically, the photodiode 23b of the light receiving unit 20b). The lens diameter of the on-chip lens 11b is set to a value corresponding to the size of the pixel 2b, and is not smaller than 0.9 μm and not greater than 3 μm, for example. Further, the refractive index of the on-chip lens 11b is 1.1 to 1.4, for example. The lens material may be a silicon oxide film (SiO₂) or the like, for example.

In the first example configuration, the respective on-chip lenses 11b provided on the imaging pixels 2Ab and the image-plane phase difference imaging pixels 2Bb have the same shape. Here, the “same” means those manufactured by using the same material and through the same process, but does not exclude variations due to various conditions at the time of manufacture.

A color filter 12b is a red (R) filter, a green (G) filter, a blue (B) filter, or a white filter (W), for example, and is provided for each pixel 2b, for example. These color filters 12b are arranged in a regular color array (the Bayer array, for example). As such color filters 12b are provided, the image sensor 1 can obtain light reception data of the colors corresponding to the color array. Note that the color of the color filter 12b in an image-plane phase difference imaging pixel 2Bb is not limited to any particular one, but it is preferable to use a green (G) filter or a white (W) filter so that an autofocus (AF) function can be used even in a dark place with a small amount of light. Further, as a white (W) filter is used, more accurate phase difference detection information can be obtained. However, in a case where a green (G) filter or a white (W) filter is provided for an image-plane phase difference imaging pixel 2Bb, the photodiode 23b of the image-plane phase difference imaging pixel 2Bb is easily saturated in a bright place with a large amount of light. In this case, the overflow barrier of the light receiving unit 20b may be closed.

(Light Receiving Unit 20b)

The light receiving unit 20b includes the silicon (Si) substrate 21b in which the photodiodes 23b are buried, a wiring layer 22b provided on the front surface of the Si substrate 21b (on the side opposite from the light receiving surface 20Sb), and a fixed charge film 24b provided on the back surface of the Si substrate 21b (or on the light receiving surface 20Sb). Further, the grooves 20Ab are provided between the respective pixels 2b on the side of the light receiving surface 20Sb of the light receiving unit 20b, as described above. The width (W) of the grooves 20Ab is only required to be such a width as to reduce crosstalk, and is not smaller than 20 nm and not greater than 5000 nm, for example. The depth (height (h)) is only required to be such a depth as to reduce crosstalk, and is not smaller than 0.3 μm and not greater than 10 μm, for example. Note that transistors such as transfer transistors, reset transistors, and amplification transistors, and various wiring lines are provided in the wiring layer 22b.

The photodiodes 23b are n-type semiconductor regions formed in the thickness direction of the Si substrate 21b, for example, and serve as p-n junction photodiodes with a p-type semiconductor region provided near the front surface and the back surface of the Si substrate 21b. In the first example configuration, the n-type semiconductor regions in which the photodiodes 23b are formed are defined as photoelectric conversion regions R. Note that the p-type semiconductor region facing the front surface and the back surface of the Si substrate 21b reduces dark current, and transfers the generated electric charges (electrons) toward the front surface side. Thus, the p-type semiconductor region also serves as a hole storage region. As a result, noise can be reduced, and electric charges can be accumulated in a portion close to the front surface. Thus, smooth transfer becomes possible. In the Si substrate 21b, p-type semiconductor regions are also formed between the respective pixels 2b.

To secure electric charges in the interface between the light collecting unit 10b and the light receiving unit 20b, the fixed charge film 24b is provided continuously between the light collecting unit 10b (specifically, the color filters 12b) and the light receiving surface 20Sb of the Si substrate 21b, and from the sidewalls to the bottom surfaces of the grooves 20Ab provided between the respective pixels 2b. With this arrangement, it is possible to reduce physical damage at the time of the formation of the grooves 20Ab, and pinning detachment to be caused by impurity activation due to ion irradiation. The material of the fixed charge film 24b is preferably a high-dielectric material having a large amount of fixed charge. Specific examples of such materials include hafnium oxide (HfO₂), aluminum oxide (Al₂O₃), tantalum oxide (Ta₂O₅), zirconium oxide. (ZrO₂), titanium oxide (TiO₂), magnesium oxide (MgO₂), lanthanum oxide (La₂O₃), praseodymium oxide (Pr₂O₃), cerium oxide (CeO₂), neodymium oxide (Nd₂O₃), promethium oxide (Pm₂O₃), samarium oxide (Sm₂O₃), europium oxide (Eu₂O₃), gadolinium oxide (Gd₂O₃), terbium oxide (Tb₂O₃), dysprosium oxide (Dy₂O₃), holmium oxide (Ho₂O₃), erbium oxide (Er₂O₃), thulium oxide (Tm₂O₃), ytterbium oxide (Yb₂O₃), lutetium oxide (Lu₂O₃), and yttrium oxide (Y₂O₃).

Alternatively, hafnium nitride, aluminum nitride, hafnium oxynitride, or aluminum oxynitride may be used. The thickness of such a fixed charge film 24b is not smaller than 1 nm and not greater than 200 nm, for example.

In the first example configuration, light blocking films 13b are provided between the light collecting unit 10b and the light receiving unit 20b as described above.

The light blocking films 13b are formed with the light blocking films 13Ab buried in the grooves 20Ab formed between the pixels 2b, the light blocking films 13Bb provided as light blocking films for pupil division in the image-plane phase difference imaging pixels 2Bb, and the light blocking film 13Cb formed on the entire surface of the OPB region. The light blocking film 13Ab reduces color mixing due to crosstalk of oblique incident light between the adjacent pixels, and is disposed in a grid-like form, for example, so as to surround each pixel 2b in an effective pixel region 200A, as shown in FIG. 63. In other words, the light blocking films 13b has a structure in which openings 13a are formed in the optical paths of the respective on-chip lenses 11b. Note that the opening 13a in each image-plane phase difference imaging pixels 2Bb is provided at a position biased (eccentrically) toward one side due to the light blocking films 13Bb provided in part of the light receiving region R for pupil division. In the first example configuration, the light blocking films 13b (13Ab, 13Bb, and 13Cb) is formed by the same process, and are formed continuously from one another. The light blocking films 13b include tungsten (W), aluminum (Al), or an alloy of Al and copper (Cu), for example, and the thickness thereof is not smaller than 20 nm and not greater than 5000 nm, for example. Note that the light blocking film 13Bb and the light blocking film 13Cb formed on the light receiving surface 20Sb do not necessarily have the same film thickness, but each of the light blocking films can be designed to have any appropriate thickness.

FIG. 65 is a functional block diagram showing the peripheral circuit configuration of the pixel unit 100b of the light receiving unit 20b. The light receiving unit 20b includes a vertical (V) selection circuit 206, sample/hold (S/H) correlated double sampling (CDS) circuit 207, a horizontal (H) selection circuit 208, a timing generator (TG) 209, an automatic gain control (AGC) circuit 210, an A/D conversion circuit 211, and a digital amplifier 212. These components are mounted on the same Si substrate (chip) 21.

Such an image sensor 1Ab can be manufactured in the manner described below, for example.

(Manufacturing Method)

First, a p-type semiconductor region and an n-type semiconductor region are formed in the Si substrate 21b, and the photodiodes 23b corresponding to the respective pixels 2b are formed. The wiring layer 22b having a multilayer wiring structure is then formed on the surface (front surface) of the Si substrate 21b on the opposite side from the light receiving surface 20Sb. Next, the grooves 20Ab are formed at predetermined positions in the light receiving surface 20Sb (the back surface) of the Si substrate 21b, or specifically, in the P-type semiconductor region located between the respective pixels 2b, by dry etching, for example. On the light receiving surface 20Sb of the Si substrate 21b, and from the wall surfaces to the bottom surfaces of the grooves 20Ab, a 50-nm HfO₂ film is then formed by a sputtering method, a CVD method, or an atomic layer deposition (ALD) method, for example, and thus, the fixed charge film 24b is formed. In a case where the HfO₂ film is formed by the ALD method, a 1-nm Sift film that reduces the interface state can be formed at the same time, for example, which is preferable.

W films, for example, are then formed as the light blocking films 13b in part of the light receiving region R of each image-plane phase difference imaging pixel 2Bb and in the OPB region 100Bb by a sputtering method or a CVD method, and are also buried in the grooves 20Ab. Next, patterning is performed by photolithography or the like, to form the light blocking films 13b. The color filters 12b and the on-chip lenses 11b in the Bayer array, for example, are then sequentially formed on the light receiving unit 20b and the light blocking films 13b in the effective pixel region 100Ab. In this manner, the image sensor 1Ab can be obtained.

(Functions and Effects)

In the back-illuminated image sensor 1Ab as in the first example configuration, the thickness of the portion extending from the exit surfaces of the on-chip lenses 11b on the light incident side (the light collecting unit 10b) to the light receiving unit 20b is preferably thin (small in height) so as to reduce the occurrence of color mixing between the pixels adjacent to one another. Furthermore, while the most preferable pixel characteristics can be obtained by aligning the focusing points of incident light with the photodiodes 23b in the imaging pixels 2Ab, the most preferable AF characteristics can be obtained by aligning the focusing points of incident light with the light blocking film 13Bb for pupil division in the image-plane phase difference imaging pixels 2Bb.

Therefore, to collect incident light at optimum positions in the imaging pixels 2Ab and the image-plane phase difference imaging pixels 2Bb, the curvature of the on-chip lenses 11b is changed as described above, or a step is provided on the Si substrate 21b so as to make the height of the light receiving surface 20Sb in the image-plane phase difference imaging pixels 2Bb smaller than the height of the imaging pixels 2Ab, for example. However, it is difficult to manufacture the components such as the on-chip lenses 11b and the light receiving surface 20Sb, which are the Si substrate 21b, separately for each pixel. In recent years, pixels have become smaller in imaging devices required to have higher sensitivity and smaller sizes. Therefore, it is even more difficult to manufacture the members separately for each pixel.

Further, in a case where the light receiving surface 20Sb is made to have different heights between the imaging pixels 2Ab and the image-plane phase difference imaging pixels 2Bb, crosstalk occurs due to oblique incident light between the pixels 2b. Specifically, the light transmitted through the on-chip lenses 11b of the imaging pixels 2Ab enters the light receiving surface 20Sb of the image-plane phase difference imaging pixels 2Bb formed a step lower than that of the imaging pixels 2Ab. As a result, color mixing occurs in the light collecting unit. Also, light transmitted through the image-plane phase difference imaging pixels 2Bb enters the photodiodes 23b of the imaging pixels 2Ab via the wall surfaces of the steps provided between the pixels. As a result, color mixing occurs in the bulk (photodiodes 23b). Further, there is a possibility that phase difference detection accuracy (autofocus accuracy) will drop due to light incidence (oblique incidence) from the adjacent pixels.

In the image sensor 1Ab of the first example configuration, on the other hand, the grooves 20Ab are formed in the Si substrate 21b between the pixels 2b, the light blocking film 13Ab is buried in the grooves 20Ab, and further, this light blocking film 13Ab continues to the light blocking film 13Bb for pupil division provided in the image-plane phase difference imaging pixels 2Bb. With this arrangement, oblique incident light from the adjacent pixels is blocked by the light blocking film 13Ab buried in the grooves 20Ab, and incident light in the image-plane phase difference imaging pixels 2Bb can be collected at the positions of the light blocking film 13Bb for pupil division.

As described above, in the first example configuration, the grooves 20Ab are formed in the light receiving unit 20b between the pixels 2b to bury the light blocking film 13Ab, and this light blocking film 13Ab is designed to continue to the light blocking film 13Bb for pupil division provided in the image-plane phase difference imaging pixels 2Bb. With this arrangement, oblique incident light from the adjacent pixels is blocked by the light blocking film 13Ab buried in the grooves 20Ab, and the focusing points of incident light in the image-plane phase difference imaging pixels 2Bb are set at the positions of the light blocking film 13Bb for pupil division. Thus, signals for high-accuracy phase difference detection can be generated in the image-plane phase difference imaging pixels 2Bb, and the AF characteristics of the image-plane phase difference imaging pixels 2Bb can be improved. Furthermore, color mixing due to crosstalk of oblique incident light between adjacent pixels is reduced, and the pixel characteristics of the imaging pixels 2Ab as well as the image-plane phase difference imaging pixels 2Bb can be improved. That is, an imaging device that exhibits excellent characteristics in both the imaging pixels 2Ab and the image-plane phase difference imaging pixels 2Bb can be obtained with a simple configuration.

Also, as the p-type semiconductor region is provided in the light receiving surface 20Sb of the Si substrate 21b, generation of dark current can be reduced. Further, as the fixed charge film 24b that is continuous on the light receiving surface 20Sb and from the wall surfaces to the bottom surfaces of the grooves 20Ab is provided, generation of dark current can be further reduced. That is, noise in the image sensor 1Ab can be reduced, and highly accurate signals can be obtained from the imaging pixels 2Ab and the image-plane phase difference imaging pixels 2Bb.

Further, as the light blocking film 13Cb provided in the OPB region 100Bb is formed in the same process as that for the light blocking film 13Ab and the light blocking film 13Bb, the manufacturing process can be simplified.

In the description below, a second example configuration is explained. Components similar to those in the first example configuration described above are denoted by the same reference numerals as those used in the first example configuration, and explanation of them is not made herein.

<Second Example Configuration>

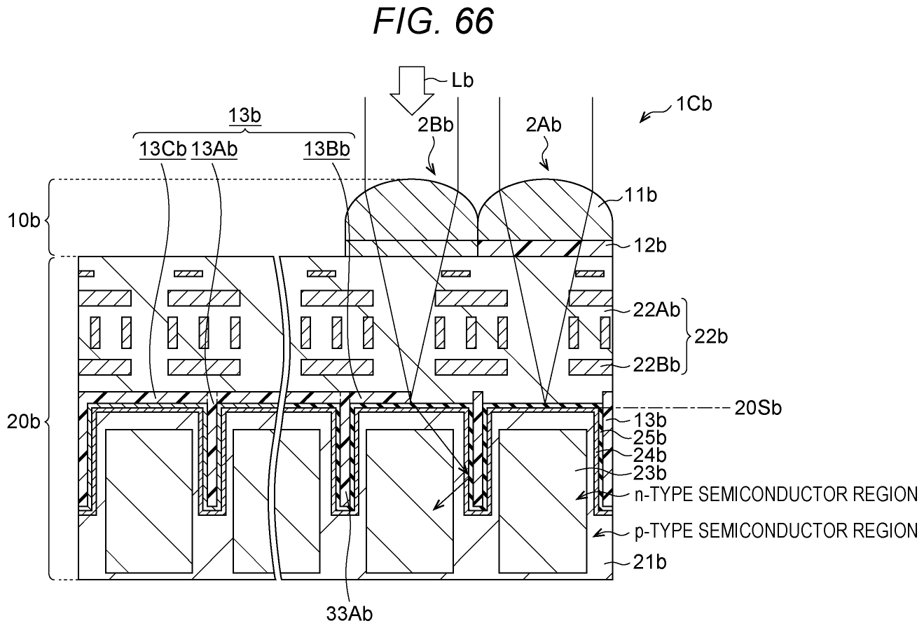

FIG. 66 shows a cross-sectional configuration of an image sensor (an image sensor 1Cb) according to the second example configuration to which the present technology can be applied. This image sensor 1Cb is a front-illuminated (front light receiving) solid-state imaging element, for example, and a plurality of pixels 2b is two-dimensionally arranged therein. A pixel 2b is formed with an imaging pixel 2Ab and an image-plane phase difference imaging pixel 2Bb. Grooves 20Ab are formed between the respective pixels 2b as in the first example configuration described above, and a pupil-division light blocking film (a light blocking film 13Ab) that continues to the light blocking film (the light blocking film 13Bb) in the image-plane phase difference imaging pixels 2Bb is buried in the grooves 20Ab. However, since the image sensor 1Cb in this modification is of a front-illuminated type, a wiring layer 22b is provided between the light collecting unit 10b and the Si substrate 21b forming the light receiving unit 20b, and light blocking films 13b (13Ab, 13Bb, and 13Cb) are provided between the Si substrate 21b of the light receiving unit 20b and the wiring layer 22b. Note that the light receiving surface 20Sb in the front-illuminated image sensor 1Cb (and image sensors 1D and 1E described later) as in the second example configuration is the illuminated surface of the Si substrate 21b.

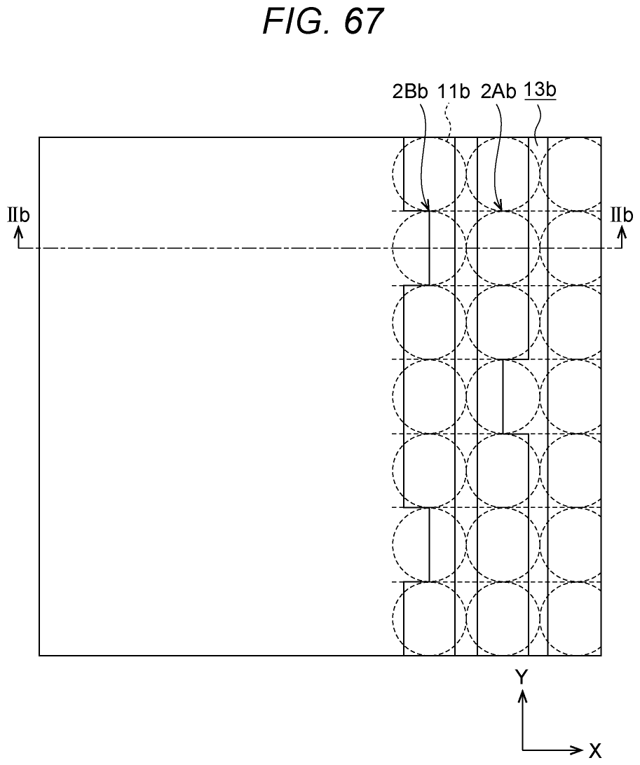

As described above, in the second example configuration, the wiring layer 22b, which is provided on the surface of the Si substrate 21 on the opposite side from the surface on which the light collecting unit 10b is provided in the first example configuration, is provided between the light collecting unit 10b and the Si substrate 21. Therefore, the grooves 20Ab provided between the pixels 2b may be formed in a grid-like pattern so as to surround the respective pixels 2b separately from one another as in the first example configuration, but may be provided only on either the X-axis or the Y-axis (in this example, the Y-axis direction), as shown in FIG. 67, for example. With this arrangement, electric charges can be smoothly transferred from the photodiodes 23b to transistors (transfer transistors, for example) provided between the respective pixels 2b in the Si substrate 21.

The image sensor 1Cb is formed with the light collecting unit 10b including on-chip lenses 11b and color filters 12b, and the light receiving unit 20b including the Si substrate 21 in which the photodiodes 23b are buried, the wiring layer 22b, and the fixed charge film 24b. In the second example configuration, an insulating film 25b is formed so as to cover the fixed charge film 24b, and the light blocking films 13Ab, 13Bb, and 13Cb are formed on the insulating film 25b. The material that forms the insulating film 25b may be a silicon oxide film (SiO), a silicon nitride film (SiN), a silicon oxynitride film (SiON), or the like, and the thickness thereof is not smaller than 1 nm and not greater than 200 nm, for example.

The wiring layer 22b is provided between the light collecting unit 10b and the Si substrate 21b, and has a multilayer wiring structure formed with two layers, or three or more layers of metal films 22Bb, for example, with an interlayer insulating film 22Ab being interposed in between. The metal films 22Bb are metal films for transistors, various kinds of wiring lines, or peripheral circuits. In a general front-illuminated image sensor, the metal films are provided between the respective pixels so that the aperture ratio of the pixels is secured, and light beams emitted from an optical functional layer such as on-chip lenses are not blocked.

An inorganic material, for example, is used as the interlayer insulating film 22Ab. Specifically, the interlayer insulating film 22Ab may be a silicon oxide film (SiO), a silicon nitride film (SiN), a silicon oxynitride film (SiON), a hafnium oxide film (HfO), an aluminum oxide film (AlO), an aluminum nitride film (AlN), a tantalum oxide film (TaO), a zirconium oxide film (ZrO), a hafnium oxynitride film, a hafnium silicon oxynitride film, an aluminum oxynitride film, a tantalum oxynitride film, a zirconium oxynitride film, or the like, for example. The thickness of the interlayer insulating film 22Ab is not smaller than 0.1 μm and not greater than 5 μm, for example.

The metal films 22Bb are electrodes forming the above described transistors for the respective pixels 2b, for example, and the material of the metal films 22Bb may be a single metal element such as aluminum (Al), chromium (Cr), gold (Au), platinum (Pt), nickel (Ni), copper (Cu), tungsten (W), or silver (Ag), or an alloy of any combination of these metal elements. Note that, as described above, the metal films 22Bb are normally designed to have a suitable size between the respective pixels 2b so that the aperture of the pixels 2b is secured, and light emitted from an optical functional layer such as the on-chip lenses 11b is not blocked.

Such an image sensor 1Cb is manufactured in the manner described below, for example. First, a p-type semiconductor region and an n-type semiconductor region are formed in the Si substrate 21b, and the photodiodes 23b are formed, as in the first example configuration. The grooves 20Ab are then formed at predetermined positions in the light receiving surface 20Sb (the front surface) of the Si substrate 21b, or specifically, in the P-type semiconductor region located between the respective pixels 2b, by dry etching, for example. An HfO₂ film having a thickness of 50 nm, for example, is then formed in the portions from the wall surfaces to the bottom surfaces of the grooves 20Ab of the Si substrate 21b by a sputtering method, for example.

Thus, the fixed charge film 24b is formed.

Next, after the fixed charge film 24b is formed on the light receiving surface 20Sb by a CVD method or an ALD method, for example, the insulating film 25b including SiO₂, for example, is formed by a CVD method, for example. A W film is then formed as the light blocking films 13 on the insulating film 25b by a sputtering method, for example, and is buried in the grooves 20Ab. After that, patterning is performed by photolithography or the like, to form the light blocking films 13b.

Next, after the wiring layer 22b is formed on the light blocking films 13b and the light receiving surface 20Sb, the color filters 12b and the on-chip lenses 11b in the Bayer array, for example, are sequentially formed on the light receiving unit 20b and the light blocking films 13b in the effective pixel region 100Ab. In this manner, the image sensor 1Cb can be obtained.

Note that, as in the first example configuration, green (G) or white (W) is assigned to the color filters 12b of the image-plane phase difference imaging pixels 2Bb in the second example configuration. However, in a case where a large amount of light enters, electric charges tend to saturate in the photodiodes 23b. At this point of time, excess charges are discharged from below the Si substrate 21b (on the side of the substrate 21b) in a front-illuminated image sensor. Therefore, the portions below the Si substrate 21b at the positions corresponding to the image-plane phase difference imaging pixels 2Bb, or more specifically, the portions below the photodiodes 23b may be doped with P-type impurities with higher concentration, and thus, the overflow barrier may be made higher.

Further, the image sensor 1cb may have an inner lens provided between the light receiving unit 20b of each image-plane phase difference imaging pixel 2Bb and the color filter 12b of the light collecting unit 10b.

As described above, the present technology can be applied not only to back-illuminated image sensors but also to front-illuminated image sensors, and similar effects can be obtained even in the case of a front-illuminated image sensor. Also, in a front-illuminated image sensor, the on-chip lenses 11b are separated from the light receiving surface 20Sb of the Si substrate 21b. Accordingly, it is easier to align the focusing points with the light receiving surface 20Sb, and both imaging pixel sensitivity and phase difference detection accuracy can be improved more easily than in a back-illuminated image sensor.

Further, another example overall configuration of a solid-state imaging device to which the present technology can be applied is described.

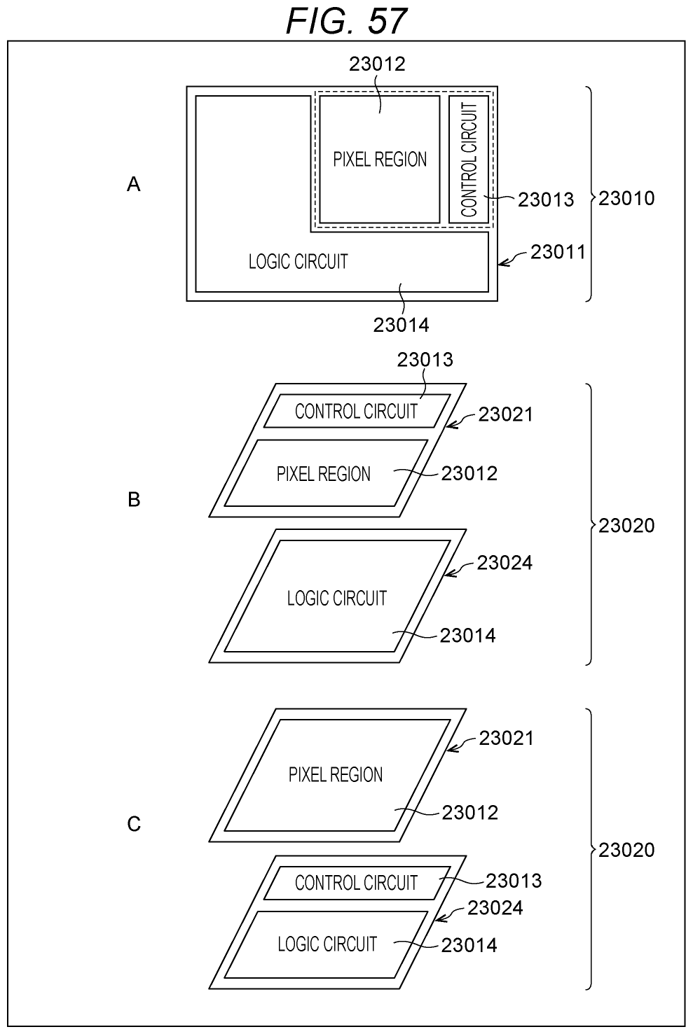

FIG. 57 is a diagram showing an outline of example configurations of a stacked solid-state imaging device to which the technology according to the present disclosure can be applied.

A of FIG. 57 shows a schematic example configuration of a non-stacked solid-state imaging device. As shown in A of FIG. 57, a solid-state imaging device 23010 has one die (a semiconductor substrate) 23011. A pixel region 23012 in which pixels are arranged in an array, a control circuit 23013 that controls driving of the pixels and performs other various kinds of control, and a logic circuit 23014 for performing signal processing are mounted on the die 23011.

B and C of FIG. 57 show schematic example configurations of a stacked solid-state imaging device. As shown in B and C of FIG. 57, a solid-state imaging device 23020 is designed as a single semiconductor chip in which two dies, which are a sensor die 23021 and a logic die 23024, are stacked and are electrically connected.

In B of FIG. 57, the pixel region 23012 and the control circuit 23013 are mounted on the sensor die 23021, and the logic circuit 23014 including a signal processing circuit that performs signal processing is mounted on the logic die 23024.

In C of FIG. 57, the pixel region 23012 is mounted on the sensor die 23021, and the control circuit 23013 and the logic circuit 23014 are mounted on the logic die 23024.

FIG. 57 is a cross-sectional view showing a first example configuration of the stacked solid-state imaging device 23020.

In the sensor die 23021, photodiodes (PDs) forming the pixels constituting the pixel region 23012, floating diffusions (FDs), Trs (MOSFETs), Trs serving as the control circuit 23013, and the like are formed. A wiring layer 23101 having a plurality of layers, which is three layers of wiring lines 23110 in this example, is further formed in the sensor die 23021. Note that (the Trs to be) the control circuit 23013 can be formed in the logic die 23024, instead of the sensor die 23021.

In the logic die 23024, Trs constituting the logic circuit 23014 are formed. A wiring layer 23161 having a plurality of layers, which is three layers of wiring lines 23170 in this example, is further formed in the logic die 23024. In the logic die 23024, a connecting hole 23171 having an insulating film 23172 formed on its inner wall surface is also formed, and a connected conductor 23173 connected to the wiring lines 23170 and the like is buried in the connecting hole 23171.

The sensor die 23021 and the logic die 23024 are bonded so that the respective wiring layers 23101 and 23161 face each other. Thus, the stacked solid-state imaging device 23020 in which the sensor die 23021 and the logic die 23024 are stacked is formed. A film 23191 such as a protective film is formed in the plane in which the sensor die 23021 and the logic die 23024 are bonded to each other.

In the sensor die 23021, a connecting hole 23111 is formed. The connecting hole 23111 penetrates the sensor die 23021 from the back surface side (the side at which light enters the PDs) (the upper side) of the sensor die 23021, and reaches the wiring lines 23170 in the uppermost layer of the logic die 23024. A connecting hole 23121 that is located in the vicinity of the connecting hole 23111 and reaches the wiring lines 23110 in the first layer from the back surface side of the sensor die 23021 is further formed in the sensor die 23021. An insulating film 23112 is formed on the inner wall surface of the connecting hole 23111, and an insulating film 23122 is formed on the inner wall surface of the connecting hole 23121. Connected conductors 23113 and 23123 are then buried in the connecting holes 23111 and 23121, respectively. The connected conductor 23113 and the connected conductor 23123 are electrically connected on the back surface side of the sensor die 23021. Thus, the sensor die 23021 and the logic die 23024 are electrically connected via the wiring layer 23101, the connecting hole 23121, the connecting hole 23111, and the wiring layer 23161.

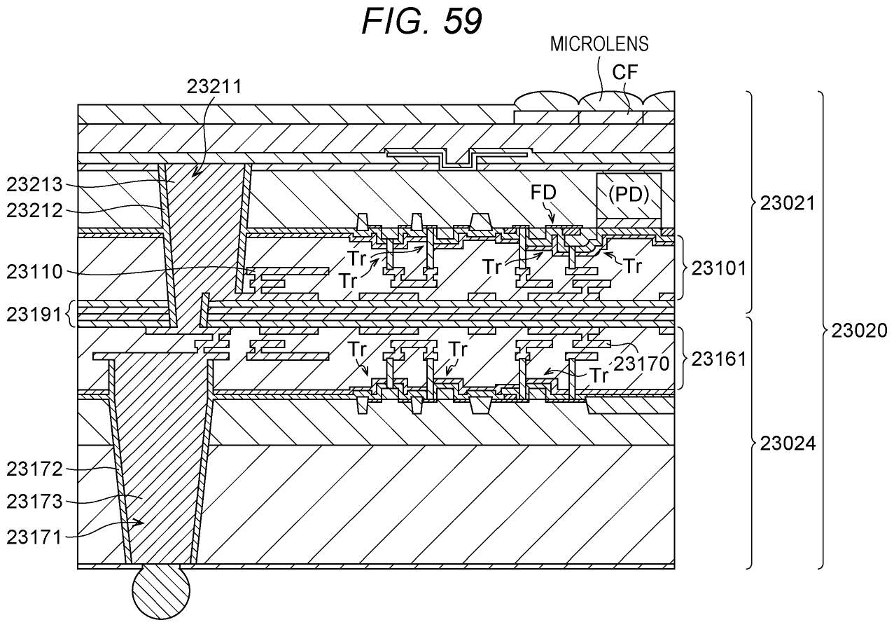

FIG. 59 is a cross-sectional view showing a second example configuration of the stacked solid-state imaging device 23020.

In the second example configuration of the solid-state imaging device 23020, ((the wiring lines 23110 of) the wiring layer 23101 of) the sensor die 23021 and ((the wiring lines 23170 of) the wiring layer 23161 of) the logic die 23024 are electrically connected by one connecting hole 23211 formed in the sensor die 23021.

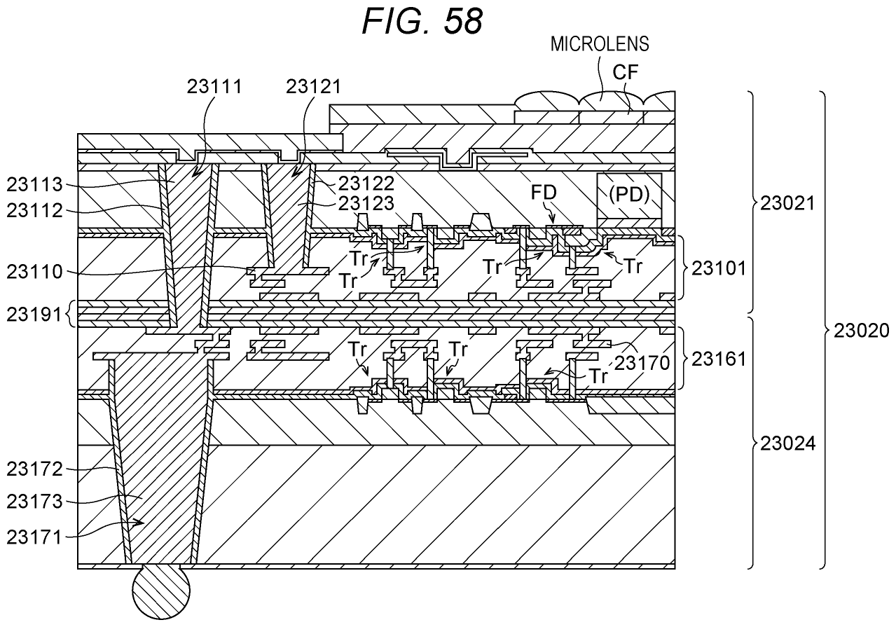

That is, in FIG. 59, the connecting hole 23211 is formed so as to penetrate the sensor die 23021 from the back surface side of the sensor die 23021, reach the wiring lines 23170 in the uppermost layer of the logic die 23024, and reach the wiring lines 23110 in the uppermost layer of the sensor die 23021. An insulating film 23212 is formed on the inner wall surface of the connecting hole 23211, and a connected conductor 23213 is buried in the connecting hole 23211. In FIG. 58 described above, the sensor die 23021 and the logic die 23024 are electrically connected by the two connecting holes 23111 and 23121. In FIG. 59, on the other hand, the sensor die 23021 and the logic die 23024 are electrically connected by the single connecting hole 23211.

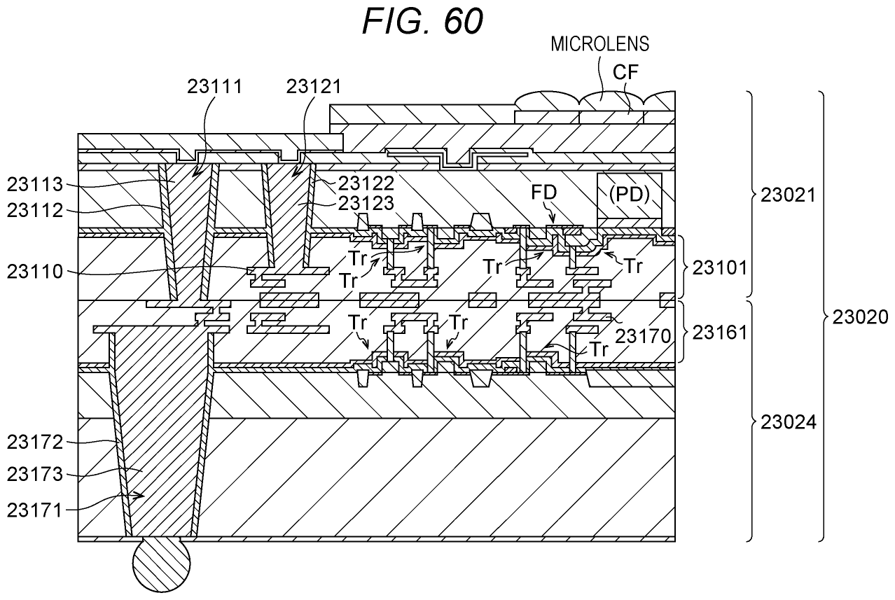

FIG. 60 is a cross-sectional view showing a third example configuration of the stacked solid-state imaging device 23020.

In the solid-state imaging device 23020 shown in FIG. 60, the film 23191 such as a protective film is not formed in the plane in which the sensor die 23021 and the logic die 23024 are bonded to each other, which differs from the case shown in FIG. 58, in which the film 23191 such as a protective film is formed in the plane in which the sensor die 23021 and the logic die 23024 are bonded to each other.

The sensor die 23021 and the logic die 23024 are stacked so that the wiring lines 23110 and 23170 are in direct contact, and heat is then applied while a required load is applied, so that the wiring lines 23110 and 23170 are bonded directly to each other. Thus, the solid-state imaging device 23020 in FIG. 60 is formed.

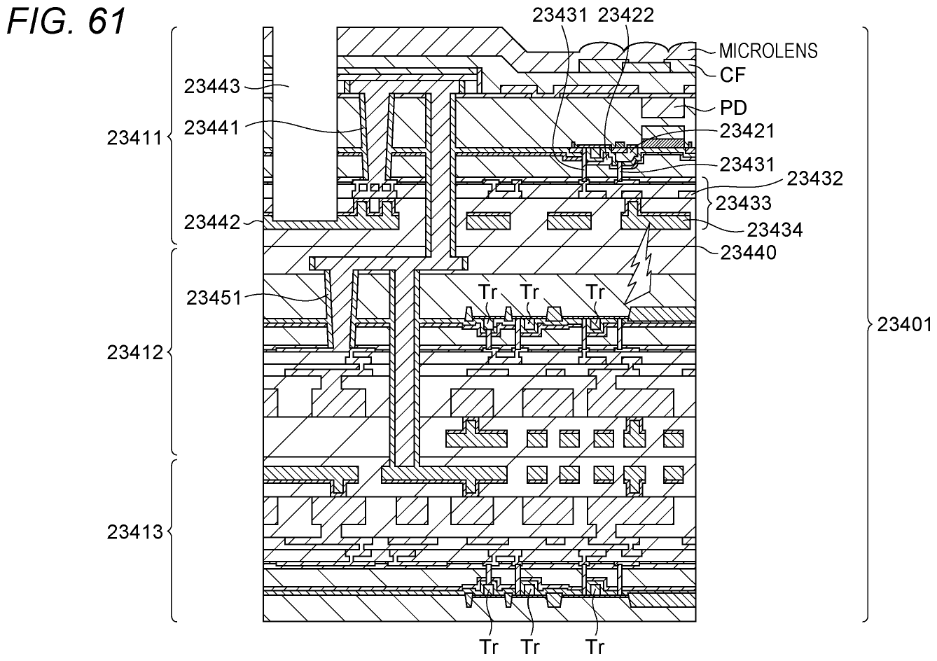

FIG. 61 is a cross-sectional view showing another example configuration of a stacked solid-state imaging device to which the technology according to the present disclosure can be applied.

In FIG. 61, a solid-state imaging device 23401 has a three-layer stack structure in which the three dies of a sensor die 23411, a logic die 23412, and a memory die 23413 are stacked.

The memory die 23413 includes a memory circuit that stores data to be temporarily required in signal processing to be performed in the logic die 23412, for example.

In FIG. 61, the logic die 23412 and the memory die 23413 are stacked in this order under the sensor die 23411. However, the logic die 23412 and the memory die 23413 may be stacked in reverse order. In other words, the memory die 23413 and the logic die 23412 can be stacked in this order under the sensor die 23411.

Note that, in FIG. 61, PDs serving as the photoelectric conversion units of the pixels, and the source/drain regions of the pixels Tr are formed in the sensor die 23411.

A gate electrode is formed around a PD via a gate insulating film, and the gate electrode and a pair of source/drain regions form a pixel Tr 23421 and a pixel Tr 23422.

The pixel Tr 23421 adjacent to the PD is a transfer Tr, and one of the source/drain regions constituting the pixel Tr 23421 is an FD.

Further, an interlayer insulating film is formed in the sensor die 23411, and a connecting hole is formed in the interlayer insulating film. In the connecting hole, a connected conductor 23431 connected to the pixel Tr 23421 and the pixel Tr 23422 is formed.

Further, a wiring layer 23433 having a plurality of layers of wiring lines 23432 connected to each connected conductor 23431 is formed in the sensor die 23411.

Aluminum pads 23434 serving as electrodes for external connection are also formed in the lowermost layer of the wiring layer 23433 in the sensor die 23411. That is, in the sensor die 23411, the aluminum pads 23434 are formed at positions closer to the bonding surface 23440 with the logic die 23412 than the wiring lines 23432. Each aluminum pad 23434 is used as one end of a wiring line related to inputting/outputting of signals from/to the outside.

Further, a contact 23441 to be used for electrical connection with the logic die 23412 is formed in the sensor die 23411. The contact 23441 is connected to a contact 23451 of the logic die 23412, and also to an aluminum pad 23442 of the sensor die 23411.

Further, a pad hole 23443 is formed in the sensor die 23411 so as to reach the aluminum pad 23442 from the back surface side (the upper side) of the sensor die 23411.

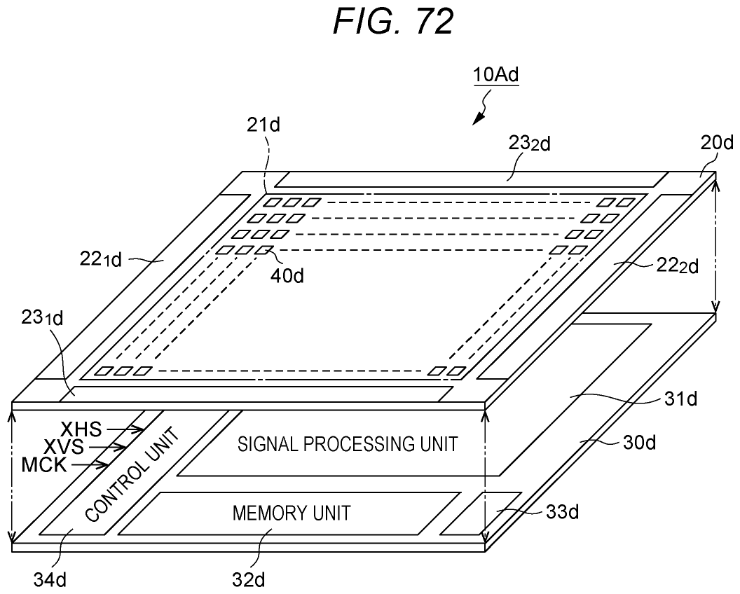

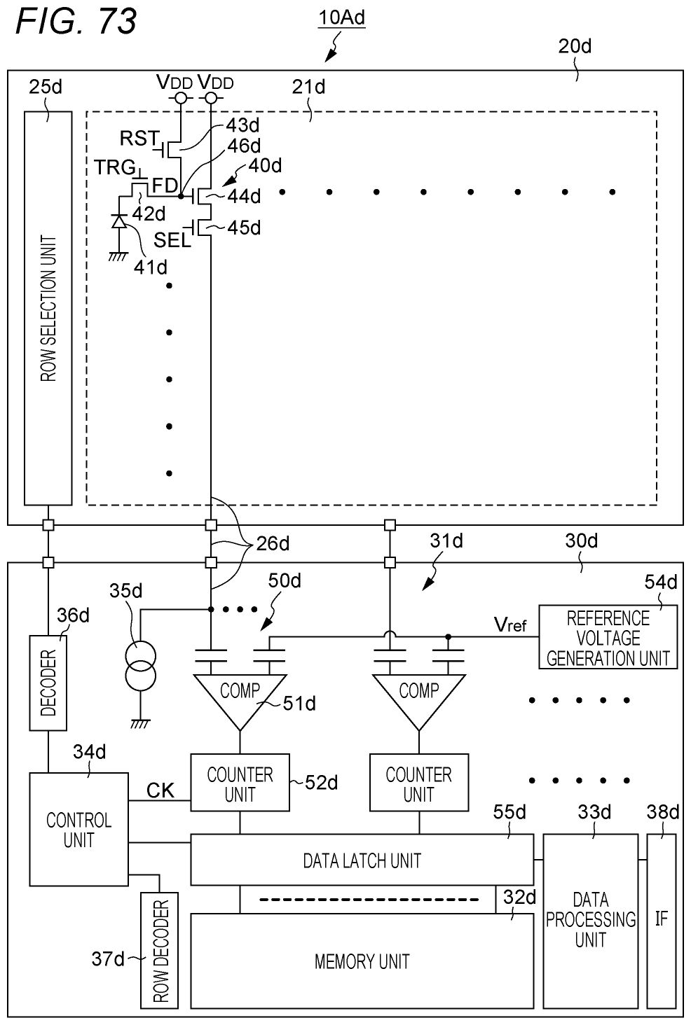

An example configuration (a circuit configuration in a stacked substrate) of a stacked solid-state imaging device to which the present technology can be applied is now described, with reference to FIGS. 72 and 73.

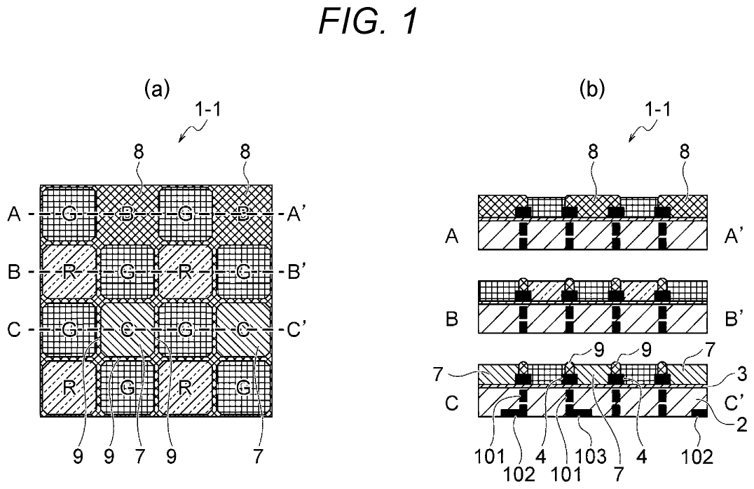

An electronic device (a stacked solid-state imaging device) 10Ad shown in FIG. 72 includes a first semiconductor chip 20d having a sensor unit 21d in which a plurality of sensors 40d is disposed, and a second semiconductor chip 30d having a signal processing unit 31d that processes signals acquired by the sensors 40d. The first semiconductor chip 20d and the second semiconductor chip 30d are stacked, and at least part of the signal processing unit 31d is formed with a depleted field effect transistor. Note that the plurality of sensors 40d is arranged in a two-dimensional matrix. The same applies in the following description. Note that, in FIG. 1, for each of explanation, the first semiconductor chip 20d and the second semiconductor chip 30d are separated from each other.

Alternatively, the electronic device 10Ad includes the first semiconductor chip 20d having the sensor unit 21d in which the plurality of sensors 40d is disposed, and the second semiconductor chip 30d having the signal processing unit 31d that processes signals acquired by the sensors 40d. The first semiconductor chip 20d and the second semiconductor chip 30d are stacked, and the signal processing unit 31d is formed with a high-voltage transistor system circuit and a low-voltage transistor system circuit, and at least part of the low-voltage transistor system circuit is formed with a depleted field effect transistor.

The depleted field effect transistor has a completely depleted SOI structure, a partially depleted SOI structure, a fin structure (also called a double-gate structure or a tri-gate structure), or a deeply depleted channel structure. The configurations and structures of these depleted field effect transistors will be described later.

Specifically, as shown in FIG. 73, the sensor unit 21d and a row selection unit 25d are disposed on the first semiconductor chip 20d. On the other hand, the signal processing unit 31d is disposed on the second semiconductor chip 30d. The signal processing unit 31d includes: an analog-digital converter (hereinafter referred to simply as “AD converter”) 50d including a comparator 51d and a counter unit 52d; a ramp voltage generator (hereinafter sometimes called “reference voltage generation unit”) 54d; a data latch unit 55d; a parallel-serial conversion unit 56; a memory unit 32d; a data processing unit 33d; a control unit 34d (including a clock supply unit connected to the AD converter 50d); a current source 35d; a decoder 36d; a row decoder 37d; and an interface (IF) unit 38b.

Further, in the electronic device of Example 1, the high-voltage transistor system circuit (the specific configuration circuit will be described later) in the second semiconductor chip 30d and the sensor unit 21d in the first semiconductor chip 20d planarly overlap with each other. In the second semiconductor chip 30d, a light blocking region is formed above the high-voltage transistor system circuit facing the sensor unit 21d of the first semiconductor chip 20d. In the second semiconductor chip 30d, the light blocking region disposed below the sensor unit 21d can be formed by disposing wiring lines (not shown) formed on the second semiconductor chip 30d as appropriate. Also, in the second semiconductor chip 30d, the AD converter 50d is disposed below the sensor unit 21d. Here, the signal processing unit 31d or the low-voltage transistor system circuit (the specific configuration circuit will be described later) includes part of the AD converter 50d, and at least part of the AD converter 50d is formed with a depleted field effect transistor. Specifically, the AD converter 50d is formed with a single-slope AD converter whose circuit diagram is shown in FIG. 73. Alternatively, the electronic device of Example 1 may have another layout in which the high-voltage transistor system circuit in the second semiconductor chip 30d and the sensor unit 21d in the first semiconductor chip 20d do not planarly overlap with each other. That is, in the second semiconductor chip 30d, part of the analog-digital converter 50d and the like are disposed at the outer peripheral portion of the second semiconductor chip 30d. As a result, forming the light blocking region becomes unnecessary, and it is possible to simplify the process, the structure, and the configuration, increase the degree of freedom in design, and reduce restrictions on layout design.

One AD converter 50d is provided for a plurality of sensors 40d (the sensors 40d belonging to one sensor column in Example 1), and one AD converter 50d formed with a single-slope analog-digital converter includes: a ramp voltage generator (reference voltage generation unit) 54d; a comparator 51d to which an analog signal acquired by a sensor 40d and a ramp voltage from the ramp voltage generator (reference voltage generation unit) 54d are to be input; and a counter unit 52d that is supplied with a clock CK from the clock supply unit (not shown) provided in the control unit 34d, and operates in accordance with an output signal from the comparator 51d. Note that the clock supply unit connected to the AD converter 50d is included in the signal processing unit 31d or the low-voltage transistor system circuit (more specifically, included in the control unit 34d), and is formed with a known PLL circuit. Further, at least part of the counter unit 52d and the clock supply unit are formed with a depleted field effect transistor.

That is, in Example 1, the sensor unit 21d (the sensors 40d) and the row selection unit 25d provided on the first semiconductor chip 20d, and further, the column selection unit 27 described later correspond to the high-voltage transistor system circuit. The comparator 51d, the ramp voltage generator (the reference voltage generation unit) 54d, the current source 35d, the decoder 36d, and the interface (IF) unit 38b that constitute the AD converter 50d in the signal processing unit 31d provided on the second semiconductor chip 30d also correspond to the high-voltage transistor system circuit. Meanwhile, the counter unit 52d, the data latch unit 55d, the parallel-serial conversion unit 56, the memory unit 32d, the data processing unit 33d (including an image signal processing unit), the control unit 34d (including the clock supply unit and a timing control circuit connected to the AD converter 50d), and the row decoder 37d that constitute the AD converter 50d in the signal processing unit 31d provided on the second semiconductor chip 30d, and further, the multiplexer (MUX) 57 and the data compression unit 58 described later correspond to the low-voltage transistor system circuit. Further, all of the counter unit 52d and the clock supply unit included in the control unit 34d are formed with a depleted field effect transistor.

To obtain the stack structure formed with the first semiconductor chip 20d and the second semiconductor chip 30d, the predetermined various circuits described above are first formed on a first silicon semiconductor substrate forming the first semiconductor chip 20d and a second silicon semiconductor substrate forming the second semiconductor chip 30d, on the basis of a known method. The first silicon semiconductor substrate and the second silicon semiconductor substrate are then bonded to each other, on the basis of a known method. Next, through holes extending from the wiring lines formed on the first silicon semiconductor substrate side to the wiring lines formed on the second silicon semiconductor substrate are formed, and the through holes are filled with a conductive material, to form TC(S)Vs. Color filters and microlenses are then formed on the sensors 40d as desired. After that, dicing is performed on the bonded structure formed with the first silicon semiconductor substrate and the second silicon semiconductor substrate. Thus, the electronic device 10Ad in which the first semiconductor chip 20d and the second semiconductor chip 30d are stacked can be obtained.

Specifically, the sensors 40d are formed with image sensors, or more specifically, the sensors 40d are formed with CMOS image sensors each having a known configuration and structure. The electronic device 10Ad is formed with a solid-state imaging device. In the solid-state imaging device, one sensor is used as a unit of sensor, a plurality of sensors is used as a unit of sensor, or one or a plurality of rows (lines) is used as a unit. Signals (analog signals) from the sensors 40d can be read from each sensor group, and the solid-state imaging device is of an XY address type. Further, in the sensor unit 21d, a control line (a row control line) is provided for each sensor row in a matrix-like sensor array, and a signal line (a column signal line/vertical signal line) 26 is provided for each sensor column in the matrix-like sensor array. The current source 35d may be connected to each of the signal lines 26d. Signals (analog signals) are then read from the sensors 40d of the sensor unit 21d via these signal lines 26d. This reading can be performed under a rolling shutter that performs exposure, with a unit being one sensor or one line (one row) of sensors, for example. This reading under the rolling shutter is referred to as “rolling reading” in some cases.

At the peripheral portion of the first semiconductor chip 20d, pad portions 22₁ and 22₂ for establishing electrical connection to the outside, and via portions 23₁ and 23₂ each having a TC(S)V structure for establishing electrical connection to the second semiconductor chip 30d are provided. Note that, in the drawings, the via portions are shown as “VIA” in some cases. Here, the pad portion 22₁ and the pad portion 22₂ are provided on both the right and left sides of the sensor unit 21d, but may be provided only one of the right and left sides. Also, the via portion 231 and the via portion 232 are provided on both the upper and lower sides of the sensor unit 21d, but may be provided one of the upper and lower sides. Further, a bonding pad portion may be provided on the second semiconductor chip 30d on the lower side, openings may be provided in the first semiconductor chip 20d, and wire bonding to the bonding pad portion provided on the second semiconductor chip 30d may be performed via the openings formed in the first semiconductor chip 20d. A TC(S)V structure may be used from the second semiconductor chip 30d, to perform substrate mounting. Alternatively, electrical connection between the circuits in the first semiconductor chip 20d and the circuits in the second semiconductor chip 30d can be established via bumps based on a chip-on-chip method. Analog signal obtained from the respective sensors 40d of the sensor unit 21d are transmitted from the first semiconductor chip 20d to the second semiconductor chip 30d via the via portions 23₁ and 23₂. Note that, in this specification, the concepts of “left side”, “right side”, “upper side”, “lower side”, “up and down”, “vertical direction”, “right and left”, and “lateral direction” are concepts indicating positional relationship when the drawings are viewed. The same applies in the description below.

The circuit configuration on the side of the first semiconductor chip 20d is now described, with reference to FIG. 73. On the side of the first semiconductor chip 20d, in addition to the sensor unit 21d in which the sensors 40d are arranged in a matrix, the row selection unit 25d that selects each sensor 40d of the sensor unit 21d row by row, in accordance with an address signal supplied from the side of the second semiconductor chip 30d. Note that the row selection unit 25d is provided on the side of the first semiconductor chip 20d in this example, but may be provided on the side of the second semiconductor chip 30d.

As shown in FIG. 73, a sensor 40d includes a photodiode 41d as a photoelectric conversion element, for example. In addition to the photodiode 41d, the sensor 40d includes four transistors: a transfer transistor (a transfer gate) 42, a reset transistor 43d, an amplification transistor 44d, and a selection transistor 45d, for example. For example, N-channel transistors are used as the four transistors 42d, 43d, 44d, and 45d. However, the combinations of conductivity types of the transfer transistor 42d, the reset transistor 43d, the amplification transistor 44d, and the selection transistor 45d shown herein are merely an example, and the conductivity types are not limited to these combinations. That is, combinations using P-channel type transistors can be used as necessary. Further, these transistors 42d, 43d, 44d, and 45d are formed with high-voltage MOS transistors. That is, as described above, the sensor unit 21d is a high-voltage transistor system circuit as a whole.

A transfer signal TRG, a reset signal RST, and a selection signal SEL that are drive signals for driving the sensor 40d are supplied to the sensor 40d from the row selection unit 25d as appropriate. That is, the transfer signal TRG is applied to the gate electrode of the transfer transistor 42d, the reset signal RST is applied to the gate electrode of the reset transistor 43d, and the selection signal SEL is applied to the gate electrode of the selection transistor 45d.

In the photodiode 41d, the anode electrode is connected to a power supply on the lower potential side (the ground, for example), received light (incident light) is photoelectrically converted into optical charges (photoelectrons herein) with a charge amount corresponding to the light amount, and the optical charges are accumulated. The cathode electrode of the photodiode 41d is electrically connected to the gate electrode of the amplification transistor 44d via the transfer transistor 42d. A node 46 electrically connected to the gate electrode of the amplification transistor 44d is called a floating diffusion (FD) unit or a floating diffusion region portion.

The transfer transistor 42d is connected between the cathode electrode of the photodiode 41d and the FD unit 46d. A transfer signal TRG that is active at the high level (the V_{DD} level, for example) (hereinafter referred to as “High-active”) is supplied to the gate electrode of the transfer transistor 42d from the row selection unit 25d. In response to this transfer signal TRG, the transfer transistor 42d becomes conductive, and the optical charges photoelectrically converted by the photodiode 41d are transferred to the FD unit 46d. The drain region of the reset transistor 43d is connected to the sensor power supply V_{DD}, and the source region is connected to the FD unit 46d. A High-active reset signal RST is supplied to the gate electrode of the reset transistor 43d from the row selection unit 25d. In response to this reset signal RST, the reset transistor 43d becomes conductive, and the electric charges in the FD unit 46d are discarded to the sensor power supply V_{DD}, so that the FD unit 46d is reset. The gate electrode of the amplification transistor 44d is connected to the FD unit 46d, and the drain region is connected to the sensor power supply V_{DD}. The amplification transistor 44d then outputs the potential of the FD unit 46d reset by the reset transistor 43d, as a reset signal (reset level: V_{Reset}). The amplification transistor 44d further outputs the potential of the FD unit 46d after the signal charge is transferred by the transfer transistor 42d, as an optical storage signal (signal level) V_{Sig}. The drain region of the selection transistor 45d is connected to the source region of the amplification transistor 44d, and the source region is connected to the signal line 26d, for example. A High-active selection signal SEL is supplied to the gate electrode of the selection transistor 45d from the row selection unit 25d. In response to this selection signal SEL, the selection transistor 45d becomes conductive, the sensor 40d enters a selected state, and the signal at the signal level V_{Sig} (an analog signal) output from the amplification transistor 44d is sent to the signal line 26d.

In this manner, the potential of the FD unit 46d after the reset is read as the reset level V_{Reset} from the sensor 40d, and the potential of the FD unit 46d after the transfer of the signal charge is then read out as the signal level V_{Sig} sequentially to the signal line 26d. The signal level V_{Sig} also includes a component of the reset level V_{Reset}. Note that the selection transistor 45d is a circuit component that is connected between the source region of the amplification transistor 44d and the signal line 26d, but may be a circuit component that is connected between the sensor power supply V_{DD} and the drain region of the amplification transistor 44d.

Further, the sensor 40d is not necessarily a component formed with such four transistors. For example, the sensor 40d may be a component formed with three transistors among which the amplification transistor 44d has the functions of the selection transistor 45d, or may be a component or the like in which the transistors after the FD unit 46d are shared among plurality of photoelectric conversion elements (among sensors), and the configuration of the circuit is not limited to any particular one.

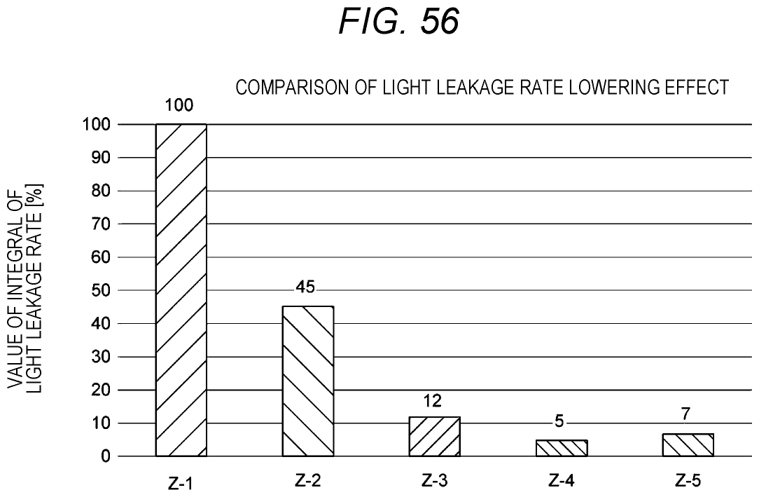

As shown in FIGS. 72 and 56, and as described above, in the electronic device 10Ad of Example 1, the memory unit 32d, the data processing unit 33d, the control unit 34d, the current source 35d, the decoder 36d, the row decoder 37d, the interface (IF) unit 38b, and the like are provided on the second semiconductor chip 30d, and a sensor drive unit (not shown) that drives each sensor 40d of the sensor unit 21d is also provided on the second semiconductor chip 30d. The signal processing unit 31d can be designed to perform predetermined signal processing including digitization (AD conversion) for each sensor column in parallel (column parallel), on analog signals read from the respective sensors 40d of the sensor unit 21d on the sensor row basis. Further, the signal processing unit 31d includes the AD converter 50d that digitizes an analog signal read from each sensor 40d of the sensor unit 21d into the signal line 26d, and transfers image data (digital data) subjected to the AD conversion, to the memory unit 32d. The memory unit 32d stores the image data subjected to the predetermined signal processing at the signal processing unit 31d. The memory unit 32d may be formed with a nonvolatile memory or a volatile memory. The data processing unit 33d reads the image data stored in the memory unit 32d in a predetermined order, performs various processes, and outputs the image data to the outside of the chip. The control unit 34d controls each operation of the signal processing unit 31d such as respective operations of the sensor drive unit, the memory unit 32d, and the data processing unit 33d, on the basis of reference signals such as a horizontal synchronization signal XHS, a vertical synchronization signal XVS, and a master clock MCK, which are supplied from outside the chip, for example. At this stage, the control unit 34d performs control, while maintaining synchronization between the circuits (the row selection unit 25d and the sensor unit 21d) on the side of the first semiconductor chip 20d and the signal processing unit 31d (the memory unit 32d, the data processing unit 33d, and the like) on the side of the second semiconductor chip 30d.

Each of the signal lines 26d from which analog signals are read out from the respective sensors 40d of the sensor unit 21d on the sensor column basis is connected to the current source 35d. The current source 35d includes a so-called load MOS circuit component that is formed with a MOS transistor whose gate potential is biased to a constant potential so as to supply a constant current to the signal lines 26d, for example. The current source 35d formed with this load MOS circuit supplies a constant current to the amplification transistor 44d of each sensor 40d included in the selected row, to cause the amplification transistor 44d to operate as a source follower. Under the control of the control unit 34d, the decoder 36d supplies the row selection unit 25d with an address signal for designating the address of the selected row, when the respective sensors 40d of the sensor unit 21d are selected row by row. Under the control of the control unit 34d, the row decoder 37d designates a row address when image data is to be written into the memory unit 32d, or image data is to be read from the memory unit 32d.

As described above, the signal processing unit 31d includes at least the AD converters 50d that performs digitization (AD conversion) on analog signals read from the respective sensors 40d of the sensor unit 21d through the signal lines 26d, and performs parallel signal processing (column parallel AD) on analog signals on the sensor column basis. The signal processing unit 31d further includes the ramp voltage generator (reference voltage generation unit) 54d that generates a reference voltage Vref to be used for AD conversion at the AD converters 50d. The reference voltage generation unit 54d generates the reference voltage Vref with so-called ramp waveforms (gradient waveforms), whose voltage value changes stepwise over time. The reference voltage generation unit 54d can be formed with a digital-analog converter (DA converter), for example, but is not limited to that.

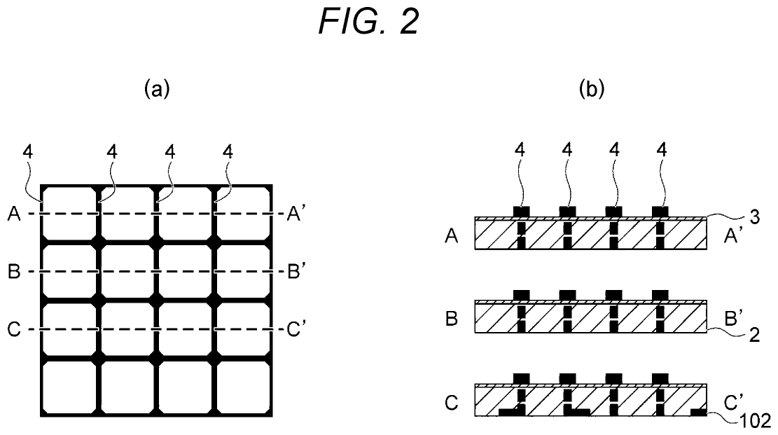

The AD converters 50d are provided for the respective sensor columns of the sensor unit 21d, or for the respective signal lines 26d, for example. That is, the AD converters 50d are so-called column-parallel AD converters, and the number of the AD converters 50d is the same as the number of the sensor columns in the sensor unit 21d. Further, an AD converter 50d generates a pulse signal having a magnitude (pulse width) in the time axis direction corresponding to the magnitude of the level of the analog signal, for example, and performs an AD conversion process by measuring the length of the period of the pulse width of this pulse signal. More specifically, as shown in FIG. 2, each AD converter 50d includes at least a comparator (COMP) 51d and a counter unit 52d. The comparator 51d compares a comparative input with a reference input, the comparative input being an analog signal (the above mentioned signal level V_{Sig} and reset level V_{Reset}) read from each sensor 40d of the sensor unit 21d via the signal line 26d, the reference input being the reference voltage Vref with ramp waveforms supplied from the reference voltage generation unit 54d. The ramp waveforms are waveforms indicating voltage that changes gradually (stepwise) over time. Further, the output of the comparator 51d is in a first state (the high level, for example) when the reference voltage Vref is higher than the analog signal, for example. On the other hand, when the reference voltage Vref is equal to or lower than the analog signal, the output is in a second state (the low level, for example). The output signal of the comparator Md is a pulse signal having a pulse width depending on the magnitude of the level of the analog signal.

A count-up/down counter is used as a counter unit 52d, for example. The clock CK is supplied to the counter unit 52d at the same timing as the start of supply of the reference voltage Vref to the comparator Md. The counter unit 52d as a count-up/down counter performs counting down or counting up in synchronization with the clock CK, to measure the period of the pulse width of the output pulse of the comparator 51d, or the comparison period from the start of a comparing operation to the end of the comparing operation. During this measurement operation, as for the reset level V_{Reset} and the signal level V_{Sig} sequentially read from the sensor 40d, the counter unit 52d performs counting down for the reset level V_{Reset}, and performs counting up for the signal level V_{Sig}. By this counting up/down operation, the difference between the signal level V_{Sig} and the reset level V_{Reset} can be calculated. As a result, the AD converter 50d performs a correlated double sampling (CDS) process, in addition to the AD conversion process. Here, the “CDS process” is a process of removing fixed pattern noise unique to the sensor, such as reset noise of the sensor 40d and threshold variation of the amplification transistor 44d, by calculating the difference between the signal level V_{Sig} and the reset level V_{Reset}. The count result (count value) from the counter unit 52d then serves as the digital value (image data) obtained by digitizing the analog signal.

As described above, in the electronic device 10Ad of Example 1, which is a solid-state imaging device in which the first semiconductor chip 20d and the second semiconductor chip 30d are stacked, the first semiconductor chip 20d is only required to have a size (area) large enough for forming the sensor unit 21d, and accordingly, the size (area) of the first semiconductor chip 20d and the size of the entire chip can be made smaller. Further, a process suitable for manufacturing the sensors 40d can be applied to the first semiconductor chip 20d, and a process suitable for manufacturing various circuits can be applied to the second semiconductor chip 30d. Thus, the electronic device 10Ad can be manufactured by an optimized process. Also, while analog signals are transmitted from the side of the first semiconductor chip 20d to the side of the second semiconductor chip 30d, a circuit portion for performing analog/digital processing is provided in the same substrate (second semiconductor chip 30d). Further, control is performed while synchronization is maintained between the circuits on the side of the first semiconductor chip 20d and the circuits on the side of the second semiconductor chip 30d. Thus, high-speed processing can be performed.

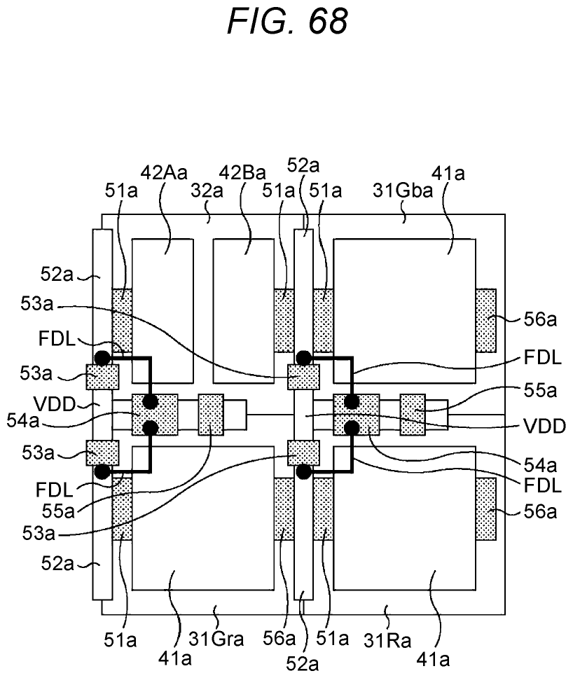

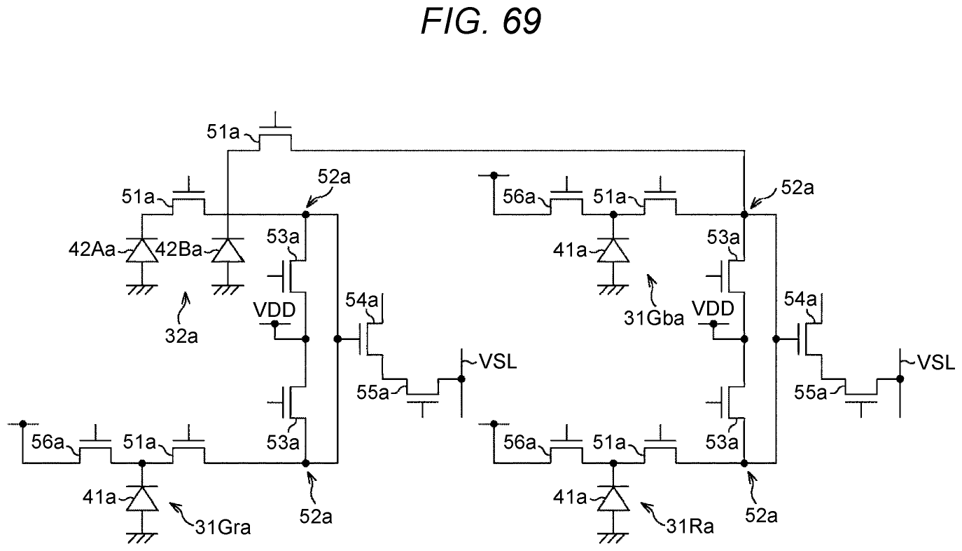

Next, an example configuration of imaging pixels and a ranging pixel (a phase difference detection pixel, for example; this applies in the description below) to which the present technology can be applied is described, with reference to FIGS. 68 and 69. FIG. 68 is a plan view showing an example configuration of imaging pixels and a phase difference detection pixel. FIG. 69 is a circuit diagram showing an example configuration of imaging pixels and a phase difference detection pixel.

FIGS. 68 and 69 show three imaging pixels 31Gra, 31Gba, and 31Ra, and one phase difference detection pixel 32a.

In this example, the phase difference detection pixel 32a, and the imaging pixel 31Gra, the imaging pixel 31Gba, and the imaging pixel 31Ra each have a two-pixel vertical sharing configuration.

The imaging pixels 31Gra, 31Gba, and 31Ra each includes a photoelectric conversion unit 41, a transfer transistor Ma, a FD 52a, a reset transistor 53a, an amplification transistor 54a, a selection transistor 55a, and an overflow control transistor 56 that discharges the electric charges accumulated in the photoelectric conversion unit 41.

As the overflow control transistor 56 is provided in each of the imaging pixels 31Gra, 31Gba, and 31Ra, optical symmetry between the pixels can be maintained, and differences in imaging characteristics can be reduced. Further, when the overflow control transistor 56 is turned on, blooming of adjacent pixels can be prevented.

Meanwhile, the phase difference detection pixel 32a includes photoelectric conversion units 42Aa and 42Ba, transfer transistors 51a, FDs 52a, reset transistors 53a, an amplification transistor 54a, and a selection transistor 55a that are associated with the respective photoelectric conversion units 42Aa and 42Ba.

Note that the FD 52a associated with the photoelectric conversion unit 42Ba is shared with the photoelectric conversion unit 41 of the imaging pixel 31Gba.

Further, as shown in FIG. 68, the FD 52a associated with the photoelectric conversion unit 42Aa in the phase difference detection pixel 32a, and the FD 52a of the imaging pixel 31Gra are both connected to the gate electrode of the amplification transistor 54a by wiring lines FDL.

With this arrangement, the photoelectric conversion unit 42Aa shares the FD 52a, the amplification transistor 54a, and the selection transistor 55a with the photoelectric conversion unit 41 of the imaging pixel 31Gra.

Likewise, the FD 52a (which is the FD 52a of the imaging pixel 31Gba) associated with the photoelectric conversion unit 42Ba in the phase difference detection pixel 32a, and the FD 52a of the imaging pixel 31Ra are both connected to the gate electrode of the amplification transistor 54a by wiring lines FDL. With this arrangement, the photoelectric conversion unit 42Ba shares the FD 52a, the amplification transistor 54a, and the selection transistor 55a with the photoelectric conversion units 41 of the imaging pixels 31Gba and 31Ra.

With the above configuration, the two photoelectric conversion units in the phase difference detection pixel share the FDs and the amplification transistors of different adjacent pixels. Thus, the two photoelectric conversion units can perform exposure and reading at the same time as each other without a charge storage unit, and AF speed and AF accuracy can be increased.

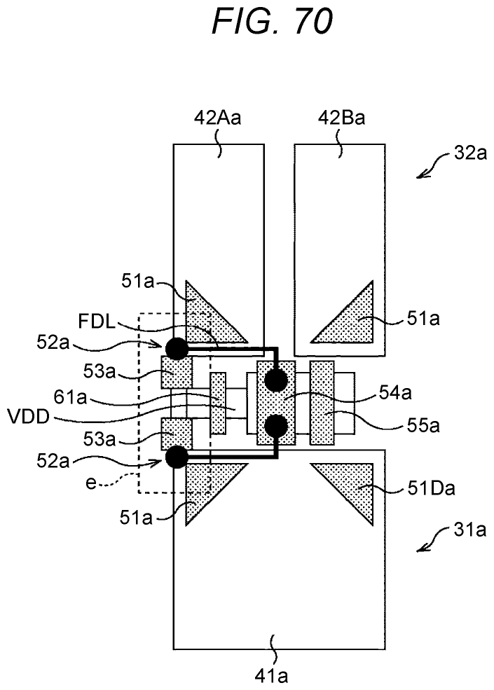

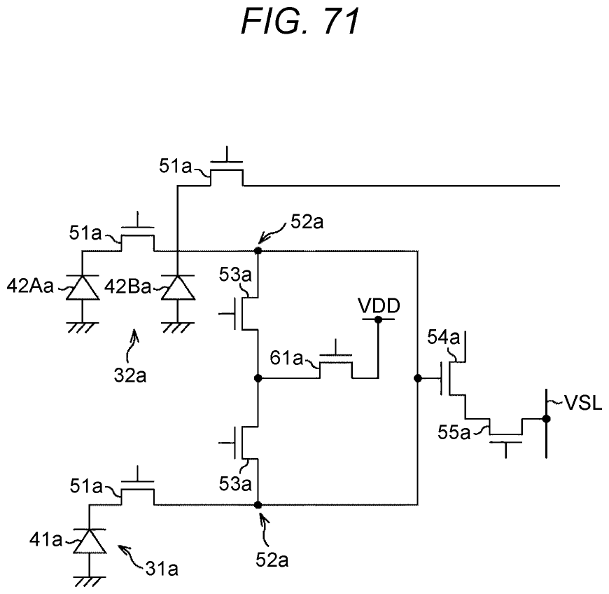

Referring now to FIGS. 70 and 71, an example configuration of an imaging pixel and a ranging pixel (a phase difference detection pixel, for example; this applies in the description below) in another mode to which the present technology can be applied is described. FIG. 70 is a plan view showing an example configuration of imaging pixels and a phase difference detection pixel. FIG. 71 is a circuit diagram showing an example configuration of imaging pixels and a phase difference detection pixel.

FIGS. 70 and 71 show one imaging pixel 31 and one phase difference detection pixel 32a.

In this example, the phase difference detection pixel 32a and the imaging pixel 31 are designed to share two vertical pixels.

The imaging pixel 31a includes a photoelectric conversion unit 41, transfer transistors 51a and 51D, a FD 52a, a reset transistor 53a, an amplification transistor 54a, and a selection transistor 55a. Here, the transfer transistor 51a is provided to maintain the symmetry of the pixel structure, and, unlike the transfer transistor 51a, does not have a function of transferring the electric charges of the photoelectric conversion unit 41 and the like. Note that the imaging pixel 31a may also include an overflow control transistor that discharges the electric charges accumulated in the photoelectric conversion unit 41.

Meanwhile, the phase difference detection pixel 32a includes photoelectric conversion units 42Aa and 42Ba, transfer transistors 51a, FDs 52a, a reset transistor 53, an amplification transistor 54a, and a selection transistor 55a that are associated with the respective photoelectric conversion units 42Aa and 42Ba.

Note that the FD associated with the photoelectric conversion unit 42Ba is shared with the photoelectric conversion unit of an imaging pixel (not shown) adjacent to the phase difference detection pixel 32a.

Further, as shown in FIG. 70, the FD 52a associated with the photoelectric conversion unit 42Aa in the phase difference detection pixel 32a, and the FD 52a of the imaging pixel 31a are both connected to the gate electrode of the amplification transistor 54a by wiring lines FDL. With this arrangement, the photoelectric conversion unit 42Aa shares the FD 52a, the amplification transistor 54a, and the selection transistor 55a with the photoelectric conversion unit 41 of the imaging pixel 31a.

Likewise, the FD 52a associated with the photoelectric conversion unit 42Ba in the phase difference detection pixel 32a, and the FD of the imaging pixel (not shown) are both connected to the gate electrode of the amplification transistor of the imaging pixel (not shown) by wiring lines FDL (not shown). With this arrangement, the photoelectric conversion unit 42Ba shares the FD, the amplification transistor, and the selection transistor with the photoelectric conversion unit of the imaging pixel (not shown).

With the above configuration, the two photoelectric conversion units in the phase difference detection pixel share the FDs and the amplification transistors of different adjacent pixels. Thus, the two photoelectric conversion units can perform exposure and reading at the same time as each other without a charge storage unit, and AF speed and AF accuracy can be increased.

Note that, in this example, a pixel transistor including the amplification transistor 54a is disposed between the pixels (the imaging pixel 31a and the phase difference detection pixel 32a) constituting a pixel sharing unit. With such a configuration, the FD 52a in each pixel and the amplification transistor 54a are disposed at positions adjacent to each other. Accordingly, the wiring length of the wiring lines FDL connecting the FDs 52a and the amplification transistor 54a can be designed to be short, and conversion efficiency can be increased.

Further, in this example, the sources of the respective reset transistors 53 of the imaging pixel 31a and the phase difference detection pixel 32a are connected to the FDs 52a of the respective pixels. With this arrangement, the capacity of the FDs 52a can be reduced, and conversion efficiency can be increased.

Furthermore, in this example, the drains of the respective reset transistors 53a of the imaging pixel 31a and the phase difference detection pixel 32a are both connected to the source of a conversion efficiency switching transistor 61a. With such a configuration, it is possible to change the capacity of the FDs 52a by turning on/off the reset transistors 53a of the respective pixels, and set conversion efficiency.

Specifically, in a case where, while the respective transfer transistors 51a of the imaging pixel 31a and the phase difference detection pixel 32a are on, the respective reset transistors 53a of the imaging pixel 31a and the phase difference detection pixel 32a are turned on, and the conversion efficiency switching transistor 61a is turned off, the capacity of the FDs in the pixel sharing unit is the sum of the capacity of the FD 52a of the imaging pixel 31a and the capacity of the FD 52a of the phase difference detection pixel 32a.

Also, in a case where, while the respective transfer transistors 51a of the imaging pixel 31a and the phase difference detection pixel 32a are on, one of the reset transistors 53a of the imaging pixel 31a and the phase difference detection pixel 32a is turned on, and the conversion efficiency switching transistor 61a is turned off, the capacity of the FDs in the pixel sharing unit is the capacity obtained by adding the gate capacity of the turned-on reset transistor 53a and the capacity of the drain portion to the capacity of the FD 52a of the imaging pixel 31a and the capacity of the FD 52a of the phase difference detection pixel 32a. With this arrangement, conversion efficiency can be made lower than in the case described above.

Further, in a case where, while the respective transfer transistors 51a of the imaging pixel 31a and the phase difference detection pixel 32a are on, the respective reset transistors 53a of the imaging pixel 31a and the phase difference detection pixel 32a are turned on, and the conversion efficiency switching transistor 61a is turned off, the capacity of the FDs in the pixel sharing unit is the capacity obtained by adding the gate capacity of the respective reset transistors 53a of the imaging pixel 31a and the phase difference detection pixel 32a, and the capacity of the drain portion to the capacity of the FD 52a of the imaging pixel 31a and the capacity of the FD 52a of the phase difference detection pixel 32a. With this arrangement, conversion efficiency can be made even lower than in the case described above.

Note that, in a case where the respective reset transistors 53a of the imaging pixel 31a and the phase difference detection pixel 32a are turned on, and the conversion efficiency switching transistor 61a is also turned on, the electric charges accumulated in the FDs 52a are reset.

Also, in this example, the FDs 52a (the sources of the reset transistors 53a) are formed to be surrounded by a device separation region formed by shallow trench isolation (STI).

Further, in this example, as shown in FIG. 70, the transfer transistor 51a of each pixel is formed at a corner of the photoelectric conversion unit formed in a rectangular shape in each pixel. With such a configuration, the device separation area in one pixel cell becomes smaller, and the area of each photoelectric conversion unit can be increased. Accordingly, even in a case where the photoelectric conversion unit is divided into two in one pixel cell as in the phase difference detection pixel 32a, designing can be advantageously performed in view of a saturation charge amount Qs.

In the description below, solid-state imaging devices of embodiments (first to eleventh embodiments) according to the present technology are explained specifically and in detail.

### 2. First Embodiment (Example 1 of a Solid-State Imaging Device)

A solid-state imaging device of a first embodiment (Example 1 of a solid-state imaging device) according to the present technology includes a plurality of imaging pixels that is orderly arranged in accordance with a certain pattern, and the imaging pixels each include at least a semiconductor substrate in which a photoelectric conversion unit is formed, and a filter that transmits certain light and is formed on the light incidence face side of the semiconductor substrate. At least one of the plurality of imaging pixels is replaced with a ranging pixel having a filter that transmits certain light, so that at least one ranging pixel is formed. A partition wall is formed between the filter of the at least one ranging pixel and the filters adjacent to the filter of the at least one ranging pixel. The partition wall contains substantially the same material as the material of the filter of the at least one imaging pixel replaced with the ranging pixel. That is, the partition wall contains a material that is substantially the same as the material forming the filter of the imaging pixel replaced by the ranging pixel.

Further, the partition wall may be formed so as to surround at least one ranging pixel.

The filter included in the ranging pixel may be designed to contain one of the materials of a color filter that transmits light in a specific wavelength band, a transparent film, a silicon oxide film that forms on-chip lenses, and the like. Further, the filter included in the ranging pixel may contain a material that transmits infrared light, ultraviolet light, red light, blue light, green light, white light, cyan light, magenta light, or yellow light.

With the solid-state imaging device of the first embodiment according to the present technology, it is possible to reduce color mixing between pixels, and reduce the difference between color mixing from a ranging pixel and color mixing from regular pixels (imaging pixels). It is also possible to block stray light entering from the invalid regions of microlenses, and improve imaging characteristics. Further, with the solid-state imaging device of the first embodiment according to the present technology, it is possible to improve the characteristics of flare and unevenness by eliminating color mixing between the pixels, and form the partition wall by lithography at the same time as the formation of the pixels without an increase in cost. Thus, a decrease in device sensitivity can be made smaller than that with a light blocking wall formed with a metal film.

Referring now to FIG. 1, a solid-state imaging device of the first embodiment according to the present technology is described.

FIG. 1(a) is a top view (planar layout diagram) of 16 pixels of a solid-state imaging device 1-1. FIG. 1(b) is a cross-sectional view of five pixels of the solid-state imaging device 1-1, taken along the A-A′ line, the B-B′ line, and the C-C′ line shown in FIG. 1(a). Of the five pixels, each one pixel on the leftmost position in FIG. 1(b) is not shown in FIG. 1(a). FIGS. 2(a) and 2(b) to FIGS. 7(a) and 7(b), which will be described later, also show similar configurations.

In the solid-state imaging device 1-1, a plurality of imaging pixels is formed with pixels each having a filter that transmits blue light, pixels each having a filter that transmits green light, and pixels each having a filter that transmits red light, and the plurality of imaging pixels is orderly arranged in accordance with the Bayer array. Each filter has a rectangular shape (which may be a square) in which four vertices are substantially rounded off (the four corners are almost at right angles) in a plan view. The distance between filters adjacent to each other in a diagonal direction is longer than the distance between filters adjacent to each other in a lateral or vertical direction. Further, the solid-state imaging device 1-1 includes at least microlenses (not shown in FIG. 1), filters 7, 8, and others, a planarizing film 3, an interlayer film (oxide film) 2, a semiconductor substrate (not shown in FIG. 1) in which photoelectric conversion units (photodiodes, for example) are formed, and a wiring layer (not shown), in this order from the light incident side. A ranging pixel may be an image-plane phase difference pixel, for example, but is not necessarily an image-plane phase difference pixel. A ranging pixel may be a pixel that acquires distance information using time-of-flight (TOF) technology, an infrared light receiving pixel, a pixel that receives light of a narrowband wavelength that can be used for specific purposes, a pixel that measures changes in luminance, or the like.

At least one pixel having a filter 8 that transmits blue light is replaced with a ranging pixel having a filter 7 that transmits cyan light, for example. In this manner, a ranging pixel is formed. The selection of the imaging pixels to be replaced with ranging pixels may be patterned or at random. A partition wall 9 is formed between the filter 7 of a ranging pixel and the four filters that transmit green light and are adjacent to the filter of the ranging pixel, so that the partition wall 9 surrounds the ranging pixel. The partition wall 9 includes the same material as the filters that transmit blue light. On the lower side of the partition wall 9 (the lower side in FIG. 1, and the side opposite from the light incident side), a partition wall 4 formed with a light-absorbing resin film containing a carbon black pigment or a titanium black pigment is formed, for example. That is, the partition walls in the solid-state imaging device 1-1 include the partition wall 9 as a first layer and the partition wall 4 as a second layer in this order from the light incident side, and is formed in a grid-like pattern when viewed in a plan view (in a planar layout diagram viewed from the filter surface on the light incident side).

As shown in FIG. 1(b), a first light blocking film 101 and a second light blocking film 102 or 103 are formed in the interlayer film (oxide film) 2, in this order from the light incident side. In FIG. 1(b), the second light blocking film 102 extends in the leftward direction with respect to the first light blocking film 101, so as to block the light to be received by the right half of a ranging pixel 7 that is the first pixel from the left. In FIG. 1(b), the second light blocking film 103 extends in the rightward direction with respect to the first light blocking film 101, so as to block the light to be received by the left half of a ranging pixel 7 that is the third pixel from the left. The first light blocking film 101, the second light blocking film 102, and the second light blocking film 103 may be insulating films or metal films, for example. The insulating films may be formed with silicon oxide films, silicon nitride films, silicon oxynitride films, or the like, for example. The metal films may be formed with tungsten, aluminum, copper, or the like, for example.

Next, a method for manufacturing the solid-state imaging device of the first embodiment (Example 1 of a solid-state imaging device) according to the present technology is described, with reference to FIGS. 2 to 7.

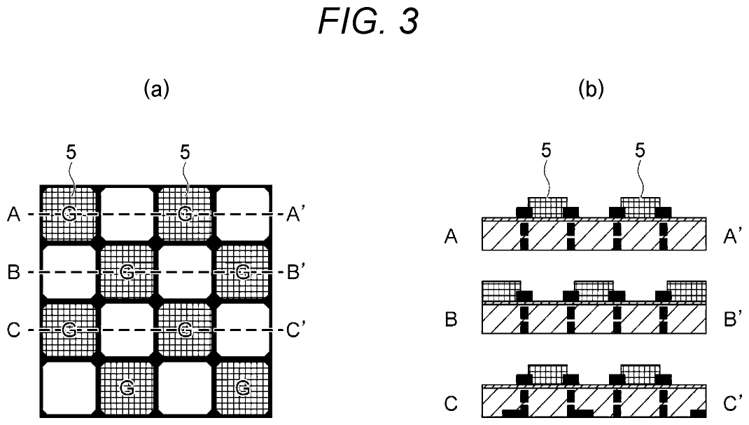

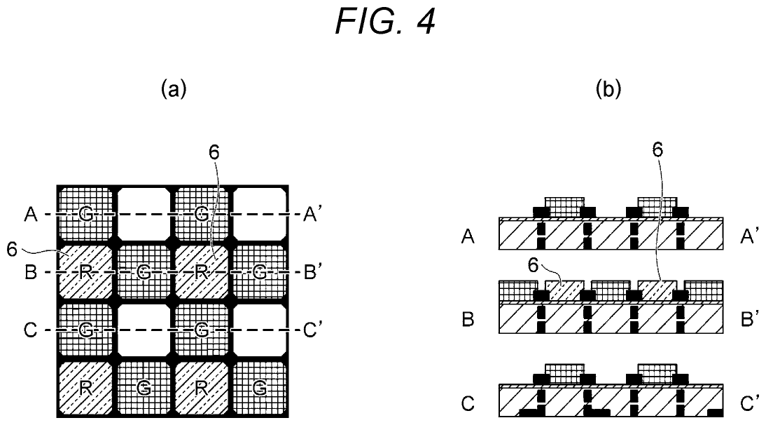

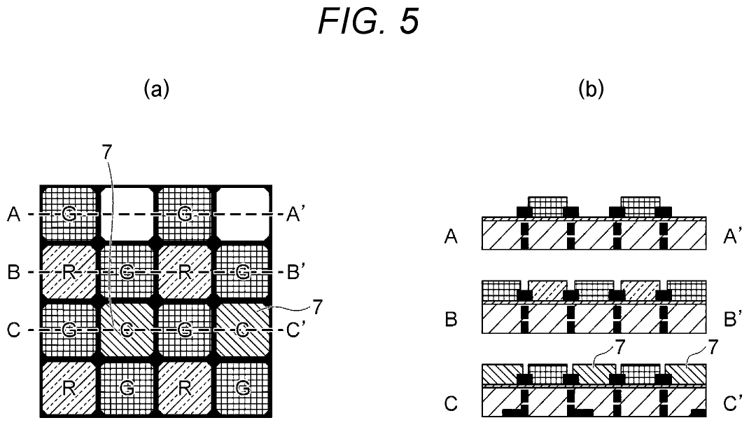

The method for manufacturing the solid-state imaging device of the first embodiment according to the present technology includes: forming a grid-like black resist pattern 4 so that filters each having a rectangular shape (which may be a square) in which the four vertices are substantially rounded off (the four corners are at almost right angles) in a plan view are formed, as shown in FIG. 2; forming a resist pattern of filters (green filters) (imaging images) 5 that transmit green light, as shown in FIG. 3; forming a resist pattern of filters (red filters) (imaging images) 6 that transmit red light, as shown in FIG. 4; and forming a resist pattern of filters (cyan filters) (ranging images) 7 that transmit cyan light, as shown in FIG. 5.

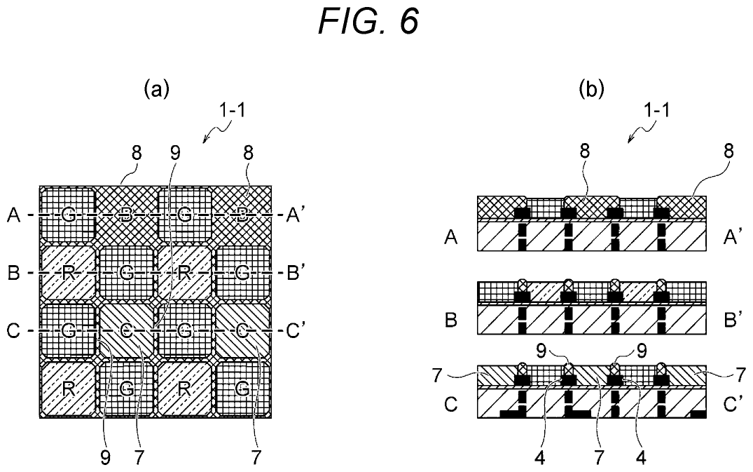

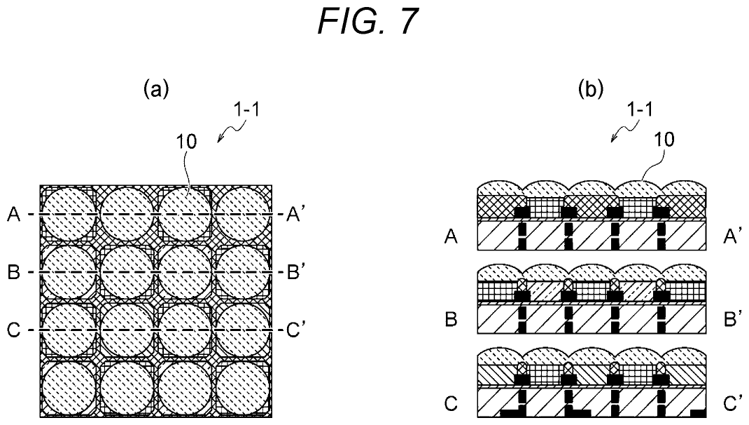

A grid-like blue resist pattern 9 and a resist pattern 8 of filters (blue filters) (imaging images) that transmit blue light are then formed, as shown in FIG. 6. Lastly, microlenses 10 are formed on the filters (on the light incident side), as shown in FIG. 7. The partition walls are formed with the first layer 9 and the second layer 4 in this order from the light incident side. The first layer 9 is formed with a blue wall (a grid-like blue wall), and the second layer 4 is formed with a black wall (a grid-like black wall).

In addition to the contents described above, the contents that will be explained below in the descriptions of solid-state imaging devices of second to eleventh embodiments according to the present technology described later can be applied, without any change, to the solid-state imaging device of the first embodiment according to the present technology, unless there is some technical contradiction.

### 3. Second Embodiment (Example 2 of a Solid-State Imaging Device)

A solid-state imaging device of a second embodiment (Example 2 of a solid-state imaging device) according to the present technology includes a plurality of imaging pixels that is orderly arranged in accordance with a certain pattern, and the imaging pixels each include at least a semiconductor substrate in which a photoelectric conversion unit is formed, and a filter that transmits certain light and is formed on the light incidence face side of the semiconductor substrate. At least one of the plurality of imaging pixels is replaced with a ranging pixel having a filter that transmits certain light, so that at least one ranging pixel is formed. A partition wall is formed between the filter of the at least one ranging pixel and the filters adjacent to the filter of the at least one ranging pixel, so as to surround the at least one ranging pixel. The partition wall contains substantially the same material as the material of the filter of the at least one imaging pixel replaced with the ranging pixel. That is, the partition wall contains a material that is substantially the same as the material forming the filter of the imaging pixel replaced by the ranging pixel.

Further, the partition wall may be formed so as to surround at least one ranging pixel.

The filter included in the ranging pixel may be designed to contain one of the materials of a color filter that transmits light in a specific wavelength band, a transparent film, a silicon oxide film that forms on-chip lenses, and the like. Further, the filter included in the ranging pixel may contain a material that transmits infrared light, ultraviolet light, red light, blue light, green light, white light, cyan light, magenta light, or yellow light.

With the solid-state imaging device of the second embodiment according to the present technology, it is possible to reduce color mixing between pixels, and reduce the difference between color mixing from a ranging pixel and color mixing from regular pixels (imaging pixels). It is also possible to block stray light entering from the invalid regions of microlenses, and improve imaging characteristics. Further, with the solid-state imaging device of the second embodiment according to the present technology, it is possible to improve the characteristics of flare and unevenness by eliminating color mixing between the pixels, and form the partition wall by lithography at the same time as the formation of the pixels without an increase in cost. Thus, a decrease in device sensitivity can be made smaller than that with a light blocking wall formed with a metal film.

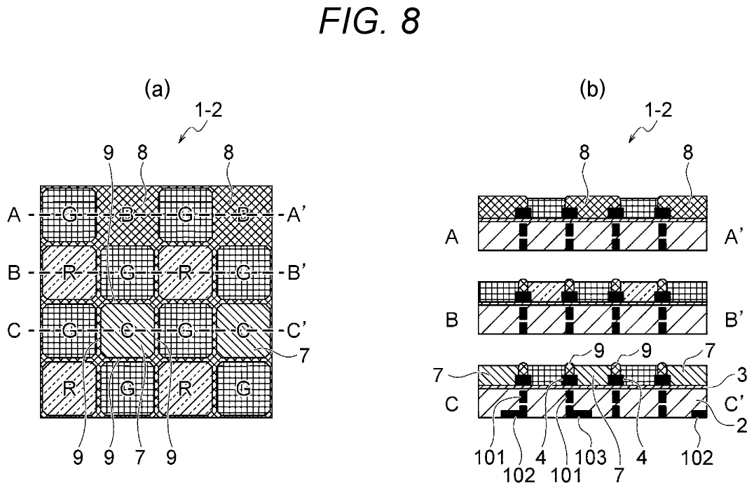

Referring now to FIG. 8, a solid-state imaging device of the second embodiment according to the present technology is described.

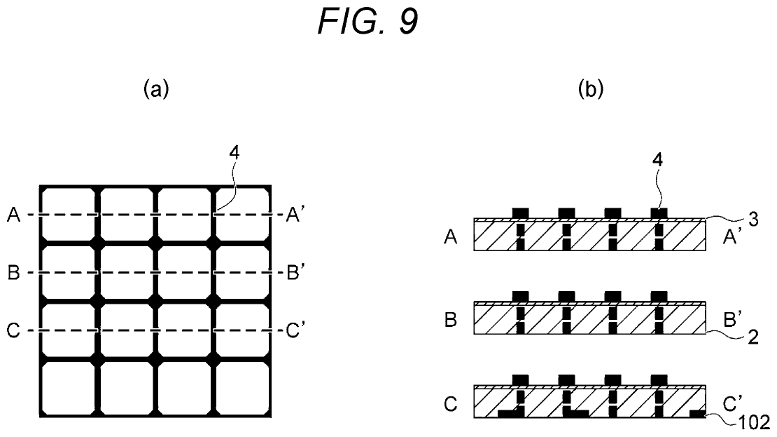

FIG. 8(a) is a top view (planar layout diagram) of 16 pixels of a solid-state imaging device 1-2. FIG. 8(b) is a cross-sectional view of five pixels of the solid-state imaging device 1-2, taken along the A-A′ line, the B-B′ line, and the C-C′ line shown in FIG. 8(a). Of the five pixels, each one pixel on the leftmost position in FIG. 8(b) is not shown in FIG. 8(a). FIGS. 9(a) and 9(b) to FIGS. 14(a) and 14(b), which will be described later, also show similar configurations.

In the solid-state imaging device 1-2, a plurality of imaging pixels is formed with pixels each having a filter that transmits blue light, pixels each having a filter that transmits green light, and pixels each having a filter that transmits red light, and the plurality of imaging pixels is orderly arranged in accordance with the Bayer array. Each filter has a rectangular shape (which may be a square) in which four vertices are substantially rounded off (the four corners are almost at right angles) in a plan view. The distance between filters adjacent to each other in a diagonal direction is longer than the distance between filters adjacent to each other in a lateral or vertical direction. Further, the solid-state imaging device 1-2 includes at least microlenses (not shown in FIG. 2), filters 7, 8, and others, a planarizing film 3, an interlayer film (oxide film) 2, a semiconductor substrate (not shown in FIG. 2) in which photoelectric conversion units (photodiodes, for example) are formed, and a wiring layer (not shown), in this order from the light incident side.

Each pixel having a filter 8 that transmits blue light is replaced with a ranging pixel having a filter 7 that transmits cyan light. In this manner, ranging pixels are formed. A partition wall 9 is formed between the filter 7 of a ranging pixel and the four filters that transmit green light and are adjacent to the filter of the ranging pixel, so that the partition wall 9 surrounds the ranging pixel. The partition wall 9 includes a material that is the same as the material of the filters that transmit blue light. On the lower side of the partition wall 9 (the lower side in FIG. 1, and the side opposite from the light incident side), a partition wall 4 formed with a light-absorbing resin film containing a carbon black pigment or a titanium black pigment is formed, for example. That is, the partition walls in the solid-state imaging device 1-1 include the partition wall 9 as a first layer and the partition wall 4 as a second layer in this order from the light incident side, and is formed in a grid-like pattern when viewed in a plan view (in a planar layout diagram viewed from the filter surface on the light incident side).

As shown in FIG. 8(b), a first light blocking film 101 and a second light blocking film 102 or 103 are formed in the interlayer film (oxide film) 2, in this order from the light incident side. In FIG. 8(b), the second light blocking film 102 extends in the leftward direction with respect to the first light blocking film 101, so as to block the light to be received by the right half of a ranging pixel 7 that is the first pixel from the left. In FIG. 8(b), the second light blocking film 103 extends in the rightward direction with respect to the first light blocking film 101, so as to block the light to be received by the left half of a ranging pixel 7 that is the third pixel from the left. The first light blocking film 101, the second light blocking film 102, and the second light blocking film 103 may be metal films, and the metal films may include tungsten, aluminum, copper, or the like, for example.

Next, a method for manufacturing the solid-state imaging device of the second embodiment (Example 2 of a solid-state imaging device) according to the present technology is described, with reference to FIGS. 9 to 14.

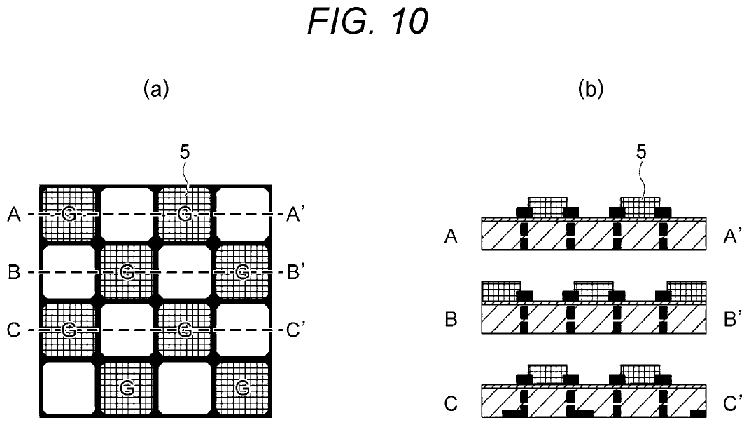

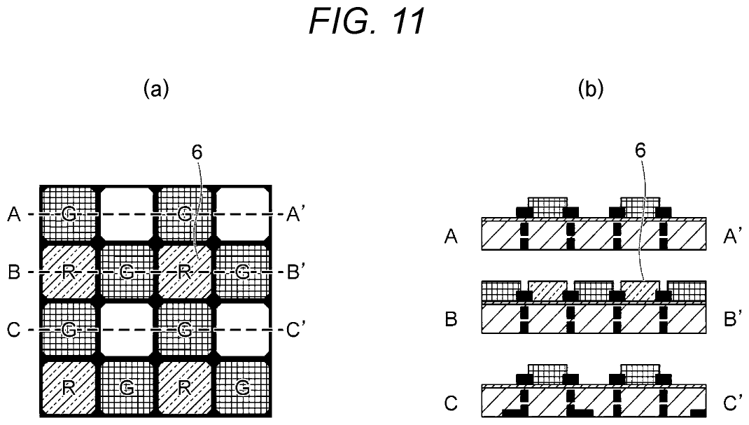

The method for manufacturing the solid-state imaging device of the second embodiment according to the present technology includes: forming a grid-like black resist pattern 4 so that filters each having a rectangular shape (which may be a square) in which the four vertices are substantially rounded off (the four corners are at almost right angles) in a plan view are formed, as shown in FIG. 9; forming a resist pattern of filters (green filters) (imaging images) 5 that transmit green light, as shown in FIG. 10; and forming a resist pattern of filters (red filters) (imaging images) 6 that transmit red light, as shown in FIG. 11.

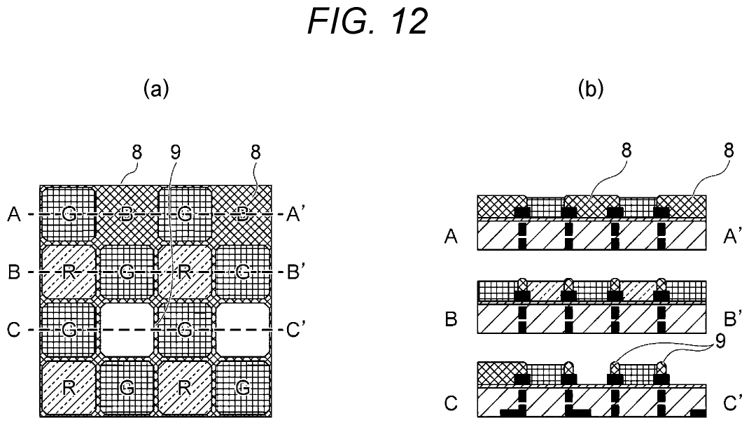

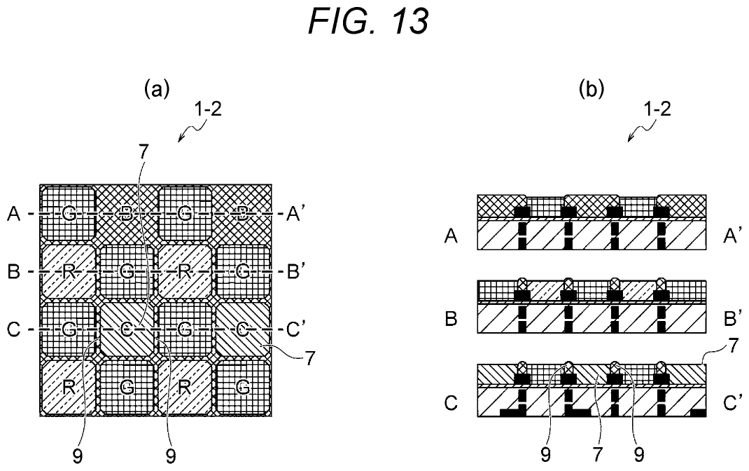

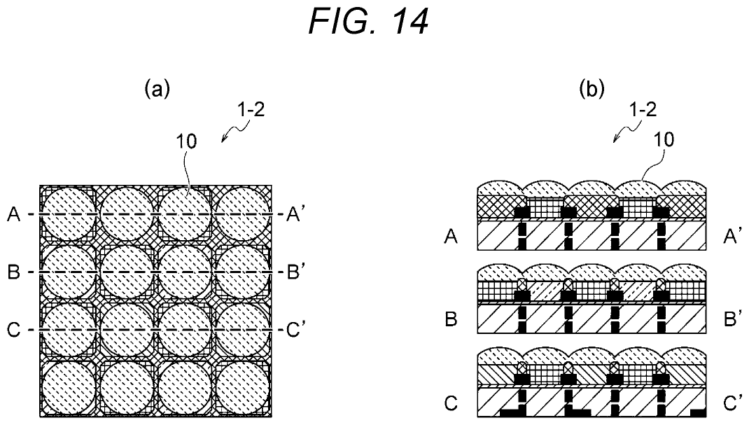

A grid-like blue resist pattern 9 and a resist pattern of filters (blue filters) (imaging images) 8 that transmit blue light are then formed, as shown in FIG. 12. A resist pattern of filters (cyan filters) (ranging images) 7 that transmit cyan light is then formed, as shown in FIG. 13. Lastly, microlenses 10 are formed on the filters (on the light incident side), as shown in FIG. 14. The partition walls are formed with the first layer 9 and the second layer 4 in this order from the light incident side. The first layer 9 is formed with a blue wall (a grid-like blue wall), and the second layer 4 is formed with a black wall (a grid-like black wall).

In addition to the contents described above, the contents described in the description of the solid-state imaging device of the first embodiment according to the present technology and the contents that will be explained below in the description of solid-state imaging devices of third to eleventh embodiments according to the present technology can be applied, without any change, to the solid-state imaging device of the second embodiment according to the present technology, unless there is some technical contradiction.

### 4. Third Embodiment (Example 3 of a Solid-State Imaging Device)

A solid-state imaging device of a third embodiment (Example 3 of a solid-state imaging device) according to the present technology includes a plurality of imaging pixels that is orderly arranged in accordance with a certain pattern, and the imaging pixels each include at least a semiconductor substrate in which a photoelectric conversion unit is formed, and a filter that transmits certain light and is formed on the light incidence face side of the semiconductor substrate. At least one of the plurality of imaging pixels is replaced with a ranging pixel having a filter that transmits certain light, so that at least one ranging pixel is formed. A partition wall is formed between the filter of the at least one ranging pixel and the filters adjacent to the filter of the at least one ranging pixel, so as to surround the at least one ranging pixel. The partition wall contains substantially the same material as the material of the filter of the at least one imaging pixel replaced with the ranging pixel. That is, the partition wall contains a material that is substantially the same as the material forming the filter of the imaging pixel replaced by the ranging pixel. Further, the partition wall may be formed so as to surround at least one ranging pixel.

The filter included in the ranging pixel may be designed to contain one of the materials of a color filter that transmits light in a specific wavelength band, a transparent film, a silicon oxide film that forms on-chip lenses, and the like. Further, the filter included in the ranging pixel may contain a material that transmits infrared light, ultraviolet light, red light, blue light, green light, white light, cyan light, magenta light, or yellow light.

With the solid-state imaging device of the third embodiment according to the present technology, it is possible to reduce color mixing between pixels, and reduce the difference between color mixing from a ranging pixel and color mixing from regular pixels (imaging pixels). It is also possible to block stray light entering from the invalid regions of microlenses, and improve imaging characteristics. Further, with the solid-state imaging device of the third embodiment according to the present technology, it is possible to improve the characteristics of flare and unevenness by eliminating color mixing between the pixels, and form the partition wall by lithography at the same time as the formation of the pixels without an increase in cost. Thus, a decrease in device sensitivity can be made smaller than that with a light blocking wall formed with a metal film.

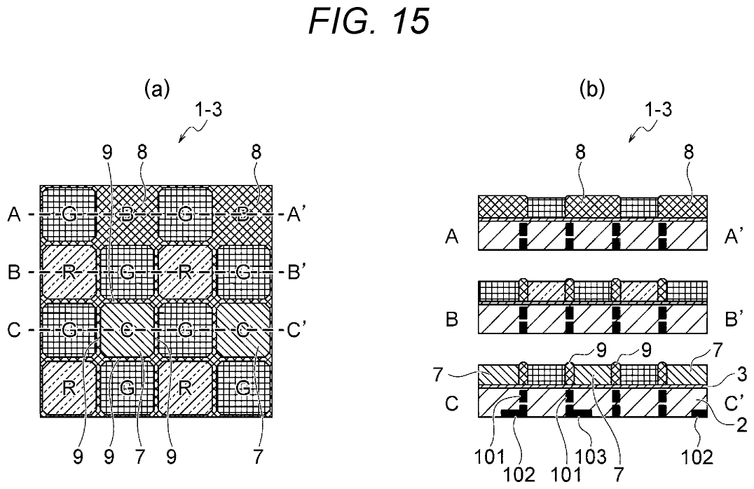

Referring now to FIG. 15, a solid-state imaging device of the third embodiment according to the present technology is described.

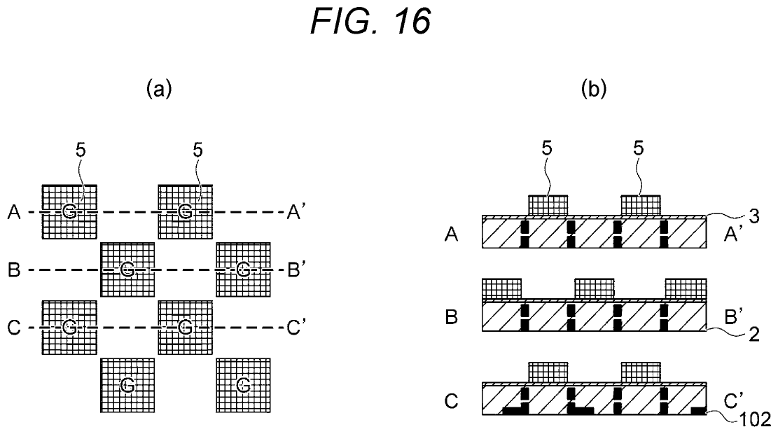

FIG. 15(a) is a top view (planar layout diagram) of 16 pixels of a solid-state imaging device 1-3. FIG. 15(b) is a cross-sectional view of five pixels of the solid-state imaging device 1-3, taken along the A-A′ line, the B-B′ line, and the C-C′ line shown in FIG. 15(a). Of the five pixels, each one pixel on the leftmost position in FIG. 15(b) is not shown in FIG. 15(a). FIGS. 16(a) and 16(b) to FIGS. 20(a) and 20(b), which will be described later, also show similar configurations.

In the solid-state imaging device 1-3, a plurality of imaging pixels is formed with pixels each having a filter that transmits blue light, pixels each having a filter that transmits green light, and pixels each having a filter that transmits red light, and the plurality of imaging pixels is orderly arranged in accordance with the Bayer array. Each filter has a rectangular shape (which may be a square) in which four vertices are substantially rounded off (the four corners are almost at right angles) in a plan view. The distance between filters adjacent to each other in a diagonal direction is longer than the distance between filters adjacent to each other in a lateral or vertical direction. Further, the solid-state imaging device 1-1 includes at least microlenses (not shown in FIG. 15), filters 7, 8, and others, a planarizing film 3, an interlayer film (oxide film) 2, a semiconductor substrate (not shown in FIG. 1) in which photoelectric conversion units (photodiodes, for example) are formed, and a wiring layer (not shown), in this order from the light incident side.

Each pixel having a filter 8 that transmits blue light is replaced with a ranging pixel having a filter 7 that transmits cyan light. In this manner, ranging pixels are formed. A partition wall 9 is formed between the filter 7 of a ranging pixel and the four filters that transmit green light and are adjacent to the filter of the ranging pixel, so that the partition wall 9 surrounds the ranging pixel. The partition wall 9 includes a material that is the same as the material of the filters that transmit blue light. That is, the partition wall in the solid-state imaging device 1-3 is formed with the partition wall 9 as a first layer, and is formed in a grid-like pattern when viewed in a plan view (in a planar layout diagram viewed from the filter surface on the light incident side).

As shown in FIG. 15(b), a first light blocking film 101 and a second light blocking film 102 or 103 are formed in the interlayer film (oxide film) 2, in this order from the light incident side. In FIG. 15(b), the second light blocking film 102 extends in the leftward direction with respect to the first light blocking film 101, so as to block the light to be received by the right half of a ranging pixel 7 that is the first pixel from the left. In FIG. 15(b), the second light blocking film 103 extends in the rightward direction with respect to the first light blocking film 101, so as to block the light to be received by the left half of a ranging pixel 7 that is the third pixel from the left. The first light blocking film 101, the second light blocking film 102, and the second light blocking film 103 may be metal films, and the metal films may include tungsten, aluminum, copper, or the like, for example.

Next, a method for manufacturing the solid-state imaging device of the third embodiment (Example 3 of a solid-state imaging device) according to the present technology is described, with reference to FIGS. 16 to 20.

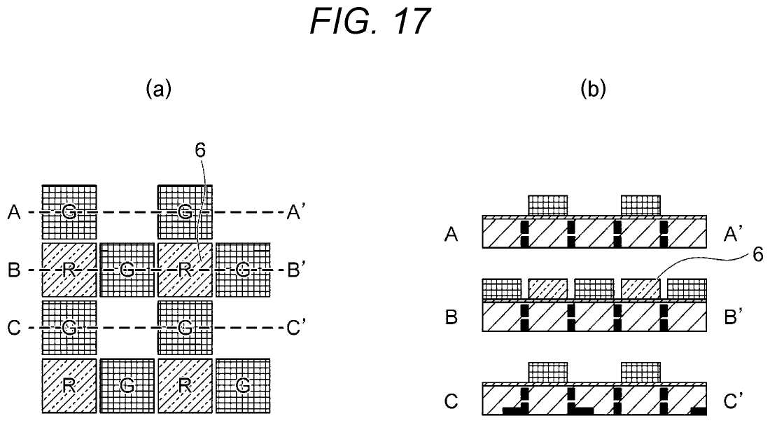

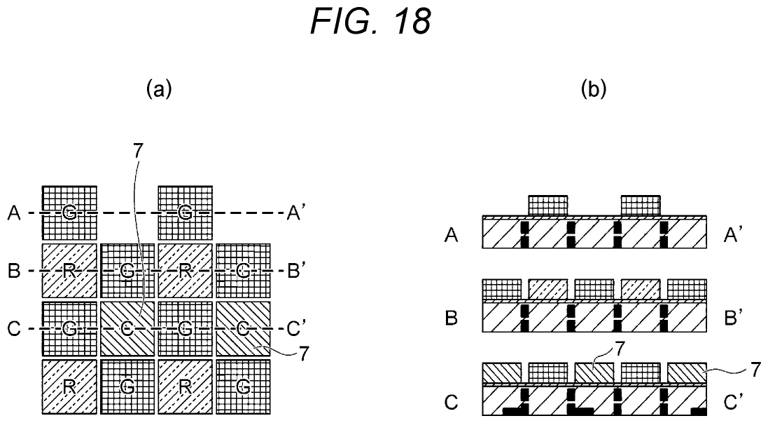

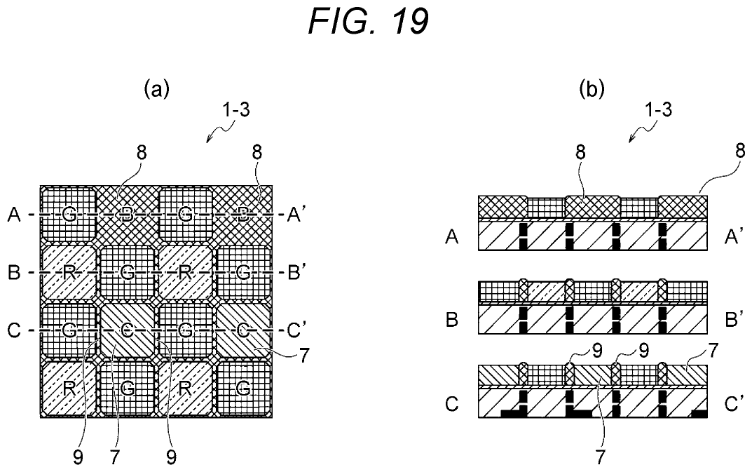

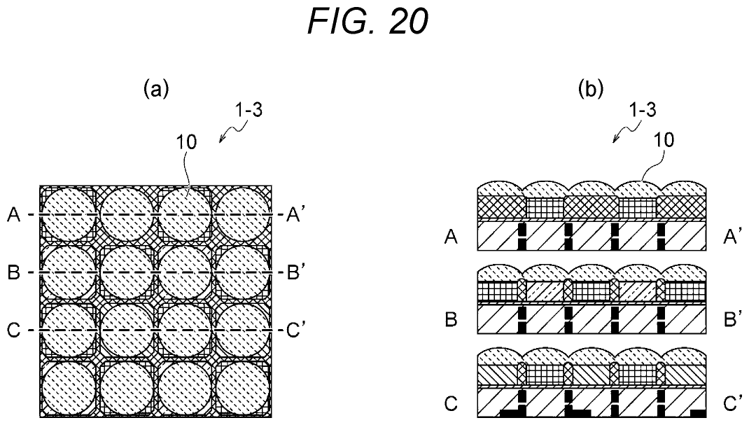

The method for manufacturing the solid-state imaging device of the third embodiment according to the present technology includes: forming a resist pattern of filters (green filters) (imaging images) 5 that transmit green light, as shown in FIG. 16; forming a resist pattern of filters (red filters) (imaging images) 6 that transmit red light, as shown in FIG. 17; forming a resist pattern of filters (cyan filters) (ranging images) 7 that transmit cyan light, as shown in FIG. 18; forming a grid-like blue resist pattern 9 and a resist pattern of filters (blue filters) (imaging images) 8 that transmit blue light, as shown in FIG. 19; and, lastly, forming microlenses 10 on the filters (on the light incident side), as shown in FIG. 20. The partition wall is formed with the first layer, and the first layer is formed with a blue wall (a grid-like blue wall).

In addition to the contents described above, the contents described in the descriptions of the solid-state imaging devices of the first and second embodiments according to the present technology and the contents that will be explained below in the description of solid-state imaging devices of fourth to eleventh embodiments according to the present technology can be applied, without any change, to the solid-state imaging device of the third embodiment according to the present technology, unless there is some technical contradiction.

### 5. Fourth Embodiment (Example 4 of a Solid-State Imaging Device)

A solid-state imaging device of a fourth embodiment (Example 4 of a solid-state imaging device) according to the present technology includes a plurality of imaging pixels that is orderly arranged in accordance with a certain pattern, and the imaging pixels each include at least a semiconductor substrate in which a photoelectric conversion unit is formed, and a filter that transmits certain light and is formed on the light incidence face side of the semiconductor substrate. At least one of the plurality of imaging pixels is replaced with a ranging pixel having a filter that transmits certain light, so that at least one ranging pixel is formed. A partition wall is formed between the filter of the at least one ranging pixel and the filters adjacent to the filter of the at least one ranging pixel, so as to surround the at least one ranging pixel. The partition wall contains substantially the same material as the material of the filter of the at least one imaging pixel replaced with the ranging pixel. That is, the partition wall contains a material that is substantially the same as the material forming the filter of the imaging pixel replaced by the ranging pixel. Further, the partition wall is formed so as to surround at least one ranging pixel.

The filter included in the ranging pixel may be designed to contain one of the materials of a color filter that transmits light in a specific wavelength band, a transparent film, a silicon oxide film that forms on-chip lenses, and the like. Further, the filter included in the ranging pixel may contain a material that transmits infrared light, ultraviolet light, red light, blue light, green light, white light, cyan light, magenta light, or yellow light.

With the solid-state imaging device of the fourth embodiment according to the present technology, it is possible to reduce color mixing between pixels, and reduce the difference between color mixing from a ranging pixel and color mixing from regular pixels (imaging pixels). It is also possible to block stray light entering from the invalid regions of microlenses, and improve imaging characteristics. Further, with the solid-state imaging device of the fourth embodiment according to the present technology, it is possible to improve the characteristics of flare and unevenness by eliminating color mixing between the pixels, and form the partition wall by lithography at the same time as the formation of the pixels without an increase in cost. Thus, a decrease in device sensitivity can be made smaller than that with a light blocking wall formed with a metal film.

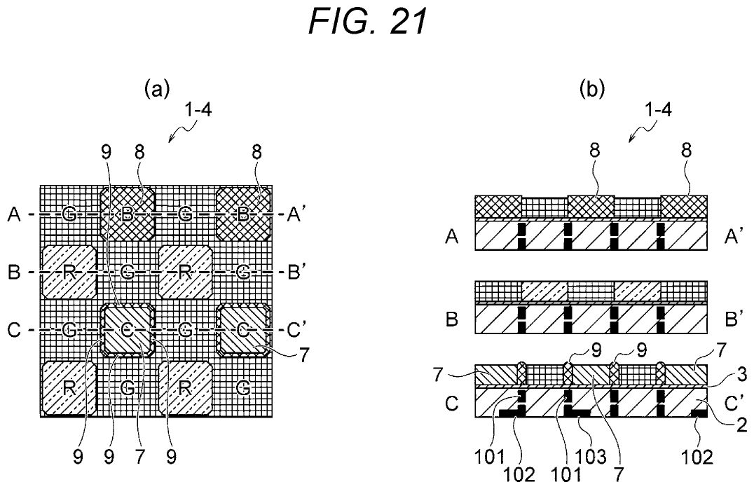

Referring now to FIG. 21, a solid-state imaging device of the fourth embodiment according to the present technology is described.

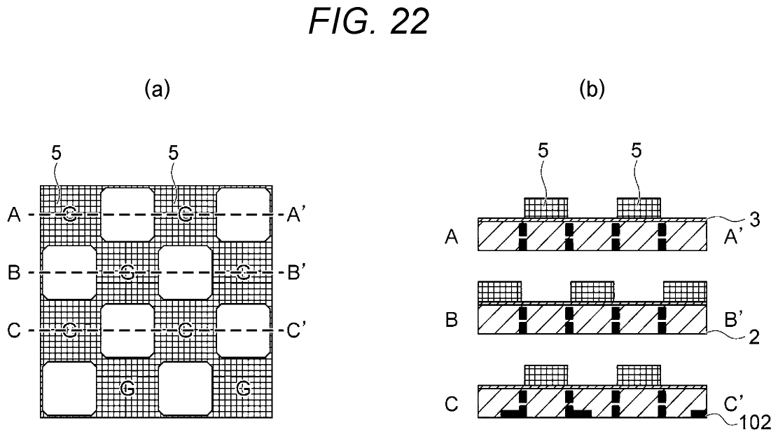

FIG. 21(a) is a top view (planar layout diagram) of 16 pixels of a solid-state imaging device 1-4. FIG. 21(b) is a cross-sectional view of five pixels of the solid-state imaging device 1-4, taken along the A-A′ line, the B-B′ line, and the C-C′ line shown in FIG. 21(a). Of the five pixels, each one pixel on the leftmost position in FIG. 21(b) is not shown in FIG. 21(a). FIGS. 22(a) and 22(b) to FIGS. 26(a) and 26(b), which will be described later, also show similar configurations.

In the solid-state imaging device 1-4, a plurality of imaging pixels is formed with pixels each having a filter that transmits blue light, pixels each having a filter that transmits green light, and pixels each having a filter that transmits red light, and the plurality of imaging pixels is orderly arranged in accordance with the Bayer array. Each filter has a rectangular shape (which may be a square) in which four vertices are substantially rounded off (the four corners are almost at right angles) in a plan view. The distance between filters adjacent to each other in a diagonal direction is longer than the distance between filters adjacent to each other in a lateral or vertical direction. Further, the solid-state imaging device 1-1 includes at least microlenses (not shown in FIG. 21), filters 7, 8, and others, a planarizing film 3, an interlayer film (oxide film) 2, a semiconductor substrate (not shown in FIG. 21) in which photoelectric conversion units (photodiodes, for example) are formed, and a wiring layer (not shown), in this order from the light incident side.

Each pixel having a filter 8 that transmits blue light is replaced with a ranging pixel having a filter 7 that transmits cyan light. In this manner, ranging pixels are formed. A partition wall 9 is formed between the filter 7 of a ranging pixel and the four filters that transmit green light and are adjacent to the filter of the ranging pixel, so that the partition wall 9 surrounds the ranging pixel. The partition wall 9 includes a material that is the same as the material of the filters that transmit blue light. That is, the partition wall in the solid-state imaging device 1-4 is formed with the partition wall 9 of the first layer in this order from the light incident side. The partition wall 9 is not formed in a grid-like pattern, but is formed so as to surround only the ranging pixels 7.

As shown in FIG. 21(b), a first light blocking film 101 and a second light blocking film 102 or 103 are formed in the interlayer film (oxide film) 2, in this order from the light incident side. In FIG. 21(b), the second light blocking film 102 extends in the leftward direction with respect to the first light blocking film 101, so as to block the light to be received by the right half of a ranging pixel 7 that is the first pixel from the left. In FIG. 21(b), the second light blocking film 103 extends in the rightward direction with respect to the first light blocking film 101, so as to block the light to be received by the left half of a ranging pixel 7 that is the third pixel from the left. The first light blocking film 101, the second light blocking film 102, and the second light blocking film 103 may be metal films, and the metal films may include tungsten, aluminum, copper, or the like, for example.

Next, a method for manufacturing the solid-state imaging device of the fourth embodiment (Example 4 of a solid-state imaging device) according to the present technology is described, with reference to FIGS. 22 to 26.

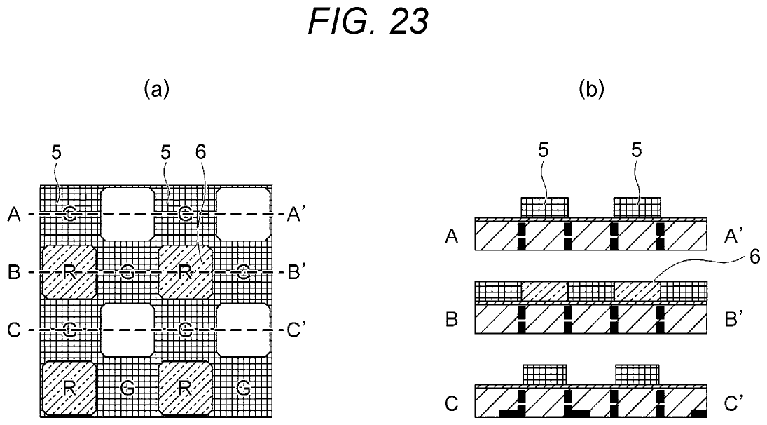

The method for manufacturing the solid-state imaging device of the fourth embodiment according to the present technology includes: first forming a resist pattern of filters (green filters) (imaging images) 5 that transmit green light, as shown in FIG. 22; and forming a resist pattern of filters (red filters) (imaging images) 6 that transmit red light, as shown in FIG. 23.

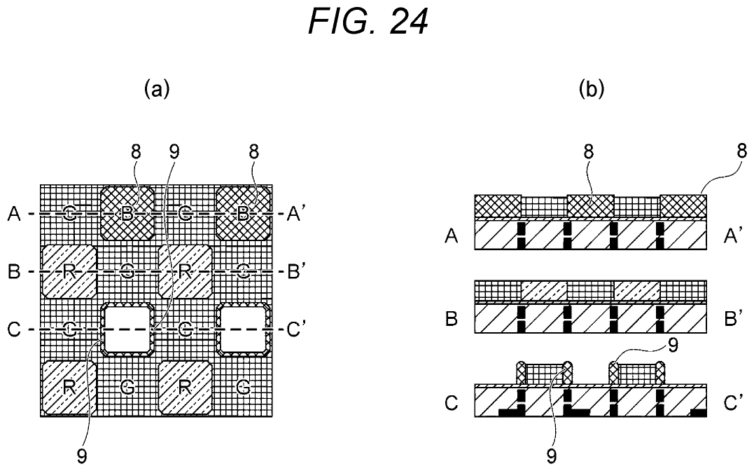

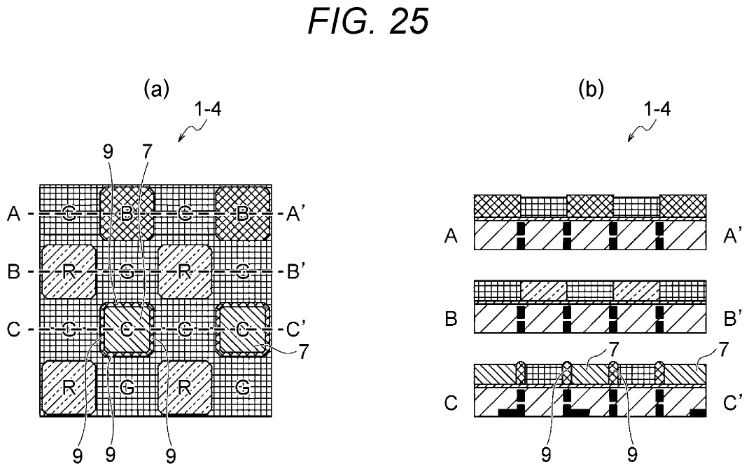

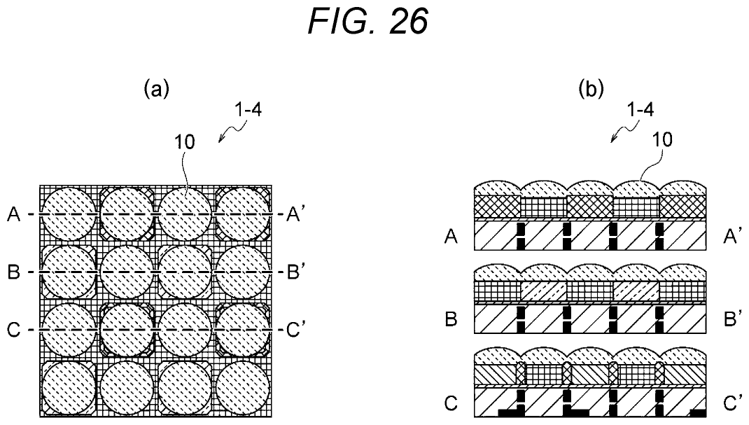

A frame-like blue resist pattern 9 (no filters are formed in the portion surrounded by a blue material) and a resist pattern of filters (blue filters) (imaging images) 8 that transmit blue light are formed, as shown in FIG. 24. A resist pattern of filters (cyan filters) (ranging images) 7 that transmit cyan light is then formed in the portion of the frame-like resist pattern of blue filters 9, as shown in FIG. 25. Lastly, microlenses are formed on the filters (on the light incident side), as shown in FIG. 26. The partition wall is formed with the first layer, and the first layer is formed with a blue wall (a grid-like blue wall).

In addition to the contents described above, the contents described in the descriptions of the solid-state imaging devices of the first to third embodiments according to the present technology and the contents that will be explained below in the description of solid-state imaging devices of fifth to eleventh embodiments according to the present technology can be applied, without any change, to the solid-state imaging device of the fourth embodiment according to the present technology, unless there is some technical contradiction.

### 6. Fifth Embodiment (Example 5 of a Solid-State Imaging Device)

A solid-state imaging device of a fifth embodiment (Example 5 of a solid-state imaging device) according to the present technology includes a plurality of imaging pixels that is orderly arranged in accordance with a certain pattern, and the imaging pixels each include at least a semiconductor substrate in which a photoelectric conversion unit is formed, and a filter that transmits certain light and is formed on the light incidence face side of the semiconductor substrate. At least one of the plurality of imaging pixels is replaced with a ranging pixel having a filter that transmits certain light, so that at least one ranging pixel is formed. A partition wall is formed between the filter of the at least one ranging pixel and the filters adjacent to the filter of the at least one ranging pixel, so as to surround the at least one ranging pixel. The partition wall contains substantially the same material as the material of the filter of the at least one imaging pixel replaced with the ranging pixel. That is, the partition wall contains a material that is substantially the same as the material forming the filter of the imaging pixel replaced by the ranging pixel. Further, the partition wall may be formed so as to surround at least one ranging pixel.

The filter included in the ranging pixel may be designed to contain one of the materials of a color filter that transmits light in a specific wavelength band, a transparent film, a silicon oxide film that forms on-chip lenses, and the like. Further, the filter included in the ranging pixel may contain a material that transmits infrared light, ultraviolet light, red light, blue light, green light, white light, cyan light, magenta light, or yellow light.

With the solid-state imaging device of the fifth embodiment according to the present technology, it is possible to reduce color mixing between pixels, and reduce the difference between color mixing from a ranging pixel and color mixing from regular pixels (imaging pixels). It is also possible to block stray light entering from the invalid regions of microlenses, and improve imaging characteristics. Further, it is possible to improve the characteristics of flare and unevenness by eliminating color mixing between the pixels, and form the partition wall by lithography at the same time as the formation of the pixels without an increase in cost. Thus, a decrease in device sensitivity can be made smaller than that with a light blocking wall formed with a metal film.

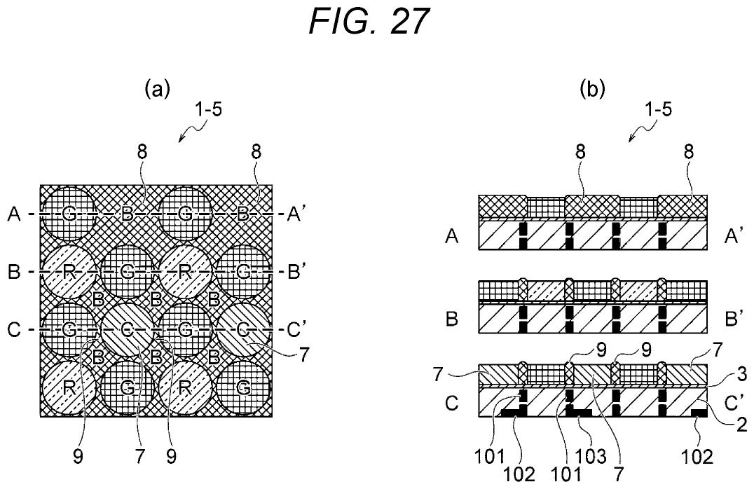

Referring now to FIG. 27, a solid-state imaging device of the fifth embodiment according to the present technology is described.

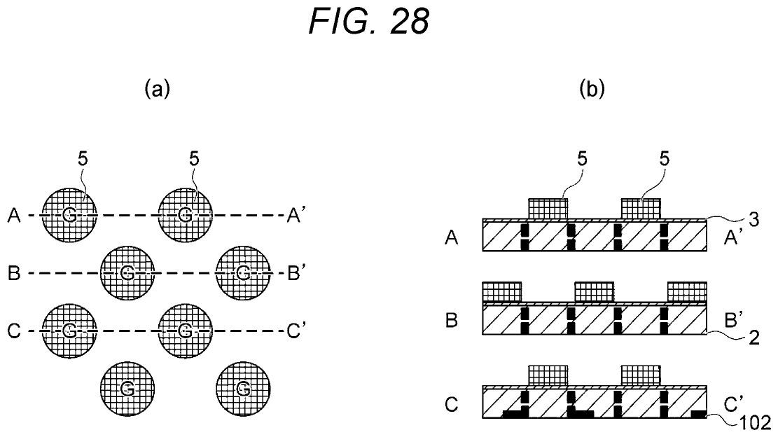

FIG. 27(a) is a top view (planar layout diagram) of 16 pixels of a solid-state imaging device 1-5. FIG. 27(b) is a cross-sectional view of five pixels of the solid-state imaging device 1-5, taken along the A-A′ line, the B-B′ line, and the C-C′ line shown in FIG. 27(a). Of the five pixels, each one pixel on the leftmost position in FIG. 27(b) is not shown in FIG. 27(a). FIGS. 28(a) and 28(b) to FIGS. 32(a) and 32(b), which will be described later, also show similar configurations.

In the solid-state imaging device 1-5, a plurality of imaging pixels is formed with pixels each having a filter that transmits blue light, pixels each having a filter that transmits green light, and pixels each having a filter that transmits red light, and the plurality of imaging pixels is orderly arranged in accordance with the Bayer array. Each filter has a circular shape in a plan view (a planar layout diagram of the filter viewed from the light incident side). The distance between filters adjacent to each other in a diagonal direction is longer than the distance between filters adjacent to each other in a lateral or vertical direction. Meanwhile, the average distance between circular filters adjacent to each other in a diagonal direction is longer than the average distance between rectangular filters (the filters used in the first embodiment, for example) adjacent to each other in a diagonal direction, and the average distance between circular filters adjacent to each other in a lateral or vertical direction is longer than the average distance between rectangular filters adjacent to each other in a lateral or vertical direction. Further, the solid-state imaging device 1-5 includes at least microlenses (not shown in FIG. 27), filters 7, 8, and others, a planarizing film 3, an interlayer film (oxide film) 2, a semiconductor substrate (not shown in FIG. 27) in which photoelectric conversion units (photodiodes, for example) are formed, and a wiring layer (not shown in FIG. 27), in this order from the light incident side.

Each pixel having a filter 8 that transmits blue light is replaced with a ranging pixel having a filter 7 that transmits cyan light. In this manner, ranging pixels are formed. A partition wall 9 is formed between the filter 7 of a ranging pixel and the four filters that transmit green light and are adjacent to the filter of the ranging pixel, so that the partition wall 9 surrounds the ranging pixel. The partition wall 9 includes a material that is the same as the material of the filters that transmit blue light. That is, the partition wall in the solid-state imaging device 1-5 is formed with the partition wall 9 as a first layer, and is formed in a circular grid-like pattern when viewed in a plan view (in a planar layout diagram viewed from the filter surface on the light incident side).

As shown in FIG. 27(b), a first light blocking film 101 and a second light blocking film 102 or 103 are formed in the interlayer film (oxide film) 2, in this order from the light incident side. In FIG. 27(b), the second light blocking film 102 extends in the leftward direction with respect to the first light blocking film 101, so as to block the light to be received by the right half of a ranging pixel 7 that is the first pixel from the left. In FIG. 27(b), the second light blocking film 103 extends in the rightward direction with respect to the first light blocking film 101, so as to block the light to be received by the left half of a ranging pixel 7 that is the third pixel from the left. The first light blocking film 101, the second light blocking film 102, and the second light blocking film 103 may be metal films, and the metal films may include tungsten, aluminum, copper, or the like, for example.

Next, a method for manufacturing the solid-state imaging device of the fifth embodiment (Example 5 of a solid-state imaging device) according to the present technology is described, with reference to FIGS. 28 to 32.

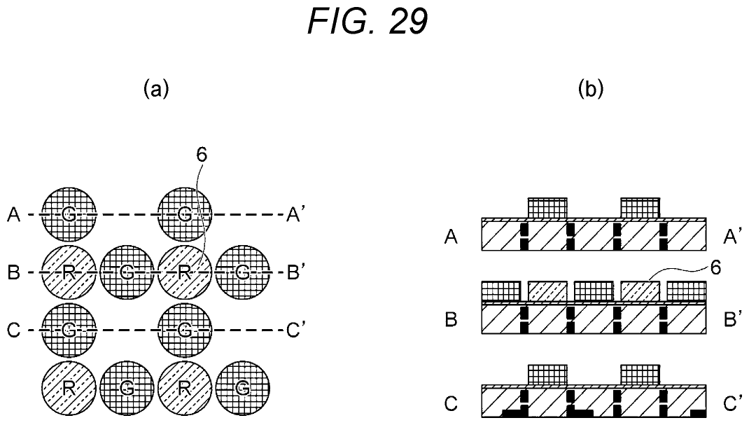

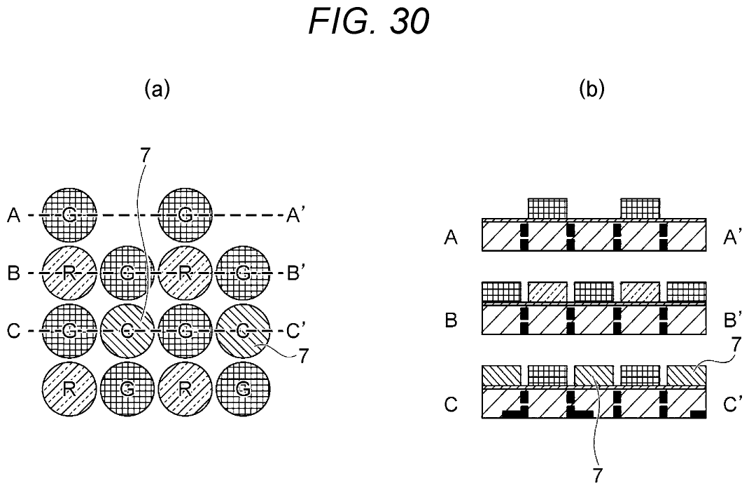

The method for manufacturing the solid-state imaging device of the fifth embodiment according to the present technology includes: forming a resist pattern of filters (green filters) (imaging images) 5 that are circuit in a plan view and transmit green light, as shown in FIG. 28; forming a resist pattern of filters (red filters) (imaging images) 6 that are circular in a plan view and transmit red light, as shown in FIG. 29; and forming a resist pattern of filters (cyan filters) (ranging images) 7 that are circular in a plan view and transmit cyan light, as shown in FIG. 30.

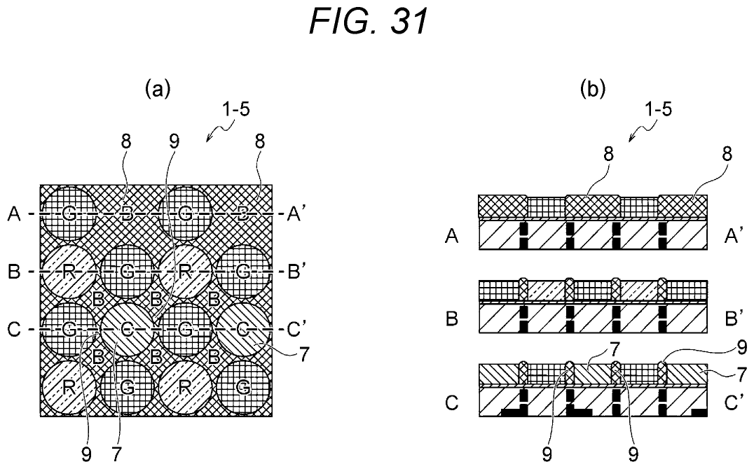

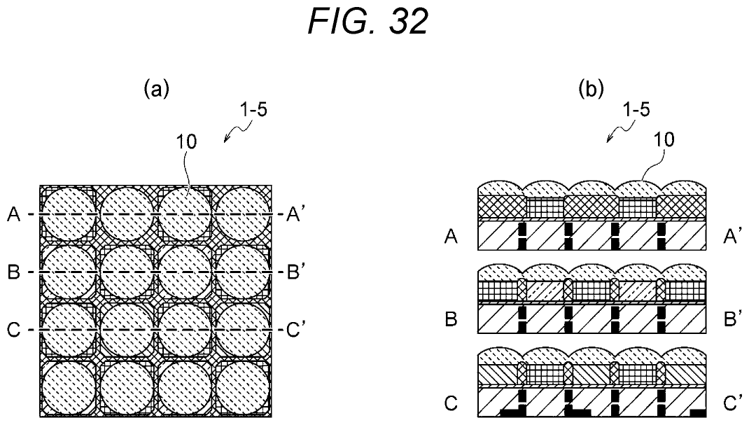

A circular grid-like blue resist pattern 9 (filters that are circular in a plan view and transmit cyan light are surrounded by a blue material) and a resist pattern of filters (blue filters) (imaging images) 8 that transmit blue light are formed, as shown in FIG. 31. Lastly, microlenses are formed on the filters (on the light incident side), as shown in FIG. 32. The partition wall is formed with the first layer, and the first layer is formed with a blue wall (a grid-like blue wall).

In addition to the contents described above, the contents described in the descriptions of the solid-state imaging devices of the first to fourth embodiments according to the present technology and the contents that will be explained below in the description of solid-state imaging devices of sixth to eleventh embodiments according to the present technology can be applied, without any change, to the solid-state imaging device of the fifth embodiment according to the present technology, unless there is some technical contradiction.

### 7. Sixth Embodiment (Example 6 of a Solid-State Imaging Device)

A solid-state imaging device of a sixth embodiment (Example 6 of a solid-state imaging device) according to the present technology includes a plurality of imaging pixels that is orderly arranged in accordance with a certain pattern, and the imaging pixels each include at least a semiconductor substrate in which a photoelectric conversion unit is formed, and a filter that transmits certain light and is formed on the light incidence face side of the semiconductor substrate. At least one of the plurality of imaging pixels is replaced with a ranging pixel having a filter that transmits certain light, so that at least one ranging pixel is formed. A partition wall is formed between the filter of the at least one ranging pixel and the filters adjacent to the filter of the at least one ranging pixel, so as to surround the at least one ranging pixel. The partition wall contains substantially the same material as the material of the filter of the at least one imaging pixel replaced with the ranging pixel. That is, the partition wall contains a material that is substantially the same as the material forming the filter of the imaging pixel replaced by the ranging pixel. Further, the partition wall may be formed so as to surround at least one ranging pixel.

The filter included in the ranging pixel may be designed to contain one of the materials of a color filter that transmits light in a specific wavelength band, a transparent film, a silicon oxide film that forms on-chip lenses, and the like. Further, the filter included in the ranging pixel may contain a material that transmits infrared light, ultraviolet light, red light, blue light, green light, white light, cyan light, magenta light, or yellow light.

With the solid-state imaging device of the sixth embodiment according to the present technology, it is possible to reduce color mixing between pixels, and reduce the difference between color mixing from a ranging pixel and color mixing from regular pixels (imaging pixels). It is also possible to block stray light entering from the invalid regions of microlenses, and improve imaging characteristics. Further, it is possible to improve the characteristics of flare and unevenness by eliminating color mixing between the pixels, and form the partition wall by lithography at the same time as the formation of the pixels without an increase in cost. Thus, a decrease in device sensitivity can be made smaller than that with a light blocking wall formed with a metal film.

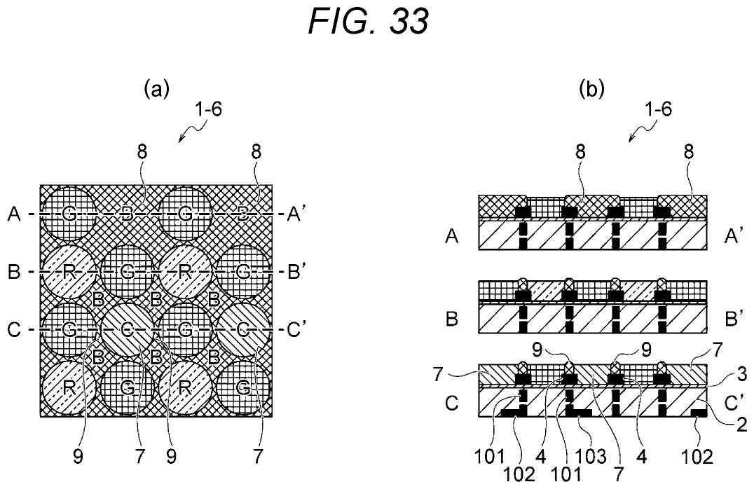

Referring now to FIG. 33, a solid-state imaging device of the sixth embodiment according to the present technology is described.

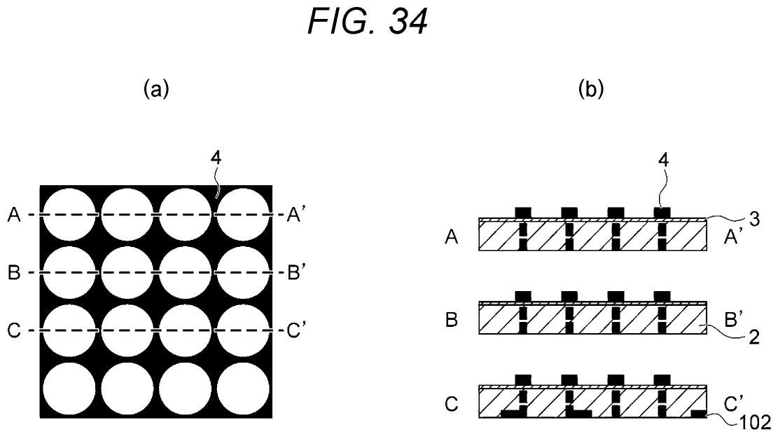

FIG. 33(a) is a top view (planar layout diagram) of 16 pixels of a solid-state imaging device 1-6. FIG. 33(b) is a cross-sectional view of five pixels of the solid-state imaging device 1-6, taken along the A-A′ line, the B-B′ line, and the C-C′ line shown in FIG. 33(a). Of the five pixels, each one pixel on the leftmost position in FIG. 33(b) is not shown in FIG. 33(a). FIGS. 34(a) and 34(b) to FIGS. 39(a) and 39(b), which will be described later, also show similar configurations.

In the solid-state imaging device 1-6, a plurality of imaging pixels is formed with pixels each having a filter that transmits blue light, pixels each having a color filter that transmits green light, and pixels each having a color filter that transmits red light, and the plurality of imaging pixels is orderly arranged in accordance with the Bayer array. Each color filter has a circular shape in a plan view. The distance between color filters adjacent to each other in a diagonal direction is longer than the distance between color filters adjacent to each other in a lateral or vertical direction. Meanwhile, the average distance between circular color filters adjacent to each other in a diagonal direction is longer than the average distance between rectangular color filters (the color filters used in the first embodiment, for example) adjacent to each other in a diagonal direction, and the average distance between circular color filters adjacent to each other in a lateral or vertical direction is longer than the average distance between rectangular color filters adjacent to each other in a lateral or vertical direction. Further, the solid-state imaging device 1-5 includes at least microlenses (not shown in FIG. 33), color filters 7, 8, and others, a planarizing film 3, an interlayer film (oxide film) 2, a semiconductor substrate (not shown in FIG. 33) in which photoelectric conversion units (photodiodes, for example) are formed, and a wiring layer (not shown in FIG. 33), in this order from the light incident side.

Each pixel having a color filter 8 that transmits blue light is replaced with a ranging pixel having a color filter 7 that transmits cyan light. In this manner, ranging pixels are formed. A partition wall 9 is formed between the color filter 7 of a ranging pixel and the four color filters that transmit green light and are adjacent to the color filter of the ranging pixel, so that the partition wall 9 surrounds the ranging pixel. The partition wall 9 includes the same material as the color filters that transmit blue light. On the lower side of the partition wall 9 (the lower side in FIG. 1, and the side opposite from the light incident side), a partition wall 4 formed with a light-absorbing resin film containing a carbon black pigment or a titanium black pigment is formed, for example. That is, the partition walls in the solid-state imaging device 1-6 include the partition wall 9 as a first layer and the partition wall 4 as a second layer in this order from the light incident side, and is formed in a circular grid-like pattern when viewed in a plan view (in a planar layout diagram viewed from the filter surface on the light incident side).

As shown in FIG. 33(b), a first light blocking film 101 and a second light blocking film 102 or 103 are formed in the interlayer film (oxide film) 2, in this order from the light incident side. In FIG. 33(b), the second light blocking film 102 extends in the leftward direction with respect to the first light blocking film 101, so as to block the light to be received by the right half of a ranging pixel (a filter 7) that is the first pixel from the left. In FIG. 33(b), the second light blocking film 103 extends in the rightward direction with respect to the first light blocking film 101, so as to block the light to be received by the left half of a ranging pixel 7 that is the third pixel from the left. In FIG. 33(b), the second light blocking film 103 extends in the rightward direction with respect to the first light blocking film 101. The first light blocking film 101, the second light blocking film 102, and the second light blocking film 103 may be metal films, and the metal films may include tungsten, aluminum, copper, or the like, for example.

Next, a method for manufacturing the solid-state imaging device of the sixth embodiment (Example 6 of a solid-state imaging device) according to the present technology is described, with reference to FIGS. 34 to 39.

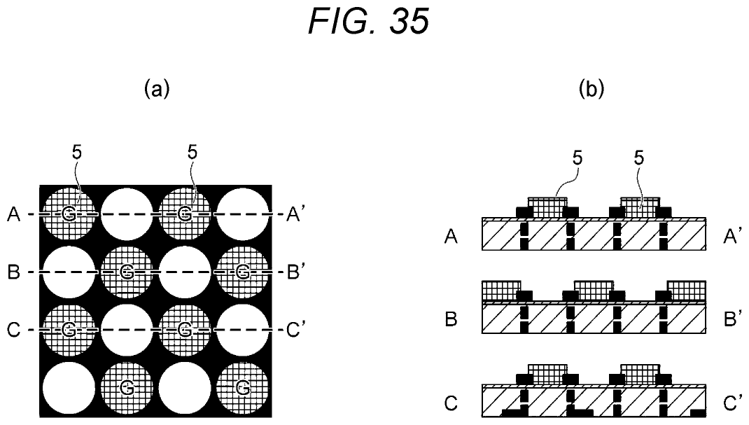

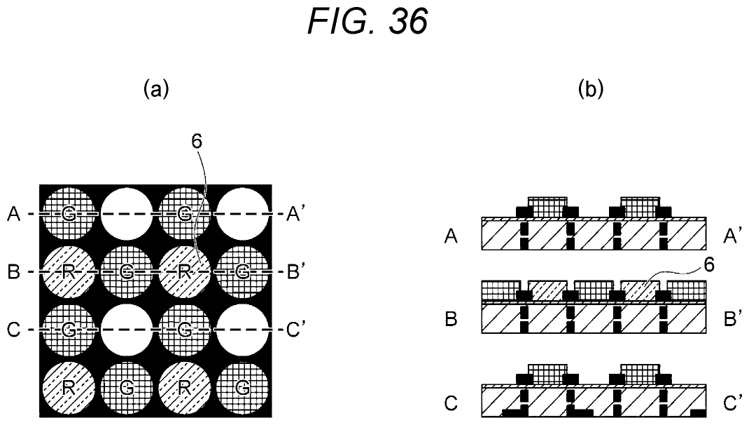

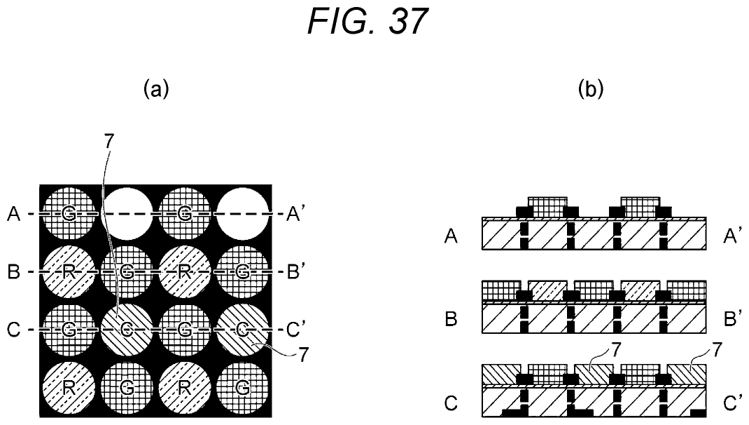

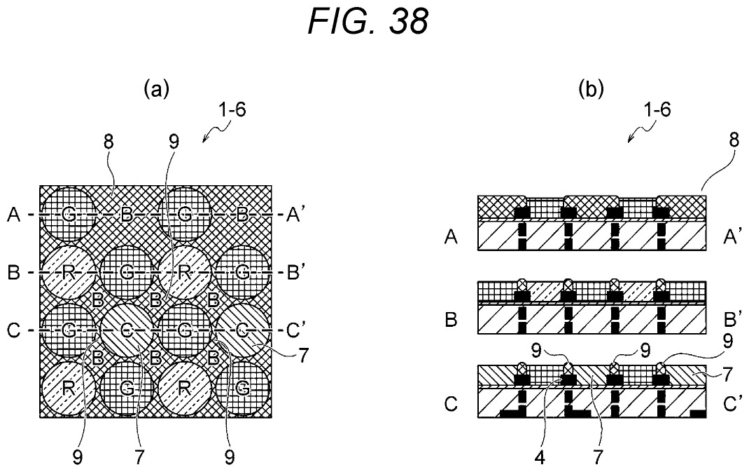

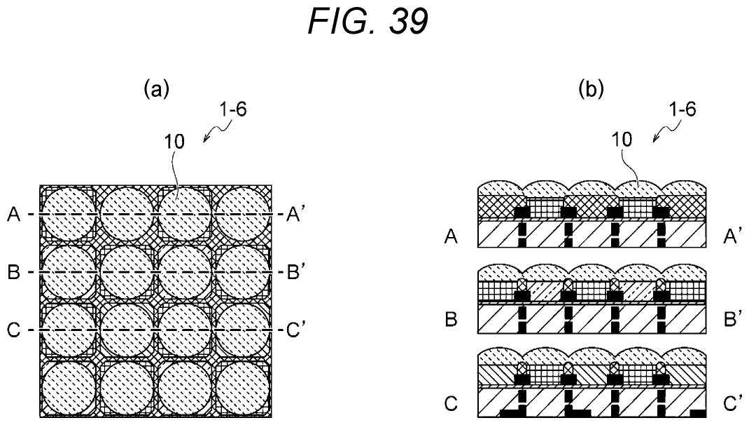

The method for manufacturing the solid-state imaging device of the sixth embodiment according to the present technology includes: forming a grid-like black resist pattern 4 so that filters that are circular in a plan view are formed, as shown in FIG. 34; forming a resist pattern of filters (green filters) (imaging images) 5 that are circular in a plan view and transmit green light, as shown in FIG. 35; forming a resist pattern of filters (red filters) (imaging images) 6 that are circular in a plan view and transmit red light, as shown in FIG. 36; forming a resist pattern of filters (cyan filters) (ranging images) 7 that are circular in a plan view and transmit cyan light, as shown in FIG. 37; forming a circular grid-like blue resist pattern 9 and a resist pattern of filters (blue filters) (imaging images) 8 that transmit blue light, as shown in FIG. 38; and, lastly, forming microlenses 10 on the filters (on the light incident side), as shown in FIG. 39. The partition walls are formed with the first layer 9 and the second layer 4 in this order from the light incident side. The first layer 9 is formed with a blue wall (a grid-like blue wall), and the second layer 4 is formed with a black wall (a grid-like black wall).

In addition to the contents described above, the contents described in the descriptions of the solid-state imaging devices of the first to fifth embodiments according to the present technology and the contents that will be explained below in the description of solid-state imaging devices of seventh to eleventh embodiments according to the present technology can be applied, without any change, to the solid-state imaging device of the sixth embodiment according to the present technology, unless there is some technical contradiction.

### 8. Seventh Embodiment (Example 7 of a Solid-State Imaging Device)

A solid-state imaging device of a seventh embodiment (Example 7 of a solid-state imaging device) according to the present technology includes a plurality of imaging pixels that is orderly arranged in accordance with a certain pattern, and the imaging pixels each include at least a semiconductor substrate in which a photoelectric conversion unit is formed, and a filter that transmits certain light and is formed on the light incidence face side of the semiconductor substrate. At least one of the plurality of imaging pixels is replaced with a ranging pixel having a filter that transmits certain light, so that at least one ranging pixel is formed. A partition wall is formed between the filter of the at least one ranging pixel and the filters adjacent to the filter of the at least one ranging pixel. The partition wall contains substantially the same material as the material of the filter of the at least one imaging pixel replaced with the ranging pixel. That is, the partition wall contains a material that is substantially the same as the material forming the filter of the imaging pixel replaced by the ranging pixel.

Further, the partition wall is formed so as to surround at least one ranging pixel.

The filter included in the ranging pixel may be designed to contain one of the materials of a color filter that transmits light in a specific wavelength band, a transparent film, a silicon oxide film that forms on-chip lenses, and the like. Further, the filter included in the ranging pixel may contain a material that transmits infrared light, ultraviolet light, red light, blue light, green light, white light, cyan light, magenta light, or yellow light.

With the solid-state imaging device of the seventh embodiment according to the present technology, it is possible to reduce color mixing between pixels, and reduce the difference between color mixing from a ranging pixel and color mixing from regular pixels (imaging pixels). It is also possible to block stray light entering from the invalid regions of microlenses, and improve imaging characteristics. Further, it is possible to improve the characteristics of flare and unevenness by eliminating color mixing between the pixels, and form the partition wall by lithography at the same time as the formation of the pixels without an increase in cost. Thus, a decrease in device sensitivity can be made smaller than that with a light blocking wall formed with a metal film.

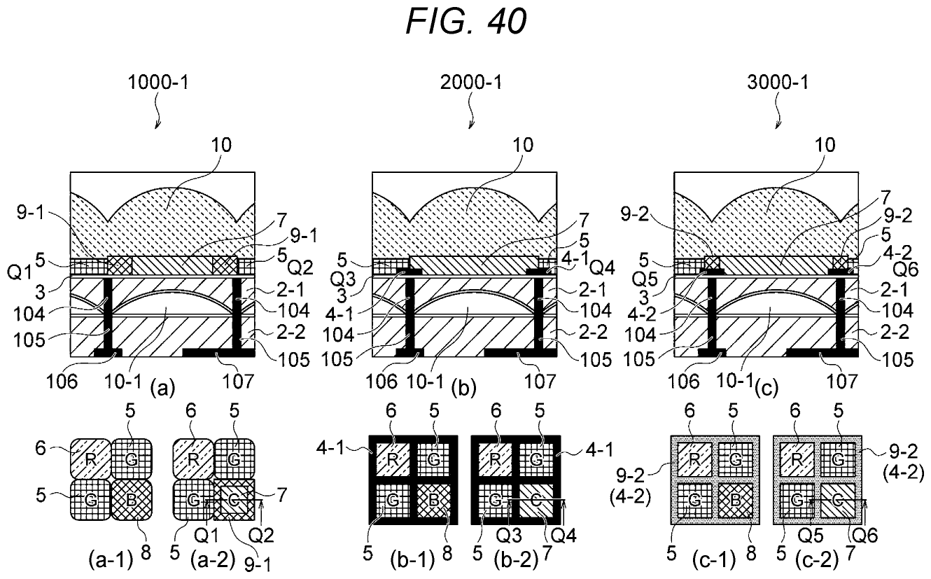

A solid-state imaging device of the seventh embodiment according to the present technology is now described, with reference to FIGS. 40(a), 40(a-1), and 40(a-2).

FIG. 40(a) is a cross-sectional view of one pixel of a solid-state imaging device 1000-1, taken along the Q1-Q2 line shown in FIG. 40(a-2). Note that FIG. 40(a) also shows part of the pixel to the left and the pixel to the right of the one pixel, for convenience. FIG. 40(a-1) is a top view (a planar layout diagram of filters (color filters)) of four imaging pixels of the solid-state imaging device 1000-1. FIG. 40(a-2) is a top view (a planar layout diagram of filters (color filters)) of three imaging pixels and one ranging pixel of the solid-state imaging device 1000-1.

In the solid-state imaging device 1000-1, a plurality of imaging pixels includes pixels each having a filter 8 that transmits blue light, pixels each having a filter 5 that transmits green light, and pixels each having a filter 6 that transmits red light. Each filter has a rectangular shape (which may be a square) in which four vertices are substantially rounded off (the four corners are almost at right angles) in a plan view from the light incident side. Further, the solid-state imaging device 1000-1 includes, in the respective pixels, at least microlenses (on-chip lenses) 10, filters (a cyan filter 7 in FIG. 40(a)), a partition wall 9-1, a planarizing film 3, interlayer films (oxide films) 2-1 and 2-2, a semiconductor substrate (not shown in FIG. 40(a)) in which photoelectric conversion units (photodiodes, for example) are formed, and a wiring layer (not shown), in this order from the light incident side. A ranging pixel may be an image-plane phase difference pixel, for example, but is not necessarily an image-plane phase difference pixel. A ranging pixel may be a pixel that acquires distance information using time-of-flight (TOF) technology, an infrared light receiving pixel, a pixel that receives light of a narrowband wavelength that can be used for specific purposes, a pixel that measures changes in luminance, or the like.

At least one pixel having a filter 8 that transmits blue light is replaced with a ranging pixel having a filter 7 that transmits cyan light, for example. In this manner, a ranging pixel is formed. The selection of the imaging pixels to be replaced with ranging pixels may be patterned or at random. So as to surround a ranging pixel (a filter 7), the partition wall 9-1 is formed between the filter 7 of the ranging pixel and a filter 5 that is adjacent to the filter 7 of the ranging pixel and transmits green light, from the boundary between the pixel having the filter 5 that transmits green light and the ranging pixel having the filter 7 that transmits cyan light, to the inside of the ranging pixel (in FIG. 40(a), from the portion that is located on the planarizing film 5 and immediately above a third light blocking film 104 described later, to the upper right portion in the third light blocking film 104 and the upper left portion in the third light blocking film 104). The partition wall 9-1 includes the same material as the material of the filters that transmit blue light. The height of the partition wall 9-1 (the length in the vertical direction in FIG. 40(a)) is substantially equal to the height of the filter 7 in FIG. 40(a), but the height of the partition wall 9-1 (the length in the vertical direction in FIG. 40(a)) may be smaller or greater than the height of the filter 7.

As shown in FIG. 40(a), in the solid-state imaging device 1000-1, the interlayer film 2-1 and the interlayer film 2-2 are formed in this order from the light incident side, and an inner lens 10-1 is formed in the interlayer film 2-1. The third light blocking film 104 is formed (vertically in FIG. 40(a)) in the interlayer film (oxide film) 2-1, so as to separate the pixels from each other. A fourth light blocking film 105, and a fifth light blocking film 106 or a sixth light blocking film 107 are formed in the interlayer film (oxide film) 2-2 in this order from the light incident side. The sixth light blocking film 107 extends in the leftward direction with respect to the fourth light blocking film 105 in FIG. 40(a), so as to block the light to be received at the right half of the ranging pixel (filter 7). The fifth light blocking film 106 extends substantially evenly in the lateral direction with respect to the fourth light blocking film 105. Note that, in FIG. 40(a), the width of the sixth light blocking film 107 extending in the leftward direction is greater than the width of the fifth light blocking film 106 extending in the lateral direction. The third light blocking film 104, the fourth light blocking film 105, the fifth light blocking film 106, and the sixth light blocking film 107 may be insulating films or metal films, for example. The insulating films may be formed with silicon oxide films, silicon nitride films, silicon oxynitride films, or the like, for example. The metal films may be formed with tungsten, aluminum, copper, or the like, for example.

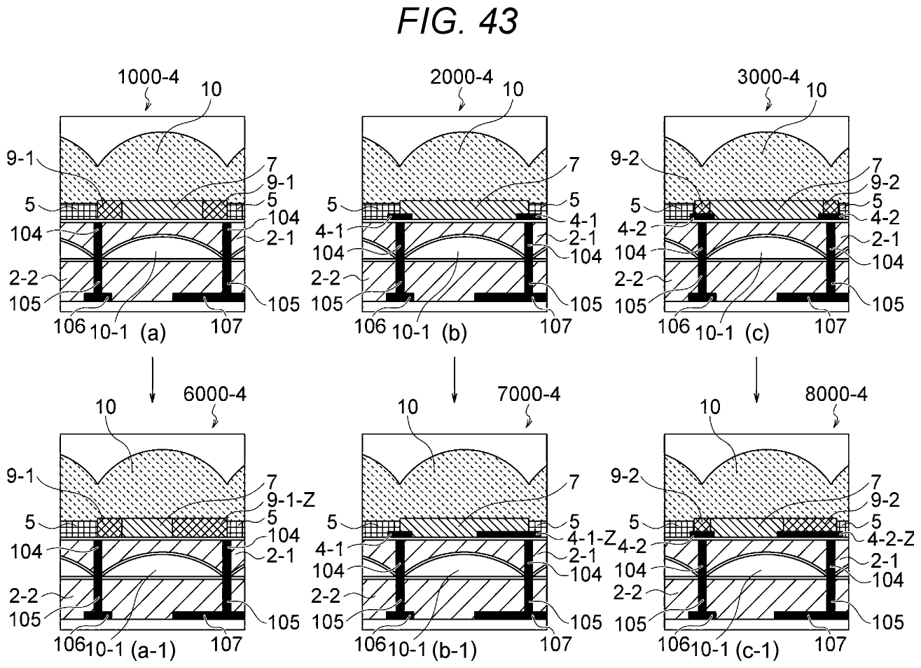

A solid-state imaging device of the seventh embodiment according to the present technology is described, with reference to FIGS. 43(a) and 43(a-1).

FIG. 43(a) is a cross-sectional view of one pixel of a solid-state imaging device 1000-4. Note that FIG. 43(a) also shows part of the pixel to the left and the pixel to the right of the one pixel, for convenience. FIG. 43(a-1) is a cross-sectional view of one pixel of a solid-state imaging device 6000-4. Note that FIG. 43(a-1) also shows part of the pixel to the left and the pixel to the right of the one pixel, for convenience. The configuration of the solid-state imaging device 1000-4 is the same as the configuration of the solid-state imaging device 1000-1, and therefore, explanation thereof is not made herein.

The difference between the configuration of the solid-state imaging device 6000-4 and the configuration of the solid-state imaging device 1000-4 is that the solid-state imaging device 6000-4 has a partition wall 9-1-Z. The partition wall 9-1-Z is longer than the partition wall 9-1, with its line width (in the lateral direction in FIG. 43(a)) extending in the leftward direction in FIG. 43(a) on the light blocking side (the side of the sixth light blocking film 107) of a ranging pixel (filter 7). Although not shown in the drawings, the height of the partition wall 9-1-Z (in the vertical direction in FIG. 43(a)) may be greater than the height of the partition wall 9-1.

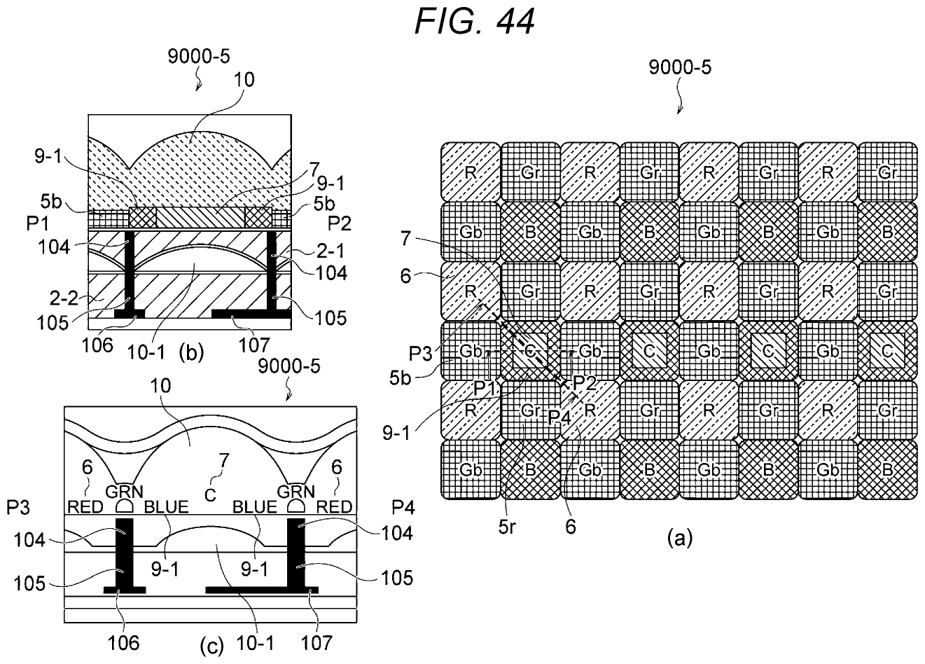

Referring now to FIG. 44, a method for manufacturing a solid-state imaging device of the seventh embodiment according to the present technology is described. FIG. 44(a) is a top view (a planar layout diagram of filters (color filters)) of 48 (8×6) pixels of a solid-state imaging device 9000-5, and the imaging pixels therein are orderly arranged in accordance with the Bayer array. FIG. 44(b) is a cross-sectional view of one pixel of the solid-state imaging device 9000-5, taken along the P1-P2 line shown in FIG. 44(a). Note that FIG. 44(b) also shows part of the pixel to the left and the pixel to the right of the one pixel, for convenience. FIG. 44(c) is a cross-sectional view of one pixel of the solid-state imaging device 9000-5, taken along the P3-P4 line shown in FIG. 44(a). Note that FIG. 44(c) also shows part of the pixel to the left and the pixel to the right of the one pixel, for convenience.

To manufacture the solid-state imaging device 9000-5, filters 5b and 5r (imaging pixels) that transmit green light, filters 6 (imaging pixels) that transmit red light, filters 8 that transmit blue light, the partition wall 9-1 containing a material that transmits blue light, and cyan filters 7 (ranging pixels) may be manufactured in this order. However, to take measures against peeling of the partition wall 9-1, it might be preferable to manufacture the partition wall 9-1 containing a material that transmits blue light, the filters 5b and 5r (imaging pixels) that transmit green light, the filters 6 (imaging pixels) that transmit red light, the filters 8 that transmit blue light, and the cyan filters 7 (ranging pixels), in this order. That is, in this preferred mode, the partition wall 9-1 is manufactured before the filters included in the imaging pixels.

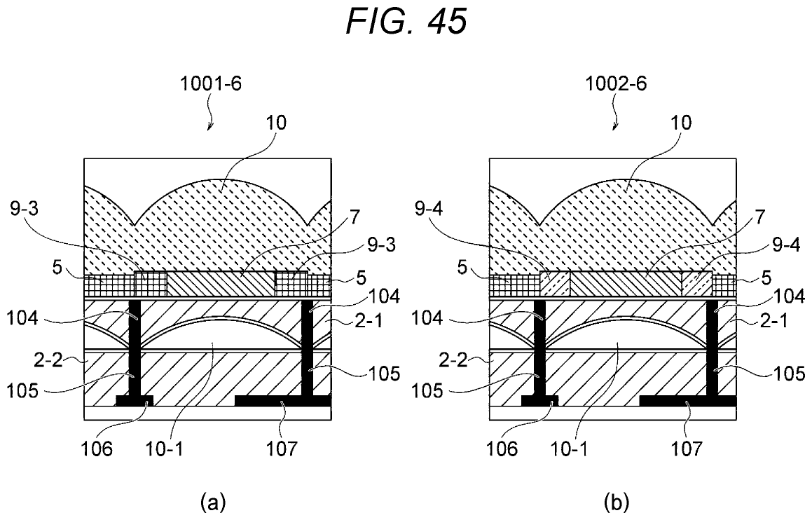

Next, a solid-state imaging device of the seventh embodiment according to the present technology is described in detail, with reference to FIG. 45. FIG. 45(a) is a cross-sectional view of one pixel of a solid-state imaging device 1001-6. Note that FIG. 45(a) also shows part of the pixel to the left and the pixel to the right of the one pixel, for convenience. FIG. 45(b) is a cross-sectional view of one pixel of a solid-state imaging device 1002-6. Note that FIG. 45(b) also shows part of the pixel to the left and the pixel to the right of the one pixel, for convenience.

As shown in FIG. 45(a), the difference between the configuration of the solid-state imaging device 1001-6 and the configuration of the solid-state imaging device 1000-1 is that the solid-state imaging device 1001-6 has a partition wall 9-3. In the solid-state imaging device 1001-6, at least one imaging pixel having a filter 5 that transmits green light is replaced with a ranging pixel having a filter 7 that transmits cyan light, for example. In this manner, a ranging pixel is formed. Therefore, the partition wall 9-3 includes the same material as the material of the filters that transmit green light.

As shown in FIG. 45(b), the difference between the configuration of the solid-state imaging device 1002-6 and the configuration of the solid-state imaging device 1000-1 is that the solid-state imaging device 1002-6 has a partition wall 9-4. In the solid-state imaging device 1002-6, at least one imaging pixel having a filter 6 that transmits red light is replaced with a ranging pixel having a filter 7 that transmits cyan light, for example. In this manner, a ranging pixel is formed. Therefore, the partition wall 9-4 includes the same material as the material of the filters that transmit red light.

With the above arrangement, the partition walls 9-1, 9-3, and 9-4 surrounding the filters 7 that transmit cyan light are effective in preventing color mixing.

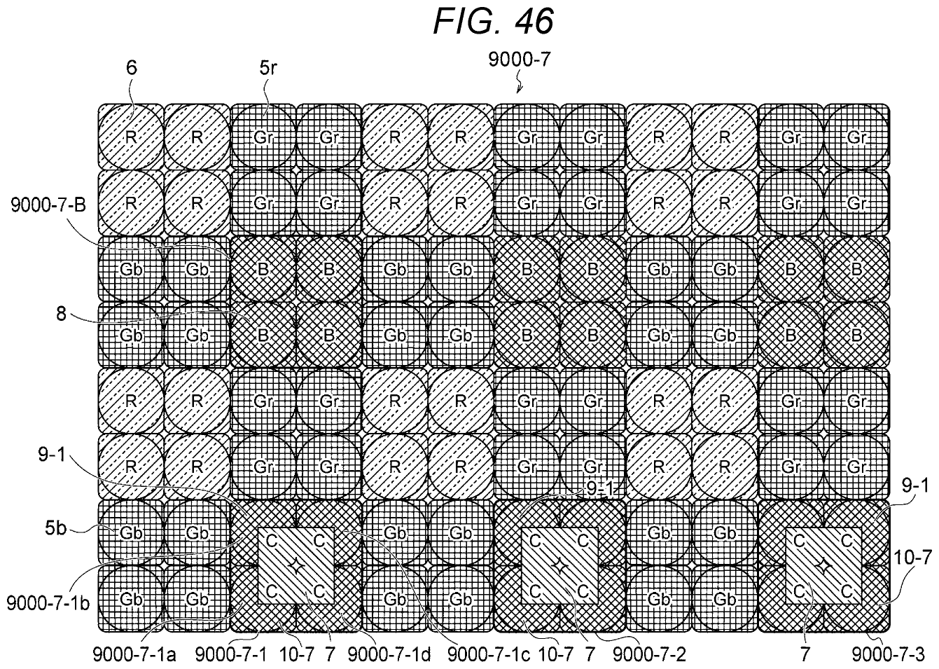

Referring now to FIG. 46, a solid-state imaging device of the seventh embodiment according to the present technology is described in detail. FIG. 46 is a top view (a planar layout diagram of filters (color filters)) of 96 pixels (12 pixels (in the lateral direction in FIG. 46)×eight pixels (in the vertical direction in FIG. 46)) of a solid-state imaging device 9000-7.

The solid-state imaging device 9000-7 has a quad Bayer array structure of color filters.

Here, one unit is formed with four pixels. In FIG. 46, one unit (9000-7-B) of four pixels including four filters 8 that transmit blue light is replaced with one unit 9000-7-1 of ranging pixels (9000-7-1a, 9000-7-1b, 9000-7-1c, and 9000-7-1d) including four filters 7 that transmit cyan light. Thus, ranging pixels equivalent to four pixels are formed. A partition wall 9-1 including the same material as the material of the filters that transmit blue light is then formed so as to surround the four cyan filters 7. Note that an on-chip lenses 10-7 is formed for each pixel. One unit 9000-7-2 and one unit 9000-7-3 have a similar configuration.

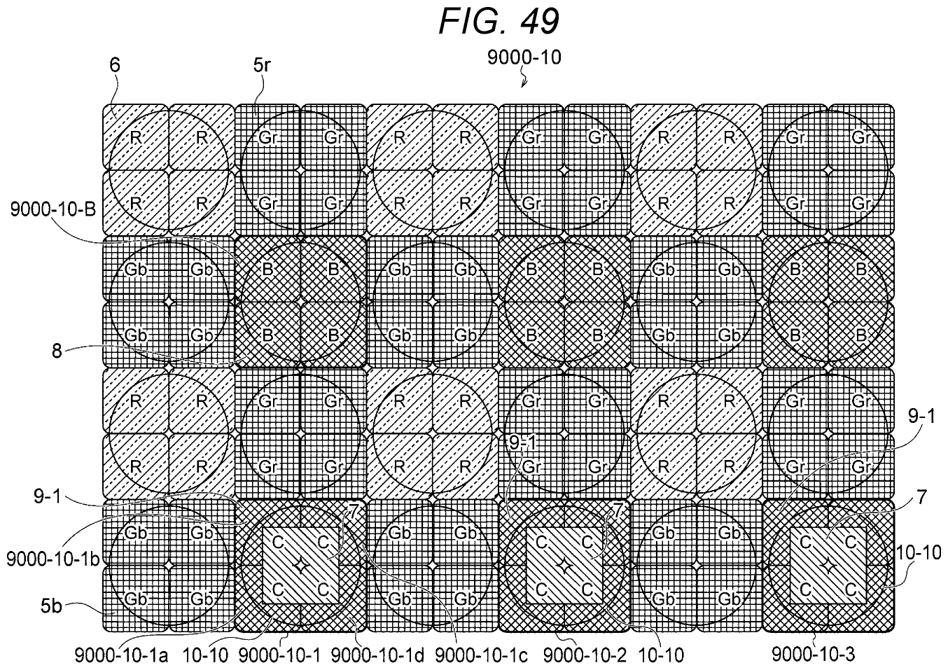

Referring now to FIG. 49, a solid-state imaging device of the seventh embodiment according to the present technology is described in detail. FIG. 49 is a top view (a planar layout diagram of filters (color filters)) of 96 (12×8) pixels of a solid-state imaging device 9000-10.

The solid-state imaging device 9000-10 has a quad Bayer array structure of color filters.

Here, one unit is formed with four pixels. In FIG. 49, one unit (9000-10-B) of four pixels including four filters 8 that transmit blue light is replaced with one unit 9000-10-1 of four ranging pixels (9000-10-1a, 9000-10-1b, 9000-10-1c, and 9000-10-1d) including filters 7 that transmit cyan light. Thus, ranging pixels equivalent to four pixels are formed. A partition wall 9-1 is then formed so as to surround the four cyan filters 7. Note that an on-chip lens 10-10 is formed for each one unit (for every four pixels). One unit 9000-10-2 and one unit 9000-10-3 have a similar configuration.

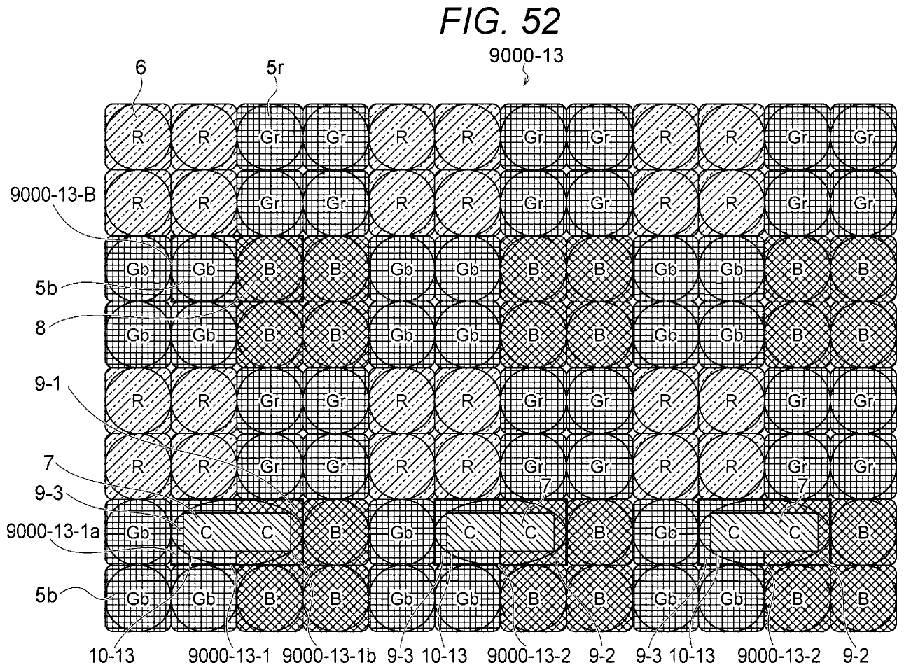

Referring now to FIG. 52, a solid-state imaging device of the seventh embodiment according to the present technology is described in detail. FIG. 52 is a top view (a planar layout diagram of filters (color filters)) of 96 (12×8) pixels of a solid-state imaging device 9000-13.

The solid-state imaging device 9000-13 has a quad Bayer array structure of color filters.

Here, one unit is formed with four pixels. In FIG. 52, one pixel having one filter 8 that transmits blue light is replaced with one ranging pixel 9000-13-1b having a filter 7 that transmits cyan light, one pixel having one filter 5 that transmits green light is replaced with one ranging pixel 9000-13-1a having a filter 7 that transmits cyan light, and an imaging pixel 9000-13-B equivalent to two pixels is replaced with a ranging pixel 9000-13-1 equivalent to two pixels. Then, a partition wall 9-1 includes a filter material that transmits blue light, and a partition wall 9-3 includes a filter material that transmits green light and is formed so as to surround two cyan filters 7. Note that an on-chip lens 10-13 is formed for a ranging pixel equivalent to two pixels, and an on-chip lens is formed for each pixel of the imaging pixels. A ranging pixel 9000-13-2 equivalent to two pixels and a ranging pixel 9000-13-3 equivalent to two pixels each have a similar configuration.

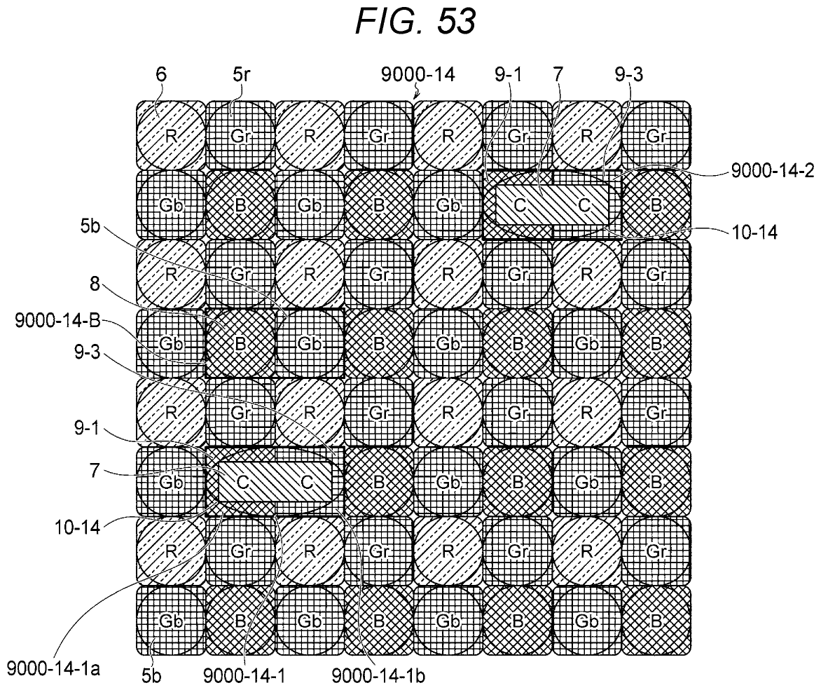

Referring now to FIG. 53, a solid-state imaging device of the seventh embodiment according to the present technology is described in detail. FIG. 53 is a top view (a planar layout diagram of filters (color filters)) of 96 (12×8) pixels of a solid-state imaging device 9000-14.

The solid-state imaging device 9000-14 has a Bayer array structure of color filters, and one unit is formed with one pixel. In FIG. 53, one pixel having one filter 8 that transmits blue light is replaced with one ranging pixel 9000-14-1a having a filter 7 that transmits cyan light, one pixel having one filter 5 that transmits green light is replaced with one ranging pixel 9000-14-1b having a filter 7 that transmits cyan light, and an imaging pixel 9000-14-B equivalent to two pixels is replaced with a ranging pixel 9000-14-1 equivalent to two pixels. Then, a partition wall 9-1 includes a filter material that transmits blue light, and a partition wall 9-3 includes a filter material that transmits green light and is formed so as to surround two cyan filters 7. Note that an on-chip lens 10-14 is formed for a ranging pixel equivalent to two pixels, and an on-chip lens is formed for each pixel of the imaging pixels. A ranging pixel 9000-14-2 equivalent to two pixels has a similar configuration.

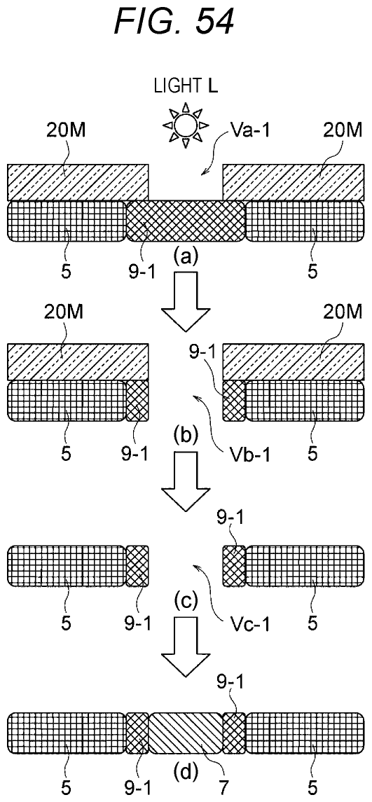

Referring now to FIG. 54, a method for manufacturing a solid-state imaging device of the seventh embodiment according to the present technology is described. The method for manufacturing the solid-state imaging device shown in FIG. 54 is a manufacturing method by photolithography using a positive resist. Note that the method for manufacturing the solid-state imaging device of the seventh embodiment according to the present technology may be a manufacturing method by photolithography using a negative resist.

In FIG. 54(a), light L (ultraviolet light, for example) is emitted onto the material forming a partition wall 9-1 through an opening Va-1 in a mask pattern 20M. The irradiated material (Vb-1) forming the partition wall 9-1 melts (FIG. 54(b)), and the mask pattern 20M is removed (FIG. 54(c)). A cyan filter 7 is formed in the melted portion Vc-1, and the partition wall 9-1 is manufactured (FIG. 54(d)). Thus, the solid-state imaging device of the seventh embodiment according to the present technology can be obtained.

In addition to the contents described above, the contents described in the descriptions of the solid-state imaging devices of the first to sixth embodiments according to the present technology and the contents that will be explained below in the description of solid-state imaging devices of eighth to eleventh embodiments according to the present technology can be applied, without any change, to the solid-state imaging device of the seventh embodiment according to the present technology, unless there is some technical contradiction.

### 9. Eighth Embodiment (Example 8 of a Solid-State Imaging Device)

A solid-state imaging device of an eighth embodiment (Example 8 of a solid-state imaging device) according to the present technology includes a plurality of imaging pixels that is orderly arranged in accordance with a certain pattern, and the imaging pixels each include at least a semiconductor substrate in which a photoelectric conversion unit is formed, and a filter that transmits certain light and is formed on the light incidence face side of the semiconductor substrate. At least one of the plurality of imaging pixels is replaced with a ranging pixel having a filter that transmits certain light, so that at least one ranging pixel is formed. A partition wall is formed between the filter of the at least one ranging pixel and the filters adjacent to the filter of the at least one ranging pixel, and the partition wall contains a light-absorbing material. That is, the partition wall contains a light-absorbing material, and the light-absorbing material may be a light-absorbing resin film containing a carbon black pigment, a light-absorbing resin film containing a titanium black pigment, or the like, for example.

The filter included in the ranging pixel may be designed to contain one of the materials of a color filter that transmits light in a specific wavelength band, a transparent film, a silicon oxide film that forms on-chip lenses, and the like. Further, the filter included in the ranging pixel may contain a material that transmits infrared light, ultraviolet light, red light, blue light, green light, white light, cyan light, magenta light, or yellow light.

With the solid-state imaging device of the eighth embodiment according to the present technology, it is possible to reduce color mixing between pixels, and reduce the difference between color mixing from a ranging pixel and color mixing from regular pixels (imaging pixels). It is also possible to block stray light entering from the invalid regions of microlenses, and improve imaging characteristics. Further, it is possible to improve the characteristics of flare and unevenness by eliminating color mixing between the pixels, and form the partition wall by lithography at the same time as the formation of the pixels without an increase in cost. Thus, a decrease in device sensitivity can be made smaller than that with a light blocking wall formed with a metal film.

A solid-state imaging device of the eighth embodiment according to the present technology is now described, with reference to FIGS. 40(b), 40(b-1), and 40(b-2).

FIG. 40(b) is a cross-sectional view of one pixel of a solid-state imaging device 2000-1, taken along the Q3-Q4 line shown in FIG. 40(b-2). Note that FIG. 40(b) also shows part of the pixel to the left and the pixel to the right of the one pixel, for convenience. FIG. 40(b-1) is a top view (a planar layout diagram of filters (color filters)) of four imaging pixels of the solid-state imaging device 2000-1. FIG. 40(b-2) is a top view (a planar layout diagram of filters (color filters)) of three imaging pixels and one ranging pixel of the solid-state imaging device 2000-1.

In the solid-state imaging device 2000-1, a plurality of imaging pixels includes pixels each having a filter 8 that transmits blue light, pixels each having a filter 5 that transmits green light, and pixels each having a filter 6 that transmits red light. Each filter has a rectangular shape (which may be a square) in which four vertices are substantially rounded off (the four corners are almost at right angles) in a plan view from the light incident side. Further, the solid-state imaging device 2000-1 includes, in the respective pixels, at least microlenses (on-chip lenses) 10, filters (a cyan filter 7 in FIG. 40(b)), a partition wall 4-1, a planarizing film 3, interlayer films (oxide films) 2-1 and 2-2, a semiconductor substrate (not shown in FIG. 40(b)) in which photoelectric conversion units (photodiodes, for example) are formed, and a wiring layer (not shown), in this order from the light incident side. A ranging pixel may be an image-plane phase difference pixel, for example, but is not necessarily an image-plane phase difference pixel. A ranging pixel may be a pixel that acquires distance information using time-of-flight (TOF) technology, an infrared light receiving pixel, a pixel that receives light of a narrowband wavelength that can be used for specific purposes, a pixel that measures changes in luminance, or the like.

At least one pixel having a filter 8 that transmits blue light is replaced with a ranging pixel having a filter 7 that transmits cyan light, for example. In this manner, a ranging pixel is formed. The selection of the imaging pixels to be replaced with ranging pixels may be patterned or at random. So as to surround a ranging pixel (a filter 7) and/or imaging pixels (a filter 5, a filter 6, and a filter 8), the partition wall 4-1 is formed at the boundary between an imaging pixel and an imaging pixel, the boundary between an imaging pixel and the ranging pixel, or the boundary and/or the region near the boundary between an imaging pixel and the ranging pixel (at a position that is located on the planarizing film 5, and is immediately above and near the region immediately above the third light blocking film 104, in FIG. 40(b)). The partition wall 4-1 is then formed in a grid-like pattern, when viewed in a plan view of the plurality of filters on the light incident side (which may be a plan view of all the pixels). The partition wall 4-1 is formed with a light-absorbing resin film containing a carbon black pigment, a light-absorbing resin film containing a titanium black pigment, or the like, for example. The height of the partition wall 4-1 (the length in the vertical direction in FIG. 40(b)) is smaller than the height of the filter 7 in FIG. 40(b), but may be substantially equal to or greater the height of the filter 7.

As shown in FIG. 40(b), in the solid-state imaging device 2000-1, the interlayer film 2-1 and the interlayer film 2-2 are formed in this order from the light incident side, and an inner lens 10-1 is formed in the interlayer film 2-1. The third light blocking film 104 is formed (vertically in FIG. 40(b)) in the interlayer film (oxide film) 2-1, so as to separate the pixels from each other. A fourth light blocking film 105, and a fifth light blocking film 106 or a sixth light blocking film 107 are formed in the interlayer film (oxide film) 2-2 in this order from the light incident side. The sixth light blocking film 107 extends in the leftward direction with respect to the fourth light blocking film 105 in FIG. 40(b), so as to block the light to be received at the right half of the ranging pixel (filter 7). The fifth light blocking film 106 extends in the rightward direction with respect to the fourth light blocking film 105. Note that, in FIG. 40(b), the width of the sixth light blocking film 107 extending in the leftward direction is greater than the width of the fifth light blocking film 106 extending in the rightward direction. The third light blocking film 104, the fourth light blocking film 105, the fifth light blocking film 106, and the sixth light blocking film 107 may be insulating films or metal films, for example. The insulating films may be formed with silicon oxide films, silicon nitride films, silicon oxynitride films, or the like, for example. The metal films may be formed with tungsten, aluminum, copper, or the like, for example.

A solid-state imaging device of the eighth embodiment according to the present technology is described, with reference to FIGS. 43(b) and 43(b-1).

FIG. 43(b) is a cross-sectional view of one pixel of a solid-state imaging device 2000-4. Note that FIG. 43(b) also shows part of the pixel to the left and the pixel to the right of the one pixel, for convenience. FIG. 43(b-1) is a cross-sectional view of one pixel of a solid-state imaging device 7000-4. Note that FIG. 43(b-1) also shows part of the pixel to the left and the pixel to the right of the one pixel, for convenience. The configuration of the solid-state imaging device 2000-4 is the same as the configuration of the solid-state imaging device 2000-1, and therefore, explanation thereof is not made herein.

The difference between the configuration of the solid-state imaging device 7000-4 and the configuration of the solid-state imaging device 2000-4 is that the solid-state imaging device 7000-4 has a partition wall 4-1-Z. The partition wall 4-1-Z is longer than the partition wall 4-1, with its line width (in the lateral direction in FIG. 43(b)) extending in the leftward direction in FIG. 43(b) on the light blocking side (the side of the sixth light blocking film 107) of a ranging pixel (filter 7). Although not shown in the drawings, the height of the partition wall 4-1-Z (in the vertical direction in FIG. 43(a)) may be greater than the height of the partition wall 4-1.

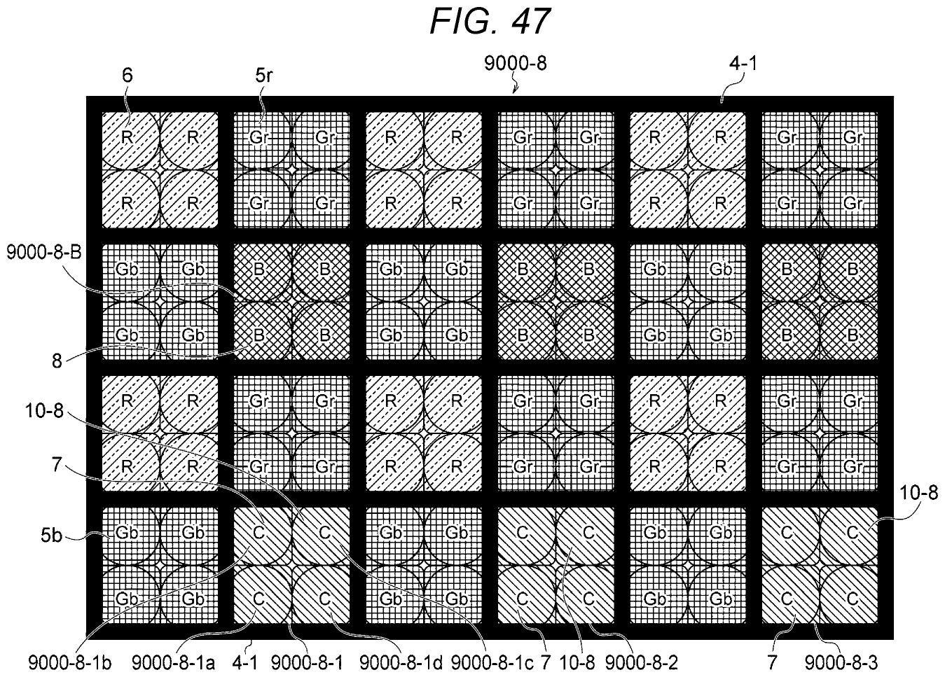

Referring now to FIG. 47, a solid-state imaging device of the eighth embodiment according to the present technology is described in detail. FIG. 47 is a top view (a planar layout diagram of filters (color filters)) of 96 (12×8) pixels of a solid-state imaging device 9000-7.

The solid-state imaging device 9000-8 has a quad Bayer array structure of color filters.

Here, one unit is formed with four pixels. In FIG. 47, one unit (9000-8-B) of four pixels including four filters 8 that transmit blue light is replaced with one unit 9000-8-1 of four ranging pixels (9000-8-1a, 9000-8-1b, 9000-8-1c, and 9000-8-1d) including filters 7 that transmit cyan light. Thus, ranging pixels equivalent to four pixels are formed. A partition wall 4-1 is then formed in a grid-like pattern. Note that an on-chip lenses 10-8 is formed for each pixel. One unit 9000-8-2 and one unit 9000-8-2 have a similar configuration.

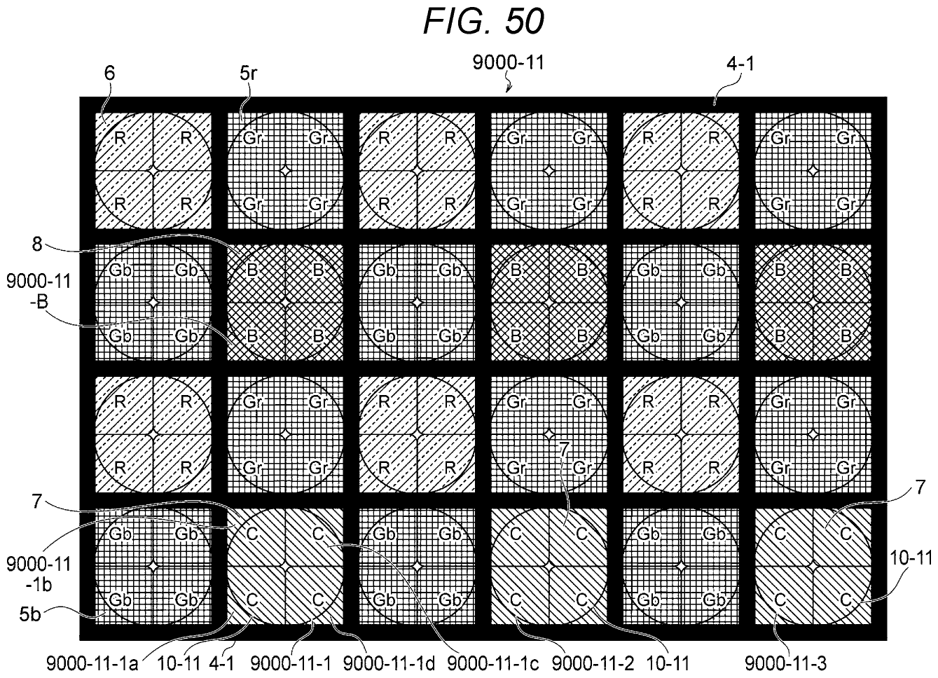

Referring now to FIG. 50, a solid-state imaging device of the eighth embodiment according to the present technology is described in detail. FIG. 50 is a top view (a planar layout diagram of filters (color filters)) of 96 (12×8) pixels of a solid-state imaging device 9000-11.

The solid-state imaging device 9000-11 has a quad Bayer array structure of color filters.

Here, one unit is formed with four pixels. In FIG. 50, one unit (9000-11-B) of four pixels including four filters 8 that transmit blue light is replaced with one unit 9000-11-1 of four ranging pixels (9000-11-1a, 9000-11-1b, 9000-11-1c, and 9000-11-1d) including filters 7 that transmit cyan light. Thus, ranging pixels equivalent to four pixels are formed. A partition wall 4-1 is then formed in a grid-like pattern. Note that an on-chip lens 10-11 is formed for each one unit (for every four pixels). One unit 9000-11-2 and one unit 9000-11-3 have a similar configuration.

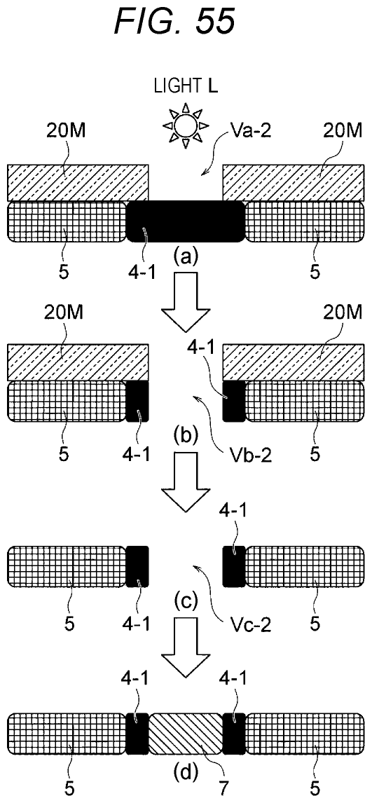

Referring now to FIG. 55, a method for manufacturing a solid-state imaging device of the eighth embodiment according to the present technology is described. The method for manufacturing the solid-state imaging device shown in FIG. 55 is a manufacturing method by photolithography using a positive resist. Note that the method for manufacturing the solid-state imaging device of the eighth embodiment according to the present technology may be a manufacturing method by photolithography using a negative resist.

In FIG. 55(a), light L (ultraviolet light, for example) is emitted onto the material forming a partition wall 4-1 through an opening Va-2 in a mask pattern 20M. The material (Vb-2) forming the irradiated portion of the partition wall 4-1 melts (FIG. 55(b)), and the mask pattern 20M is removed (FIG. 55(c)). A cyan filter 7 is formed in the melted portion Vc-2, and the partition wall 4-1 is manufactured (FIG. 55(d)). Thus, the solid-state imaging device of the eighth embodiment according to the present technology can be obtained.

In addition to the contents described above, the contents described in the descriptions of the solid-state imaging devices of the first to seventh embodiments according to the present technology and the contents that will be explained below in the description of solid-state imaging devices of ninth to eleventh embodiments according to the present technology can be applied, without any change, to the solid-state imaging device of the eighth embodiment according to the present technology, unless there is some technical contradiction.

### 10. Ninth Embodiment (Example 9 of a Solid-State Imaging Device)

A solid-state imaging device of a ninth embodiment (Example 9 of a solid-state imaging device) according to the present technology includes a plurality of imaging pixels that is orderly arranged in accordance with a certain pattern, and the imaging pixels each include at least a semiconductor substrate in which a photoelectric conversion unit is formed, and a filter that transmits certain light and is formed on the light incidence face side of the semiconductor substrate. At least one of the plurality of imaging pixels is replaced with a ranging pixel having a filter that transmits certain light, so that at least one ranging pixel is formed. A partition wall is formed between the filter of the at least one ranging pixel and the filters adjacent to the filter of the at least one ranging pixel. The partition wall contains substantially the same material as the material of the filter of the at least one imaging pixel replaced with the ranging pixel, and a light-absorbing material. That is, the partition wall contains a material that is substantially the same as the material forming the filter of the imaging pixel replaced with the ranging pixel, and a light-absorbing material. The light-absorbing material may be a light-absorbing resin film containing a carbon black pigment, a light-absorbing resin film containing a titanium black pigment, or the like, for example.

The filter included in the ranging pixel may be designed to contain one of the materials of a color filter that transmits light in a specific wavelength band, a transparent film, a silicon oxide film that forms on-chip lenses, and the like. Further, the filter included in the ranging pixel may contain a material that transmits infrared light, ultraviolet light, red light, blue light, green light, white light, cyan light, magenta light, or yellow light.

With the solid-state imaging device of the ninth embodiment according to the present technology, it is possible to reduce color mixing between pixels, and reduce the difference between color mixing from a ranging pixel and color mixing from regular pixels (imaging pixels). It is also possible to block stray light entering from the invalid regions of microlenses, and improve imaging characteristics. Further, it is possible to improve the characteristics of flare and unevenness by eliminating color mixing between the pixels, and form the partition wall by lithography at the same time as the formation of the pixels without an increase in cost. Thus, a decrease in device sensitivity can be made smaller than that with a light blocking wall formed with a metal film.

A solid-state imaging device of the ninth embodiment according to the present technology is now described, with reference to FIGS. 40(c), 40(c-1), and 40(c-2).

FIG. 40(c) is a cross-sectional view of one pixel of a solid-state imaging device 3000-1, taken along the Q5-Q6 line shown in FIG. 40(c-2). Note that FIG. 40(c) also shows part of the pixel to the left and the pixel to the right of the one pixel, for convenience. FIG. 40(c-1) is a top view (a planar layout diagram of filters (color filters)) of four imaging pixels of the solid-state imaging device 3000-1. FIG. 40(c-2) is a top view (a planar layout diagram of filters (color filters)) of three imaging pixels and one ranging pixel of the solid-state imaging device 3000-1.

In the solid-state imaging device 3000-1, a plurality of imaging pixels includes pixels each having a filter 8 that transmits blue light, pixels each having a filter 5 that transmits green light, and pixels each having a filter 6 that transmits red light. Each filter has a rectangular shape (which may be a square) in which four vertices are substantially rounded off (the four corners are almost at right angles) in a plan view from the light incident side. Further, the solid-state imaging device 3000-1 includes, in the respective pixels, at least microlenses (on-chip lenses) 10, filters (a cyan filter 7 in FIG. 40(c)), a partition wall 4-2 and a partition wall 9-2, a planarizing film 3, interlayer films (oxide films) 2-1 and 2-2, a semiconductor substrate (not shown in FIG. 40(a)) in which photoelectric conversion units (photodiodes, for example) are formed, and a wiring layer (not shown), in this order from the light incident side. A ranging pixel may be an image-plane phase difference pixel, for example, but is not necessarily an image-plane phase difference pixel. A ranging pixel may be a pixel that acquires distance information using time-of-flight (TOF) technology, an infrared light receiving pixel, a pixel that receives light of a narrowband wavelength that can be used for specific purposes, a pixel that measures changes in luminance, or the like.

At least one pixel having a filter 8 that transmits blue light is replaced with a ranging pixel having a filter 7 that transmits cyan light, for example. In this manner, a ranging pixel is formed. The selection of the imaging pixels to be replaced with ranging pixels may be patterned or at random. So as to surround a ranging pixel (a filter 7) and/or imaging pixels (a filter 5, a filter 6, and a filter 8), the partition wall 9-2 and the partition wall 4-2 are formed in this order from the light incident side, at the boundary between an imaging pixel and an imaging pixel, and the boundary between an imaging pixel and the ranging pixel and/or the boundary and/or the region near the boundary between an imaging pixel and the ranging pixel (at a position that is located on the planarizing film 5, and is immediately above and near the region immediately above the third light blocking film 104, in FIG. 40(c)). The partition wall 9-2 (the partition wall 4-2) is then formed in a grid-like pattern, when viewed in a plan view of the plurality of filters on the light incident side (which may be a plan view of all the pixels). The partition wall 9-2 includes the same material as the material of the filters that transmit blue light. The partition wall 4-2 is formed with a light-absorbing resin film containing a carbon black pigment, a light-absorbing resin film containing a titanium black pigment, or the like, for example. The total height (a length in the vertical direction in FIG. 40(c)) of the height of the partition wall 9-2 and the height of the partition wall 4-2 is substantially equal to the height of the filter 7 in FIG. 40(c), but the total height (the length in the vertical direction in FIG. 40(c)) of the height of the partition wall 9-2 and the height of the partition wall 4-2 may be smaller or greater than the height of the filter 7.

As shown in FIG. 40(c), in the solid-state imaging device 3000-1, the interlayer film 2-1 and the interlayer film 2-2 are formed in this order from the light incident side, and an inner lens 10-1 is formed in the interlayer film 2-1. The third light blocking film 104 is formed (vertically in FIG. 40(c)) in the interlayer film (oxide film) 2-1, so as to separate the pixels from each other. A fourth light blocking film 105, and a fifth light blocking film 106 or a sixth light blocking film 107 are formed in the interlayer film (oxide film) 2-2 in this order from the light incident side. The sixth light blocking film 107 extends in the leftward direction with respect to the fourth light blocking film 105 in FIG. 40(c), so as to block the light to be received at the right half of the ranging pixel (filter 7). The fifth light blocking film 106 extends in the rightward direction with respect to the fourth light blocking film 105. Note that, in FIG. 40(c), the width of the sixth light blocking film 107 extending in the leftward direction is greater than the width of the fifth light blocking film 106 extending in the rightward direction. The third light blocking film 104, the fourth light blocking film 105, the fifth light blocking film 106, and the sixth light blocking film 107 may be insulating films or metal films, for example. The insulating films may be formed with silicon oxide films, silicon nitride films, silicon oxynitride films, or the like, for example. The metal films may be formed with tungsten, aluminum, copper, or the like, for example.

A solid-state imaging device of the ninth embodiment according to the present technology is described, with reference to FIGS. 43(c) and 43(c-1).

FIG. 43(c) is a cross-sectional view of one pixel of a solid-state imaging device 3000-4. Note that FIG. 43(c) also shows part of the pixel to the left and the pixel to the right of the one pixel, for convenience. FIG. 43(c-1) is a cross-sectional view of one pixel of a solid-state imaging device 8000-4. Note that FIG. 43(c-1) also shows part of the pixel to the left and the pixel to the right of the one pixel, for convenience. The configuration of the solid-state imaging device 3000-4 is the same as the configuration of the solid-state imaging device 3000-1, and therefore, explanation thereof is not made herein.

The difference between the configuration of the solid-state imaging device 8000-4 and the configuration of the solid-state imaging device 3000-4 is that the solid-state imaging device 8000-4 has partition walls 9-2-Z and 4-2-Z. The partition wall 4-2-Z is longer than the partition wall 4-2, with its line width (in the lateral direction in FIG. 43(c)) extending in the leftward in FIG. 43(c), on the light blocking side (the side of the sixth light blocking film 107) of the ranging pixel (the filter 7). Although not shown in the drawings, the height of the partition wall 4-2-Z (in the vertical direction in FIG. 43(c)) may be greater than the height of the partition wall 4-2. Likewise, the partition wall 9-2-Z is longer than the partition wall 9-2, with its line width (in the lateral direction in FIG. 43(c)) extending in the leftward in FIG. 43(c), on the light blocking side (the side of the sixth light blocking film 107) of the ranging pixel (the filter 7). Although not shown in the drawings, the height of the partition wall 9-2-Z (in the vertical direction in FIG. 43(c)) may be greater than the height of the partition wall 9-2.

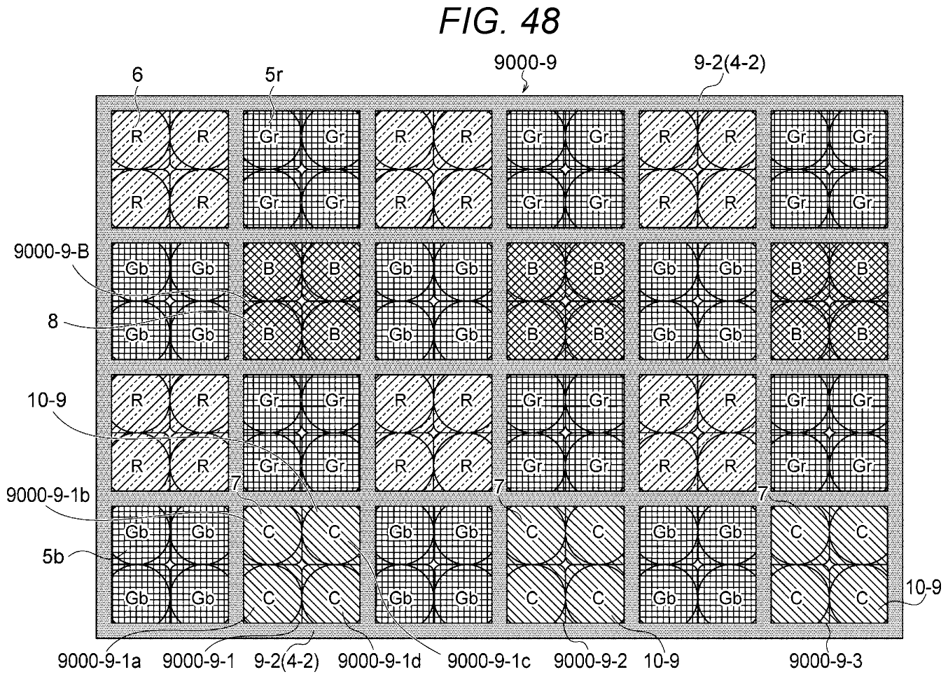

Referring now to FIG. 48, a solid-state imaging device of the ninth embodiment according to the present technology is described in detail. FIG. 48 is a top view (a planar layout diagram of filters (color filters)) of 96 (12×8) pixels of a solid-state imaging device 9000-9.

The solid-state imaging device 9000-9 has a quad Bayer array structure of color filters.

Here, one unit is formed with four pixels. In FIG. 48, one unit (9000-9-B) of four pixels including four filters 8 that transmit blue light is replaced with one unit 9000-9-1 of four ranging pixels (9000-9-1a, 9000-9-1b, 9000-9-1c, and 9000-9-1d) including filters 7 that transmit cyan light. Thus, ranging pixels equivalent to four pixels are formed. A partition wall 4-2 and a partition wall 9-2 are then formed in a grid-like pattern. Note that an on-chip lenses 10-9 is formed for each pixel. One unit 9000-9-2 and one unit 9000-9-3 have a similar configuration.

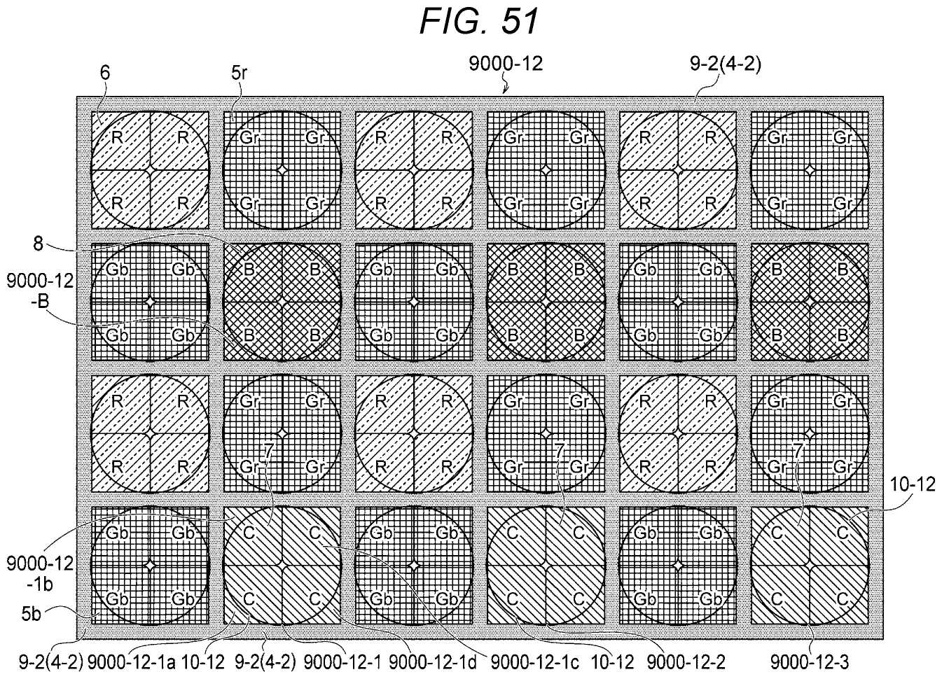

Referring now to FIG. 51, a solid-state imaging device of the ninth embodiment according to the present technology is described in detail. FIG. 51 is a top view (a planar layout diagram of filters (color filters)) of 96 (12×8) pixels of a solid-state imaging device 9000-12.

The solid-state imaging device 9000-12 has a quad Bayer array structure of color filters.

Here, one unit is formed with four pixels. In FIG. 51, one unit (9000-12-B) of four pixels including four filters 8 that transmit blue light is replaced with one unit 9000-12-1 of four ranging pixels (9000-12-1a, 9000-12-1b, 9000-12-1c, and 9000-12-1d) including filters 7 that transmit cyan light. Thus, ranging pixels equivalent to four pixels are formed. A partition wall 4-2 and a partition wall 9-2 are then formed in a grid-like pattern. Note that an on-chip lens 10-12 is formed for each one unit (for every four pixels). One unit 9000-12-2 and one unit 9000-12-3 have a similar configuration.

In addition to the contents described above, the contents described in the descriptions of the solid-state imaging devices of the first to eighth embodiments according to the present technology and the contents that will be explained below in the description of solid-state imaging devices of tenth to eleventh embodiments according to the present technology can be applied, without any change, to the solid-state imaging device of the ninth embodiment according to the present technology, unless there is some technical contradiction.

### 11. Tenth Embodiment (Example 10 of a Solid-State Imaging Device)

A solid-state imaging device of a tenth embodiment (Example 10 of a solid-state imaging device) according to the present technology includes a plurality of imaging pixels that is orderly arranged in accordance with a certain pattern, and the imaging pixels each include at least a semiconductor substrate in which a photoelectric conversion unit is formed, and a filter that transmits certain light and is formed on the light incidence face side of the semiconductor substrate. At least one of the plurality of imaging pixels is replaced with a ranging pixel having a filter that transmits certain light, so that at least one ranging pixel is formed. A partition wall is formed between the filter of the at least one ranging pixel and the filters adjacent to the filter of the at least one ranging pixel. The partition wall contains substantially the same material as the material of the filter of the at least one imaging pixel replaced with the ranging pixel, and a light-absorbing material. That is, the partition wall contains a material that is substantially the same as the material forming the filter of the imaging pixel replaced with the ranging pixel, and a light-absorbing material. The light-absorbing material may be a light-absorbing resin film containing a carbon black pigment, a light-absorbing resin film containing a titanium black pigment, or the like, for example.

Further, the partition wall is formed so as to surround at least one ranging pixel.

The filter included in the ranging pixel may be designed to contain one of the materials of a color filter that transmits light in a specific wavelength band, a transparent film, a silicon oxide film that forms on-chip lenses, and the like. Further, the filter included in the ranging pixel may contain a material that transmits infrared light, ultraviolet light, red light, blue light, green light, white light, cyan light, magenta light, or yellow light.

With the solid-state imaging device of the tenth embodiment according to the present technology, it is possible to reduce color mixing between pixels, and reduce the difference between color mixing from a ranging pixel and color mixing from regular pixels (imaging pixels). It is also possible to block stray light entering from the invalid regions of microlenses, and improve imaging characteristics. Further, it is possible to improve the characteristics of flare and unevenness by eliminating color mixing between the pixels, and form the partition wall by lithography at the same time as the formation of the pixels without an increase in cost. Thus, a decrease in device sensitivity can be made smaller than that with a light blocking wall formed with a metal film.

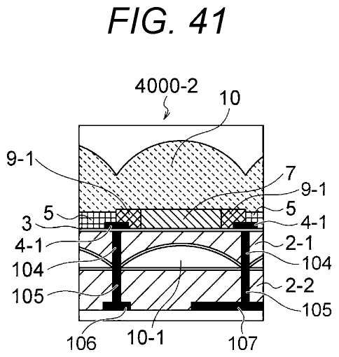

Referring now to FIG. 41, a solid-state imaging device of the tenth embodiment according to the present technology is described.

FIG. 41 is a cross-sectional view of one pixel of a solid-state imaging device 4000-2. Note that FIG. 41 also shows part of the pixel to the left and the pixel to the right of the one pixel, for convenience.

The solid-state imaging device 4000-2 includes, in the respective pixels, at least microlenses (on-chip lenses) 10, filters (a cyan filter 7 in FIG. 41)), a partition wall 4-1 and a partition wall 9-1, a planarizing film 3, interlayer films (oxide films) 2-1 and 2-2, a semiconductor substrate (not shown in FIG. 41) in which photoelectric conversion units (photodiodes, for example) are formed, and a wiring layer (not shown), in this order from the light incident side. A ranging pixel may be an image-plane phase difference pixel, for example, but is not necessarily an image-plane phase difference pixel. A ranging pixel may be a pixel that acquires distance information using time-of-flight (TOF) technology, an infrared light receiving pixel, a pixel that receives light of a narrowband wavelength that can be used for specific purposes, a pixel that measures changes in luminance, or the like.

With the solid-state imaging device 4000-2, the partition wall 4-1 is disposed in all the pixels (or may be disposed between each two pixels of all the pixels), for example, and the partition wall 9-1 is disposed so as to surround the ranging pixels (image-plane phase difference pixels, for example). Thus, color mixing between imaging pixels can be reduced, and horizontal flare streaks can be prevented. Note that the specifics of the partition wall 4-1 and the partition wall 9-1 are as described above, and therefore, explanation thereof is not made herein.

In addition to the contents described above, the contents described in the descriptions of the solid-state imaging devices of the first to ninth embodiments according to the present technology and the contents that will be explained below in the description of solid-state imaging devices of the eleventh embodiment according to the present technology can be applied, without any change, to the solid-state imaging device of the tenth embodiment according to the present technology, unless there is some technical contradiction.

### 12. Eleventh Embodiment (Example 11 of a Solid-State Imaging Device)

A solid-state imaging device of an eleventh embodiment (Example 11 of a solid-state imaging device) according to the present technology includes a plurality of imaging pixels that is orderly arranged in accordance with a certain pattern, and the imaging pixels each include at least a semiconductor substrate in which a photoelectric conversion unit is formed, and a filter that transmits certain light and is formed on the light incidence face side of the semiconductor substrate. At least one of the plurality of imaging pixels is replaced with a ranging pixel having a filter that transmits certain light, so that at least one ranging pixel is formed. A partition wall is formed between the filter of the at least one ranging pixel and the filters adjacent to the filter of the at least one ranging pixel. The partition wall contains substantially the same material as the material of the filter of the at least one imaging pixel replaced with the ranging pixel, and a light-absorbing material. That is, the partition wall contains a material that is substantially the same as the material forming the filter of the imaging pixel replaced with the ranging pixel, and a light-absorbing material. The light-absorbing material may be a light-absorbing resin film containing a carbon black pigment, a light-absorbing resin film containing a titanium black pigment, or the like, for example.

Further, the partition wall is formed so as to surround at least one ranging pixel.

The filter included in the ranging pixel may be designed to contain one of the materials of a color filter that transmits light in a specific wavelength band, a transparent film, a silicon oxide film that forms on-chip lenses, and the like. Further, the filter included in the ranging pixel may contain a material that transmits infrared light, ultraviolet light, red light, blue light, green light, white light, cyan light, magenta light, or yellow light.

With the solid-state imaging device of the eleventh embodiment according to the present technology, it is possible to reduce color mixing between pixels, and reduce the difference between color mixing from a ranging pixel and color mixing from regular pixels (imaging pixels). It is also possible to block stray light entering from the invalid regions of microlenses, and improve imaging characteristics. Further, it is possible to improve the characteristics of flare and unevenness by eliminating color mixing between the pixels, and form the partition wall by lithography at the same time as the formation of the pixels without an increase in cost. Thus, a decrease in device sensitivity can be made smaller than that with a light blocking wall formed with a metal film.

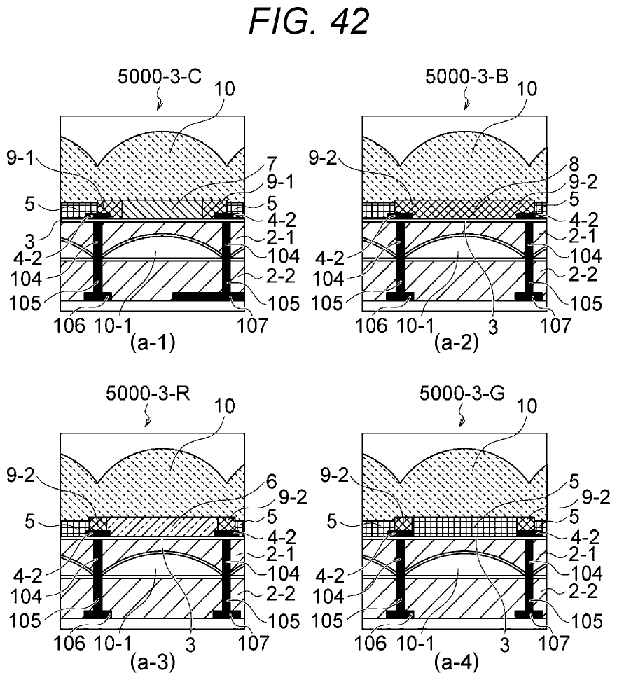

A solid-state imaging device of the eleventh embodiment according to the present technology is now described, with reference to FIG. 42 (FIGS. 42(a-1) to 42(a-4)).

FIGS. 42(a-1) to 42(a-4) are cross-sectional views of one pixel of a solid-state imaging device 5000-3-C, a solid-state imaging device 5000-3-B, a solid-state imaging device 5000-3-R, and a solid-state imaging device 5000-3-G, respectively. Note that, for convenience, FIGS. 42(a-1) to 42(a-4) each also show part of the pixel to the left and the pixel to the right of the one pixel.

A solid-state imaging device 5000-3 (5000-3-C) includes, in the respective pixels, at least microlenses (on-chip lenses) 10, filters (a cyan filter 7 in FIG. 42(a-1)), a partition wall 4-2 and a partition wall 9-1, a planarizing film 3, interlayer films (oxide films) 2-1 and 2-2, a semiconductor substrate (not shown in FIG. 42(a-1)) in which photoelectric conversion units (photodiodes, for example) are formed, and a wiring layer (not shown), in this order from the light incident side. A ranging pixel may be an image-plane phase difference pixel, for example, but is not necessarily an image-plane phase difference pixel. A ranging pixel may be a pixel that acquires distance information using time-of-flight (TOF) technology, an infrared light receiving pixel, a pixel that receives light of a narrowband wavelength that can be used for specific purposes, a pixel that measures changes in luminance, or the like.

As shown in FIG. 42(a-1), in the solid-state imaging device 5000-3-C, the interlayer film 2-1 and the interlayer film 2-2 are formed in this order from the light incident side, and an inner lens 10-1 is formed in the interlayer film 2-1. A third light blocking film 104 is formed (vertically in FIG. 42(a-1)) in the interlayer film (oxide film) 2-1, so as to separate the pixels from each other. A fourth light blocking film 105, and a fifth light blocking film 106 or a sixth light blocking film 107 are formed in the interlayer film (oxide film) 2-2 in this order from the light incident side. The sixth light blocking film 107 extends in the leftward direction with respect to the fourth light blocking film 105 in FIG. 40(a), so as to block the light to be received at the right half of the ranging pixel (filter 7). The fifth light blocking film 106 extends substantially evenly in the lateral direction with respect to the fourth light blocking film 105. Note that, in FIG. 42(a-1), the width of the sixth light blocking film 107 extending in the leftward direction is greater than the width of the fifth light blocking film 106 extending in the lateral direction. The third light blocking film 104, the fourth light blocking film 105, the fifth light blocking film 106, and the sixth light blocking film 107 may be insulating films or metal films, for example. The insulating films may be formed with silicon oxide films, silicon nitride films, silicon oxynitride films, or the like, for example. The metal films may be formed with tungsten, aluminum, copper, or the like, for example.

A solid-state imaging device 5000-3 (5000-3-B) includes, in the respective pixels, at least microlenses (on-chip lenses) 10, filters (a blue filter 8 in FIG. 42(a-2)), a partition wall 4-2 and a partition wall 9-2, a planarizing film 3, interlayer films (oxide films) 2-1 and 2-2, a semiconductor substrate (not shown in FIG. 42(a-2)) in which photoelectric conversion units (photodiodes, for example) are formed, and a wiring layer (not shown), in this order from the light incident side. A ranging pixel may be an image-plane phase difference pixel, for example, but is not necessarily an image-plane phase difference pixel. A ranging pixel may be a pixel that acquires distance information using time-of-flight (TOF) technology, an infrared light receiving pixel, a pixel that receives light of a narrowband wavelength that can be used for specific purposes, a pixel that measures changes in luminance, or the like.

As shown in FIG. 42(a-2), in the solid-state imaging device 5000-3-B, the interlayer film 2-1 and the interlayer film 2-2 are formed in this order from the light incident side, and an inner lens 10-1 is formed in the interlayer film 2-1. A third light blocking film 104 is formed (vertically in FIG. 42(a-2)) in the interlayer film (oxide film) 2-1, so as to separate the pixels from each other. A fourth light blocking film 105, and a fifth light blocking film 106 or a sixth light blocking film 107 are formed in the interlayer film (oxide film) 2-2 in this order from the light incident side. The sixth light blocking film 107 extends substantially evenly in the lateral direction with respect to the fourth light blocking film 105 in FIG. 42(a-2). Likewise, the fifth light blocking film 106 also extends substantially evenly in the lateral direction with respect to the fourth light blocking film 105. In FIG. 42(a-2), the width of the sixth light blocking film 107 extending in the lateral direction is substantially the same as the width of the fifth light blocking film 106 extending in the lateral direction. The third light blocking film 104, the fourth light blocking film 105, the fifth light blocking film 106, and the sixth light blocking film 107 may be insulating films or metal films, for example. The insulating films may be formed with silicon oxide films, silicon nitride films, silicon oxynitride films, or the like, for example. The metal films may be formed with tungsten, aluminum, copper, or the like, for example.

A solid-state imaging device 5000-3 (5000-3-R) includes, in the respective pixels, at least microlenses (on-chip lenses) 10, filters (a red filter 6 in FIG. 42(a-3)), a partition wall 4-2 and a partition wall 9-2, a planarizing film 3, interlayer films (oxide films) 2-1 and 2-2, a semiconductor substrate (not shown in FIG. 42(a-3)) in which photoelectric conversion units (photodiodes, for example) are formed, and a wiring layer (not shown), in this order from the light incident side. A ranging pixel may be an image-plane phase difference pixel, for example, but is not necessarily an image-plane phase difference pixel. A ranging pixel may be a pixel that acquires distance information using time-of-flight (TOF) technology, an infrared light receiving pixel, a pixel that receives light of a narrowband wavelength that can be used for specific purposes, a pixel that measures changes in luminance, or the like.

As shown in FIG. 42(a-3), in the solid-state imaging device 5000-3-R, the interlayer film 2-1 and the interlayer film 2-2 are formed in this order from the light incident side, and an inner lens 10-1 is formed in the interlayer film 2-1. A third light blocking film 104 is formed (vertically in FIG. 42(a-3)) in the interlayer film (oxide film) 2-1, so as to separate the pixels from each other. A fourth light blocking film 105, and a fifth light blocking film 106 or a sixth light blocking film 107 are formed in the interlayer film (oxide film) 2-2 in this order from the light incident side. The sixth light blocking film 107 extends substantially evenly in the lateral direction with respect to the fourth light blocking film 105 in FIG. 42(a-3). Likewise, the fifth light blocking film 106 also extends substantially evenly in the lateral direction with respect to the fourth light blocking film 105. In FIG. 42(a-3), the width of the sixth light blocking film 107 extending in the lateral direction is substantially the same as the width of the fifth light blocking film 106 extending in the lateral direction. The third light blocking film 104, the fourth light blocking film 105, the fifth light blocking film 106, and the sixth light blocking film 107 may be insulating films or metal films, for example. The insulating films may be formed with silicon oxide films, silicon nitride films, silicon oxynitride films, or the like, for example. The metal films may be formed with tungsten, aluminum, copper, or the like, for example.

A solid-state imaging device 5000-3 (5000-3-G) includes, in the respective pixels, at least microlenses (on-chip lenses) 10, filters (a green filter 5 in FIG. 42(a-4)), a partition wall 4-2 and a partition wall 9-2, a planarizing film 3, interlayer films (oxide films) 2-1 and 2-2, a semiconductor substrate (not shown in FIG. 42(a-4)) in which photoelectric conversion units (photodiodes, for example) are formed, and a wiring layer (not shown), in this order from the light incident side. A ranging pixel may be an image-plane phase difference pixel, for example, but is not necessarily an image-plane phase difference pixel. A ranging pixel may be a pixel that acquires distance information using time-of-flight (TOF) technology, an infrared light receiving pixel, a pixel that receives light of a narrowband wavelength that can be used for specific purposes, a pixel that measures changes in luminance, or the like.

As shown in FIG. 42(a-4), in the solid-state imaging device 5000-3-G, the interlayer film 2-1 and the interlayer film 2-2 are formed in this order from the light incident side, and an inner lens 10-1 is formed in the interlayer film 2-1. A third light blocking film 104 is formed (vertically in FIG. 42(a-4)) in the interlayer film (oxide film) 2-1, so as to separate the pixels from each other. A fourth light blocking film 105, and a fifth light blocking film 106 or a sixth light blocking film 107 are formed in the interlayer film (oxide film) 2-2 in this order from the light incident side. The sixth light blocking film 107 extends substantially evenly in the lateral direction with respect to the fourth light blocking film 105 in FIG. 42(a-4). Likewise, the fifth light blocking film 106 also extends substantially evenly in the lateral direction with respect to the fourth light blocking film 105. In FIG. 42(a-4), the width of the sixth light blocking film 107 extending in the lateral direction is substantially the same as the width of the fifth light blocking film 106 extending in the lateral direction. The third light blocking film 104, the fourth light blocking film 105, the fifth light blocking film 106, and the sixth light blocking film 107 may be insulating films or metal films, for example. The insulating films may be formed with silicon oxide films, silicon nitride films, silicon oxynitride films, or the like, for example. The metal films may be formed with tungsten, aluminum, copper, or the like, for example.

With the solid-state imaging devices 5000-3, the partition wall 4-2 and the partition wall 9-2 are disposed in all the pixels (or may be disposed between each two pixels of all the pixels), and the partition wall 9-1 is disposed so as to surround the ranging pixels (image-plane phase difference pixels, for example). Thus, color mixing between imaging pixels can be reduced, and horizontal flare streaks can be prevented. Note that the specifics of the partition wall 4-2, the partition wall 9-1, and the partition wall 9-2 are as described above, and therefore, explanation thereof is not made herein.

In addition to the contents described above, the contents explained in the descriptions of the solid-state imaging devices of the first to tenth embodiments according to the present technology can be applied, without any change, to the solid-state imaging device of the eleventh embodiment according to the present technology, unless there is some technical contradiction.

### 13. Checking of Light Leakage Rate Lowering Effects

The light leakage rate lowering effects of solid-state imaging devices according to the present technology (solid-state imaging devices according to the first to eleventh embodiments according to the present technology, for example) are now described. A solid-state imaging device Z-1, a solid-state imaging device Z-2, a solid-state imaging device Z-3, a solid-state imaging device Z-4, and a solid-state imaging device Z-5 are used as samples. The solid-state imaging device Z-1 is the reference sample (comparative sample) for the solid-state imaging device Z-2, the solid-state imaging device Z-3, the solid-state imaging device Z-4, and the solid-state imaging device Z-5, and has no partition walls. The solid-state imaging device Z-2 is a sample corresponding to a solid-state imaging device of the eighth embodiment according to the present technology, and the solid-state imaging device Z-3 is a sample corresponding to a solid-state imaging device of the ninth embodiment according to the present technology. The solid-state imaging device Z-4 is a sample corresponding to a solid-state imaging device of the seventh embodiment according to the present technology, and a filter (a cyan filter) that transmits cyan light is disposed in each ranging pixel (phase difference pixel). The solid-state imaging device Z-5 is a sample corresponding to a solid-state imaging device of the seventh embodiment according to the present technology, and a filter (a transparent filter) that transmits white light is disposed in each ranging pixel (phase difference pixel).

First, measurement and evaluation methods for checking a light leakage rate lowering effect are described.

[Measurement Method and Evaluation Method]
Acquiring images obtained by irradiating solid-state imaging devices (image sensors) Z-1 to Z-5 with a parallel light source while swinging these devices in a horizontal direction.
Calculating the absolute value of the difference value between an output value of a (Gr) pixel (an imaging pixel) that is adjacent horizontally to a ranging pixel (a phase difference pixel) and transmits green light, and an output value of a (Gr) pixel that is not adjacent to the ranging pixel (phase difference pixel) and transmits green light.
Calculating a light leakage rate that is the value obtained by standardizing the difference value with the output value of the (Gr) pixel that is not adjacent to the ranging pixel (phase difference pixel) and transmits green light.
Comparing a lowering effect with that of the solid-state imaging device Z-1 as the reference sample (comparative sample), using the value of integral of light leakage rates in a certain angular range.

The resultant light leakage rate lowering effects are shown in FIG. 56. FIG. 56 is a graph showing the resultant light leakage rate lowering effects. The ordinate axis in FIG. 56 indicates the value of integral of light leakage rate, and the abscissa axis in FIG. 56 indicates sample names (solid-state imaging devices Z-1 to Z-5).

As shown in FIG. 56, in comparison with the solid-state imaging device Z-1 (reference sample) whose value of integral of light leakage rate is 100%, the value of integral of light leakage rate of the solid-state imaging device Z-2 is 45%, the value of integral of light leakage rate of the solid-state imaging device Z-3 is 12%, the value of integral of light leakage rate of the solid-state imaging device Z-4 is 5%, and the value of integral of light leakage rate of the solid-state imaging device Z-5 is 7%.

As can be seen from the above, solid-state imaging devices (the solid-state imaging devices Z-2 to Z-5) according to the present technology each have a light leakage rate lowering effect. Particularly, among the solid-state imaging devices Z-2 to Z-5, the light leakage rate lowering effects of the solid-state imaging devices Z-4 and Z-5 corresponding to the seventh embodiment according to the present technology were remarkable. Further, among the solid-state imaging devices Z-2 to Z-5, the degree (level) of decrease in the light leakage rate of the solid-state imaging device Z-4 was the highest at 5%.

### 14. Twelfth Embodiment (Examples of Electronic Apparatuses)

An electronic apparatus of a twelfth embodiment according to the present technology is an electronic apparatus in which a solid-state imaging device of one embodiment among the solid-state imaging devices of the first to eleventh embodiments according to the present technology is mounted. In the description below, electronic apparatuses of the twelfth embodiment according to the present technology are described in detail.

### 15. Examples of Use of Solid-State Imaging Devices to which the Present Technology is Applied

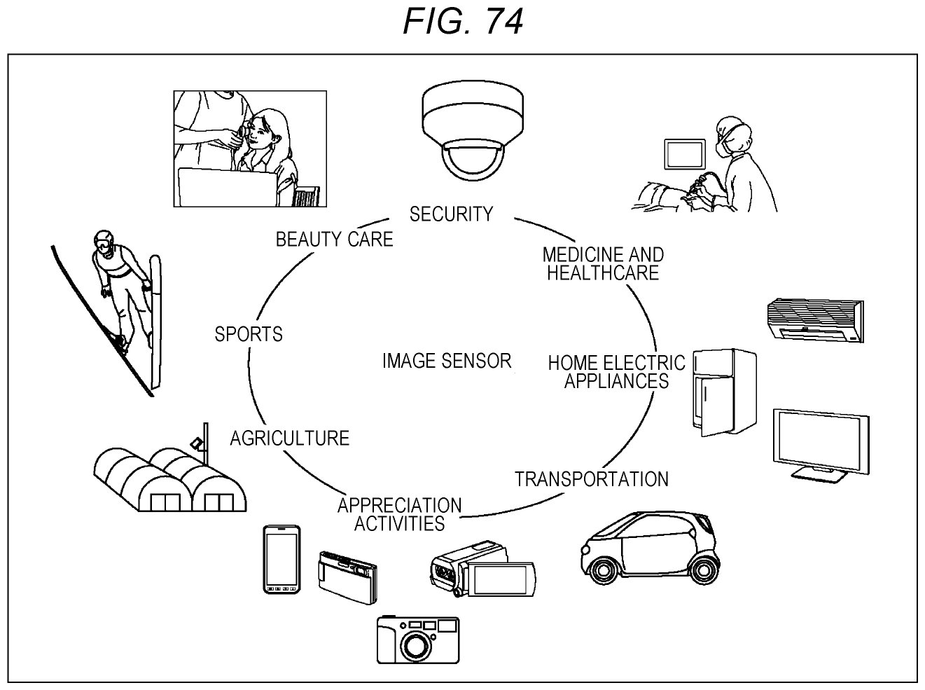

FIG. 74 is a diagram showing examples of use of solid-state imaging devices of the first to eleventh embodiments according to the present technology as image sensors.

Solid-state imaging devices of the first to eleventh embodiments described above can be used in various cases where light such as visible light, infrared light, ultraviolet light, or an X-ray is sensed, as described below, for example. That is, as shown in FIG. 74, solid-state imaging devices of any one of the first to eleventh embodiments can be used in apparatuses (such as an electronic apparatus of the twelfth embodiment described above, for example) that are used in the appreciation activity field where images are taken and are used in appreciation activities, the field of transportation, the field of home electric appliances, the fields of medicine and healthcare, the field of security, the field of beauty care, the field of sports, the field of agriculture, and the like, for example.

Specifically, in the appreciation activity field, a solid-state imaging device of any one of the first to eleventh embodiments can be used in an apparatus for capturing images to be used in appreciation activities, such as a digital camera, a smartphone, or a portable telephone with a camera function, for example.

In the field of transportation, a solid-state imaging device of any one of the first to eleventh embodiments can be used in an apparatus for transportation use, such as a vehicle-mounted sensor designed to capture images of the front, the back, the surroundings, the inside, and the like of an automobile, to perform safe driving such as an automatic stop and recognize the driver's condition or the like, a surveillance camera for monitoring running vehicles and roads, or a ranging sensor for measuring distances between vehicles or the like, for example.

In the field of home electric appliances, a solid-state imaging device of any one of the first to eleventh embodiments can be used in an apparatus to be used as home electric appliances, such as a television set, a refrigerator, or an air conditioner, to capture images of gestures of users and operate the apparatus in accordance with the gestures, for example.

In the fields of medicine and healthcare, a solid-state imaging device of any one of the first to eleventh embodiments can be used in an apparatus for medical use or healthcare use, such as an endoscope or an apparatus for receiving infrared light for angiography, for example.

In the field of security, a solid-state imaging device of any one of the first to eleventh embodiments can be used in an apparatus for security use, such as a surveillance camera for crime prevention or a camera for personal authentication, for example.

In the field of beauty care, a solid-state imaging device of any one of the first to eleventh embodiments can be used in an apparatus for beauty care use, such as a skin measurement apparatus designed to capture images of the skin or a microscope for capturing images of the scalp, for example.

In the field of sports, a solid-state imaging device of any one of the first to eleventh embodiments can be used in an apparatus for sporting use, such as an action camera or a wearable camera for sports or the like, for example.

In the field of agriculture, a solid-state imaging device of any one of the first to eleventh embodiments can be used in an apparatus for agricultural use, such as a camera for monitoring conditions of fields and crops, for example.

Solid-state imaging devices of any one of the first to eleventh embodiments can be used in various kinds of electronic apparatuses, such as imaging apparatuses for digital still cameras and digital video cameras, portable telephone devices having imaging functions, and other apparatuses having imaging functions, for example.

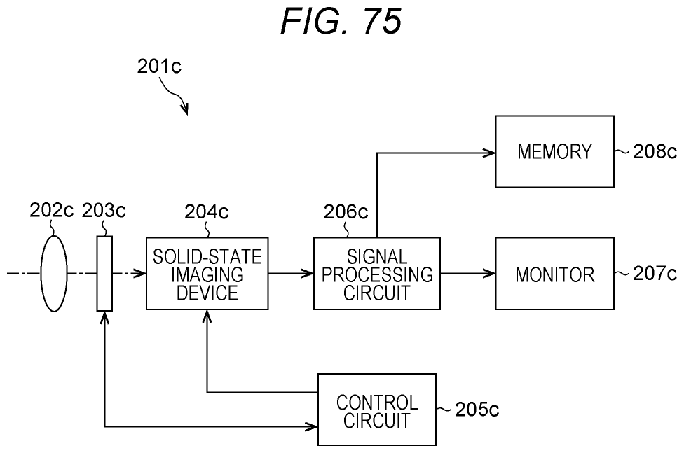

FIG. 75 is a block diagram showing an example configuration of an imaging apparatus as an electronic apparatus to which the present technology is applied.

An imaging apparatus 201c shown in FIG. 75 includes an optical system 202c, a shutter device 203c, a solid-state imaging device 204c, a control circuit 205c, a signal processing circuit 206c, a monitor 207c, and a memory 208c, and can take still images and moving images.

The optical system 202c includes one or more lenses to guide light (incident light) from the object to the solid-state imaging device 204c, and form an image on the light receiving surface of the solid-state imaging device 204c.

The shutter device 203c is disposed between the optical system 202c and the solid-state imaging device 204c, and, under the control of the control circuit 205c, controls the light irradiation period and the light blocking period for the solid-state imaging device 204c.

In accordance with light that is emitted to form an image on the light receiving surface via the optical system 202c and the shutter device 203c, the solid-state imaging device 204c accumulates signal charges for a certain period of time. The signal charges accumulated in the solid-state imaging device 204c are transferred in accordance with a drive signal (timing signal) supplied from the control circuit 205c.

The control circuit 205c outputs the drive signal for controlling transfer operations of the solid-state imaging device 204c and shutter operations of the shutter device 203c, to drive the solid-state imaging device 204c and the shutter device 203c.

The signal processing circuit 206c performs various kinds of signal processing on signal charges that are output from the solid-state imaging device 204c. The image (image data) obtained through the signal processing performed by the signal processing circuit 206c is supplied to and displayed on the monitor 207c, or is supplied to and stored (recorded) into the memory 208c.

### 16. Example Applications of Solid-State Imaging Devices to which the Present Technology is Applied

In the description below, example applications (Example Applications 1 to 6) of solid-state imaging devices (image sensors) described in the first to eleventh embodiments described above are described. Any of the solid-state imaging devices in the above embodiments and the like can be applied to electronic apparatuses in various fields. As such examples, an imaging apparatus (a camera) (Example Application 1), an endoscopic camera (Example Application 2), a vision chip (artificial retina) (Example Application 3), a biological sensor (Example Application 4), an endoscopic surgery system (Provided Example 5), and a mobile structure (Example Application 6) are described herein. Note that the imaging apparatuses described above in <14. Examples of Use of Solid-State Imaging Devices to Which the Present Technology Is Applied> are also example applications of the solid-state imaging devices (image sensors) described in the first to eleventh embodiments according to the present technology.

### Example Application 1

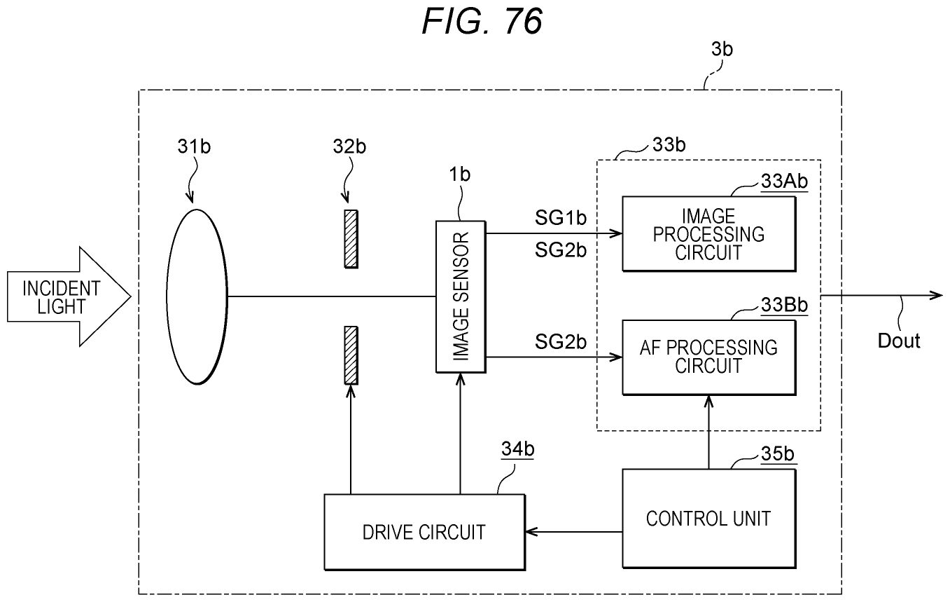

FIG. 76 is a functional block diagram showing the overall configuration of an imaging apparatus (an imaging apparatus 3b). The imaging apparatus 3b is a digital still camera or a digital video camera, and includes an optical system 31b, a shutter device 32b, an image sensor 1b, a signal processing circuit 33b (an image processing circuit 33Ab and an AF processing circuit 33Bb), a drive circuit 34b, and a control unit 35b, for example.

The optical system 31b includes one or a plurality of imaging lenses that form an image with image light (incident light) from the object on the imaging surface of the image sensor 1b. The shutter device 32b controls the light irradiation period (exposure period) and the light blocking period for the image sensor 1b. The drive circuit 34b drives opening and closing of the shutter device 32, and also drives exposure operations and signal reading operations at the image sensor 1b. The signal processing circuit 33b performs predetermined signal processing, such as various correction processes including demosaicing and white balance adjustment, for example, on output signals (SG1b and SG2b) from the image sensor 1b. The control unit 35b is formed with a microcomputer, for example. The control unit 35b controls shutter drive operations and image sensor drive operations at the drive circuit 34b, and also controls signal processing operations at the signal processing circuit 33b.

In this imaging apparatus 3b, when incident light is received by the image sensor 1b via the optical system 31b and the shutter device 32b, the image sensor 1b accumulates the signal charges based on the received light amount. The drive circuit 34b reads the signal charges accumulated in the respective pixels 2b of the image sensor 1b (an electric signal SG1b obtained from an imaging pixel 2Ab and an electric signal SG2b obtained from an image-plane phase difference pixel 2Bb), and outputs the read electric signals SG1b and SG2b to the image processing circuit 33Ab and the AF processing circuit 33Bb of the signal processing circuit 33b. The output signals output from the image sensor 1b are subjected to predetermined signal processing at the signal processing circuit 33b, and are output as a video signal Dout to the outside (such as a monitor), or are held in a storage unit (a storage medium) such as a memory not shown in the drawing.

### Example Application 2

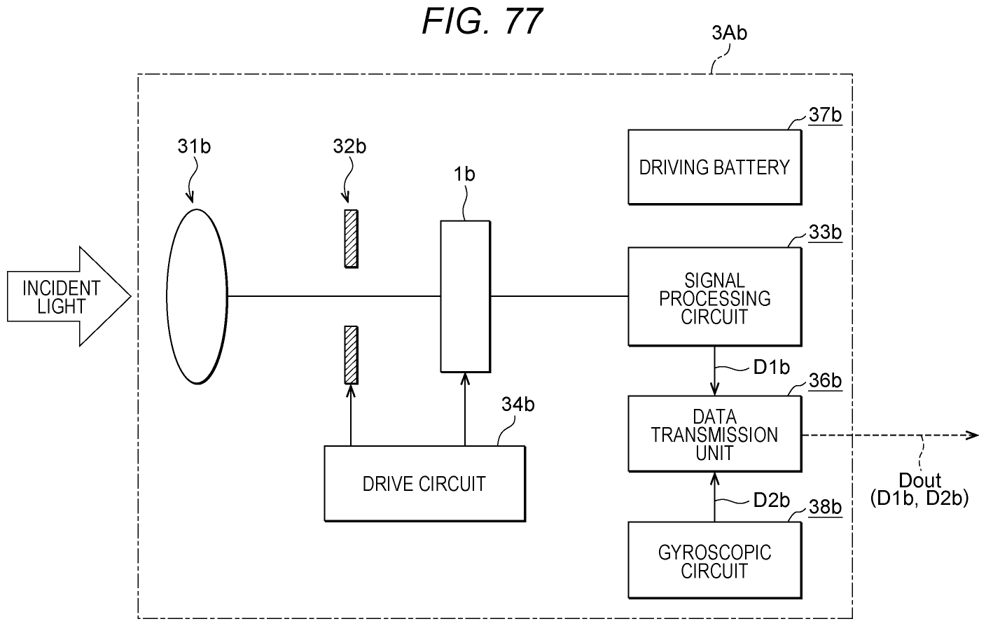

FIG. 77 is a functional block diagram showing the overall configuration of an endoscopic camera (a capsule-type endoscopic camera 3Ab) according to Example Application 2. The capsule-type endoscopic camera 3Ab includes an optical system 31b, a shutter device 32b, an image sensor 1b, a drive circuit 34b, a signal processing circuit 33b, a data transmission unit 36, a driving battery 37b, and a gyroscopic circuit 38b for posture (orientation, angle) sensing. Of these components, the optical system 31b, the shutter device 32b, the drive circuit 34b, and the signal processing circuit 33b have functions similar to those of the optical system 31b, the shutter device 32b, the drive circuit 34b, and the signal processing circuit 33b described above in conjunction with the imaging apparatus 3. However, the optical system 31b is preferably capable of imaging in a plurality of directions (all directions, for example) in a four-dimensional space, and is formed with one or a plurality of lenses. In this example, however, a video signal D1 after signal processing at the signal processing circuit 33b and a posture-sensed signal D2b output from the gyroscopic circuit 38b are transmitted to an external device by wireless communication through the data transmission unit 45b.

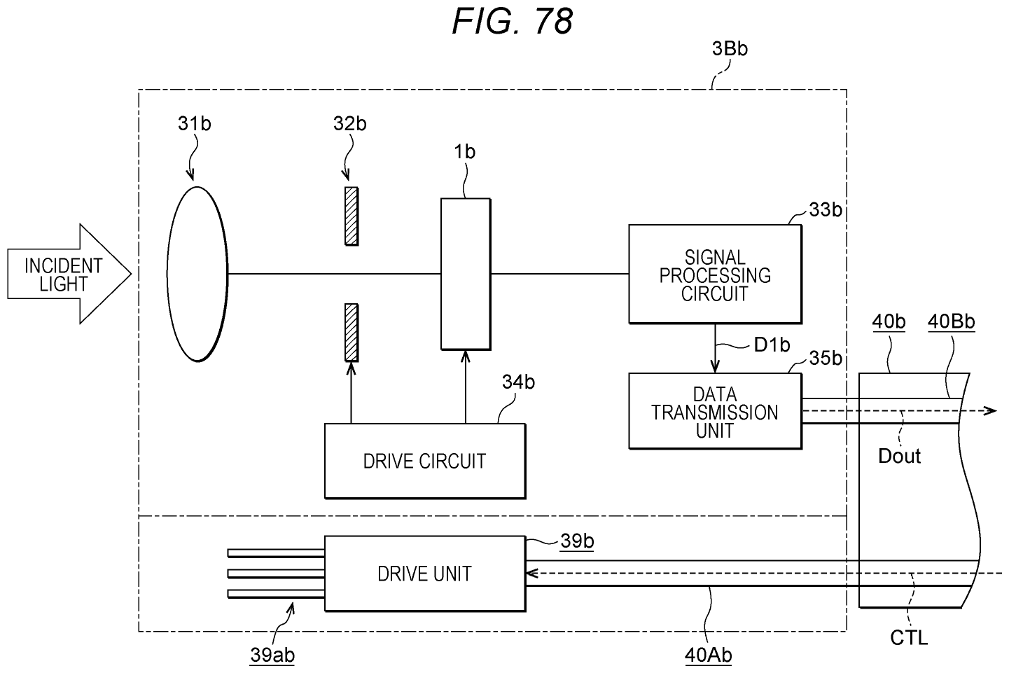

Note that an endoscopic camera to which an image sensor of one of the above embodiments can be applied is not necessarily a capsule-type endoscopic camera like the one described above, but may be an endoscopic camera of an insertion type (an insertion-type endoscopic camera 3Bb) as shown in FIG. 78, for example. Like part of the configuration of the capsule-type endoscopic camera 3A, the insertion-type endoscopic camera 3Bb includes an optical system 31b, a shutter device 32b, an image sensor 1, a drive circuit 34b, a signal processing circuit 33b, and a data transmission unit 35b. However, this insertion-type endoscopic camera 3Bb is further equipped with arms 39ab that can be retracted into the apparatus, and a drive unit 39b that drives the arms 39ab. Such an insertion-type endoscopic camera 3Bb is connected to a cable 40b that includes a wiring line 40Ab for transmitting an arm control signal CTL to the drive unit 39b, and a wiring line 40Bb for transmitting a video signal Dout based on captured images.

### Example Application 3

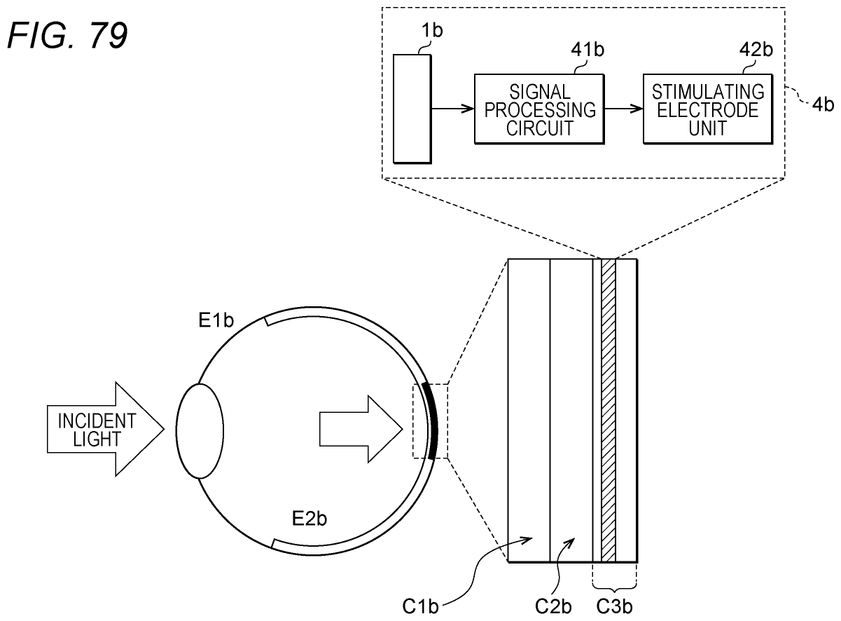

FIG. 79 is a functional block diagram showing the overall configuration of a vision chip (a vision chip 4b) according to Example Application 3. The vision chip 4b is an artificial retina that is buried in part of the backside wall (a retina E2b having visual nerves) of an eyeball E1b. This vision chip 4b is buried in part of ganglion cells C1b, horizontal cells C2b, and photoreceptor cells C3b in the retina E2b, for example, and includes an image sensor 1b, a signal processing circuit 41b, and a stimulating electrode unit 42b. With this arrangement, the image sensor 1b acquires an electric signal based on light incident on the eye, and the electric signal is processed by the signal processing circuit 41b, so that a predetermined control signal is supplied to the stimulating electrode unit 42b. The stimulating electrode unit 42b has a function of providing visual nerves with stimulation (an electric signal), in response to the input control signal.

### Example Application 4

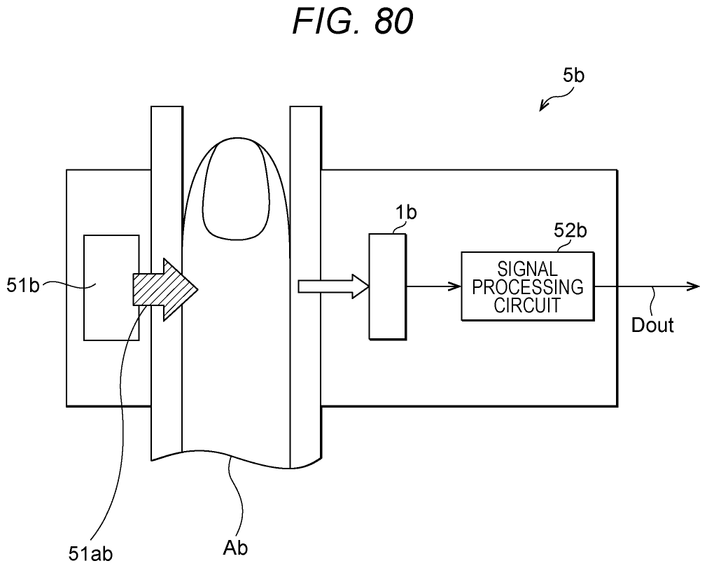

FIG. 80 is a functional block diagram showing the overall configuration of a biological sensor (a biological sensor 5b) according to Example Application 4. The biological sensor 5b is a blood glucose level sensor that can be attached to a finger Ab, for example, and includes a semiconductor laser 51b, an image sensor 1b, and a signal processing circuit 52b. The semiconductor laser 51b is an infrared (IR) laser that emits infrared light (780 nm or longer in wavelength), for example. In such a configuration, the image sensor 1b senses the absorption state of laser light depending on the amount of glucose in the blood, so that the blood glucose level is measured.

### Example Application 5

[Example Application to an Endoscopic Surgery System]

The present technology can be applied to various products. For example, the technology (the present technology) according to the present disclosure may be applied to an endoscopic surgery system.

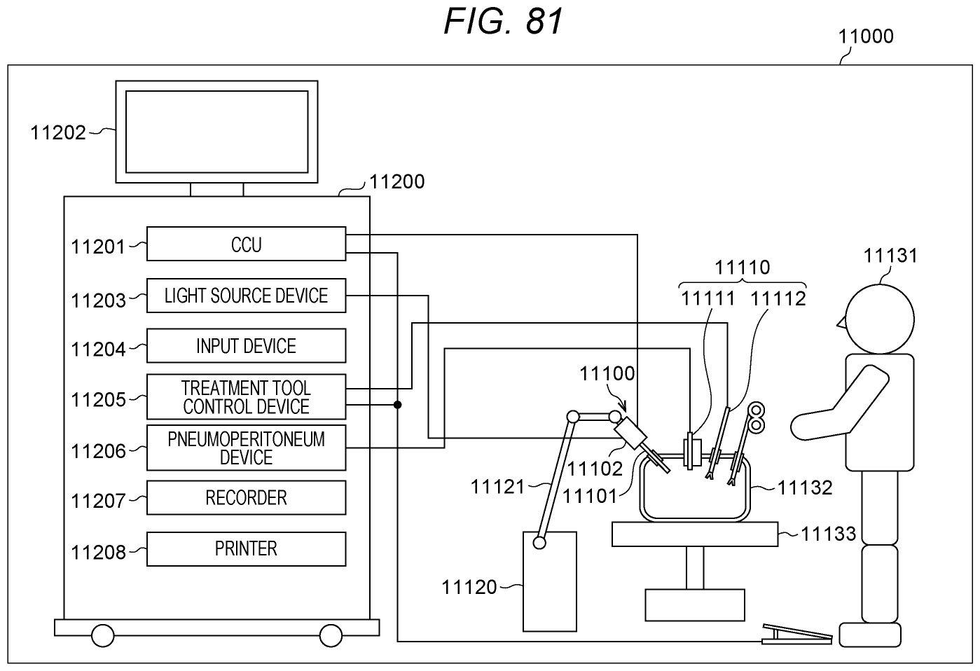

FIG. 81 is a diagram schematically showing an example configuration of an endoscopic surgery system to which the technology (the present technology) according to the present disclosure may be applied.

FIG. 81 shows a situation where a surgeon (a physician) 11131 is performing surgery on a patient 11132 on a patient bed 11133, using an endoscopic surgery system 11000. As shown in the drawing, the endoscopic surgery system 11000 includes an endoscope 11100, other surgical tools 11110 such as a pneumoperitoneum tube 11111 and an energy treatment tool 11112, a support arm device 11120 that supports the endoscope 11100, and a cart 11200 on which various kinds of devices for endoscopic surgery are mounted.

The endoscope 11100 includes a lens barrel 11101 that has a region of a predetermined length from the top end to be inserted into a body cavity of the patient 11132, and a camera head 11102 connected to the base end of the lens barrel 11101. In the example shown in the drawing, the endoscope 11100 is designed as a so-called rigid scope having a rigid lens barrel 11101. However, the endoscope 11100 may be designed as a so-called flexible scope having a flexible lens barrel.

At the top end of the lens barrel 11101, an opening into which an objective lens is inserted is provided. A light source device 11203 is connected to the endoscope 11100, and the light generated by the light source device 11203 is guided to the top end of the lens barrel by a light guide extending inside the lens barrel 11101, and is emitted toward the current observation target in the body cavity of the patient 11132 via the objective lens. Note that the endoscope 11100 may be a forward-viewing endoscope, an oblique-viewing endoscope, or a side-viewing endoscope.

An optical system and imaging elements are provided inside the camera head 11102, and reflected light (observation light) from the current observation target is converged on the imaging elements by the optical system. The observation light is photoelectrically converted by the imaging elements, and an electrical signal corresponding to the observation light, or an image signal corresponding to the observation image, is generated. The image signal is transmitted as RAW data to a camera control unit (CCU) 11201.

The CCU 11201 is formed with a central processing unit (CPU), a graphics processing unit (GPU), or the like, and collectively controls operations of the endoscope 11100 and a display device 11202. Further, the CCU 11201 receives an image signal from the camera head 11102, and subjects the image signal to various kinds of image processing, such as a development process (a demosaicing process), for example, to display an image based on the image signal.

Under the control of the CCU 11201, the display device 11202 displays an image based on the image signal subjected to the image processing by the CCU 11201.

The light source device 11203 is formed with a light source such as a light emitting diode (LED), for example, and supplies the endoscope 11100 with illuminating light for imaging the surgical site or the like.

An input device 11204 is an input interface to the endoscopic surgery system 11000. The user can input various kinds of information and instructions to the endoscopic surgery system 11000 via the input device 11204. For example, the user inputs an instruction or the like to change imaging conditions (such as the type of illuminating light, the magnification, and the focal length) for the endoscope 11100.

A treatment tool control device 11205 controls driving of the energy treatment tool 11112 for tissue cauterization, incision, blood vessel sealing, or the like. A pneumoperitoneum device 11206 injects a gas into a body cavity of the patient 11132 via the pneumoperitoneum tube 11111 to inflate the body cavity, for the purpose of securing the field of view of the endoscope 11100 and the working space of the surgeon. A recorder 11207 is a device capable of recording various kinds of information about the surgery. A printer 11208 is a device capable of printing various kinds of information relating to the surgery in various formats such as text, images, graphics, and the like.

Note that the light source device 11203 that supplies the endoscope 11100 with the illuminating light for imaging the surgical site can be formed with an LED, a laser light source, or a white light source that is a combination of an LED and a laser light source, for example. In a case where a white light source is formed with a combination of RGB laser light sources, the output intensity and the output timing of each color (each wavelength) can be controlled with high precision. Accordingly, the white balance of an image captured by the light source device 11203 can be adjusted. Alternatively, in this case, laser light from each of the RGB laser light sources may be emitted onto the current observation target in a time-division manner, and driving of the imaging elements of the camera head 11102 may be controlled in synchronization with the timing of the light emission. Thus, images corresponding to the respective RGB colors can be captured in a time-division manner. According to the method, a color image can be obtained without any filter provided in the imaging elements.

Further, the driving of the light source device 11203 may also be controlled so that the intensity of light to be output is changed at predetermined time intervals. The driving of the imaging elements of the camera head 11102 is controlled in synchronism with the timing of the change in the intensity of the light, and images are acquired in a time-division manner and are then combined. Thus, a high dynamic range image with no black portions and no white spots can be generated.

Further, the light source device 11203 may also be designed to be capable of supplying light of a predetermined wavelength band compatible with special light observation. In special light observation, light of a narrower band than the illuminating light (or white light) at the time of normal observation is emitted, with the wavelength dependence of light absorption in body tissue being taken advantage of, for example. As a result, so-called narrow band light observation (narrow band imaging) is performed to image predetermined tissue such as a blood vessel in a mucosal surface layer or the like, with high contrast. Alternatively, in the special light observation, fluorescence observation for obtaining an image with fluorescence generated through emission of excitation light may be performed. In fluorescence observation, excitation light is emitted to body tissue so that the fluorescence from the body tissue can be observed (autofluorescence observation). Alternatively, a reagent such as indocyanine green (ICG) is locally injected into body tissue, and excitation light corresponding to the fluorescence wavelength of the reagent is emitted to the body tissue so that a fluorescent image can be obtained, for example. The light source device 11203 can be designed to be capable of supplying narrow band light and/or excitation light compatible with such special light observation.

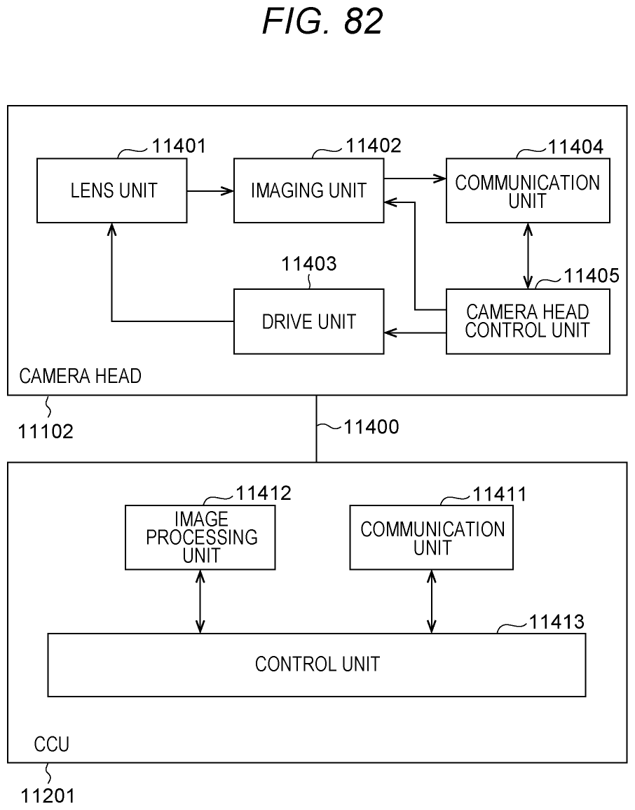

FIG. 82 is a block diagram showing an example of the functional configurations of the camera head 11102 and the CCU 11201 shown in FIG. 81.

The camera head 11102 includes a lens unit 11401, an imaging unit 11402, a drive unit 11403, a communication unit 11404, and a camera head control unit 11405. The CCU 11201 includes a communication unit 11411, an image processing unit 11412, and a control unit 11413. The camera head 11102 and the CCU 11201 are communicably connected to each other by a transmission cable 11400.

The lens unit 11401 is an optical system provided at the connecting portion with the lens barrel 11101. Observation light captured from the top end of the lens barrel 11101 is guided to the camera head 11102, and enters the lens unit 11401. The lens unit 11401 is formed with a combination of a plurality of lenses including a zoom lens and a focus lens.

The imaging unit 11402 is formed with an imaging device (imaging element). The imaging unit 11402 may be formed with one imaging element (a so-called single-plate type), or may be formed with a plurality of imaging elements (a so-called multiple-plate type). In a case where the imaging unit 11402 is of a multiple-plate type, for example, image signals corresponding to the respective RGB colors may be generated by the respective imaging elements, and be then combined to obtain a color image. Alternatively, the imaging unit 11402 may be designed to include a pair of imaging elements for acquiring right-eye and left-eye image signals compatible with three-dimensional (3D) display. As the 3D display is conducted, the surgeon 11131 can grasp more accurately the depth of the body tissue at the surgical site. Note that, in a case where the imaging unit 11402 is of a multiple-plate type, a plurality of lens units 11401 is provided for the respective imaging elements.

Further, the imaging unit 11402 is not necessarily provided in the camera head 11102. For example, the imaging unit 11402 may be provided immediately behind the objective lens in the lens barrel 11101.

The drive unit 11403 is formed with an actuator, and, under the control of the camera head control unit 11405, moves the zoom lens and the focus lens of the lens unit 11401 by a predetermined distance along the optical axis. With this arrangement, the magnification and the focal point of the image captured by the imaging unit 11402 can be adjusted as appropriate.

The communication unit 11404 is formed with a communication device for transmitting and receiving various kinds of information to and from the CCU 11201. The communication unit 11404 transmits the image signal obtained as RAW data from the imaging unit 11402 to the CCU 11201 via the transmission cable 11400.

The communication unit 11404 also receives a control signal for controlling the driving of the camera head 11102 from the CCU 11201, and supplies the control signal to the camera head control unit 11405. The control signal includes information regarding imaging conditions, such as information for specifying the frame rate of captured images, information for specifying the exposure value at the time of imaging, and/or information for specifying the magnification and the focal point of captured images, for example.

Note that the above imaging conditions such as the frame rate, the exposure value, the magnification, and the focal point may be appropriately specified by the user, or may be automatically set by the control unit 11413 of the CCU 11201 on the basis of an acquired image signal. In the latter case, the endoscope 11100 has a so-called auto-exposure (AE) function, an auto-focus (AF) function, and an auto-white-balance (AWB) function.

The camera head control unit 11405 controls the driving of the camera head 11102, on the basis of a control signal received from the CCU 11201 via the communication unit 11404.

The communication unit 11411 is formed with a communication device for transmitting and receiving various kinds of information to and from the camera head 11102. The communication unit 11411 receives an image signal transmitted from the camera head 11102 via the transmission cable 11400.

Further, the communication unit 11411 also transmits a control signal for controlling the driving of the camera head 11102, to the camera head 11102. The image signal and the control signal can be transmitted through electrical communication, optical communication, or the like.

The image processing unit 11412 performs various kinds of image processing on an image signal that is RAW data transmitted from the camera head 11102.

The control unit 11413 performs various kinds of control relating to display of an image of the surgical portion or the like captured by the endoscope 11100, and a captured image obtained through imaging of the surgical site or the like. For example, the control unit 11413 generates a control signal for controlling the driving of the camera head 11102.

Further, the control unit 11413 also causes the display device 11202 to display a captured image showing the surgical site or the like, on the basis of the image signal subjected to the image processing by the image processing unit 11412. In doing so, the control unit 11413 may recognize the respective objects shown in the captured image, using various image recognition techniques. For example, the control unit 11413 can detect the shape, the color, and the like of the edges of an object shown in the captured image, to recognize the surgical tool such as forceps, a specific body site, bleeding, the mist at the time of use of the energy treatment tool 11112, and the like. When causing the display device 11202 to display the captured image, the control unit 11413 may cause the display device 11202 to superimpose various kinds of surgery aid information on the image of the surgical site on the display, using the recognition result. As the surgery aid information is superimposed and displayed, and thus, is presented to the surgeon 11131, it becomes possible to reduce the burden on the surgeon 11131, and enable the surgeon 11131 to proceed with the surgery in a reliable manner.

The transmission cable 11400 connecting the camera head 11102 and the CCU 11201 is an electrical signal cable compatible with electric signal communication, an optical fiber compatible with optical communication, or a composite cable thereof.

Here, in the example shown in the drawing, communication is performed in a wired manner using the transmission cable 11400. However, communication between the camera head 11102 and the CCU 11201 may be performed in a wireless manner.

An example of an endoscopic surgery system to which the technique according to the present disclosure can be applied has been described above. The technology according to the present disclosure may be applied to the endoscope 11100, the imaging unit 11402 of the camera head 11102, and the like in the configuration described above, for example. Specifically, the solid-state imaging device 111 of the present disclosure can be applied to the imaging unit 10402. As the technology according to the present disclosure is applied to the endoscope 11100, (the imaging unit 11402 of) the camera head 11102, and the like, it is possible to improve the performance, the quality, and the like of the endoscope 11100, (the imaging unit 11402 of) the camera head 11102, and the like.

Although the endoscopic surgery system has been described as an example herein, the technology according to the present disclosure may be applied to a microscopic surgery system or the like, for example.

### Example Application 6

[Example Applications to Mobile Structures]

The technology (the present technology) according to the present disclosure can be applied to various products. For example, the technology according to the present disclosure may be embodied as a device mounted on any type of mobile structure, such as an automobile, an electrical vehicle, a hybrid electrical vehicle, a motorcycle, a bicycle, a personal mobility device, an airplane, a drone, a vessel, or a robot.

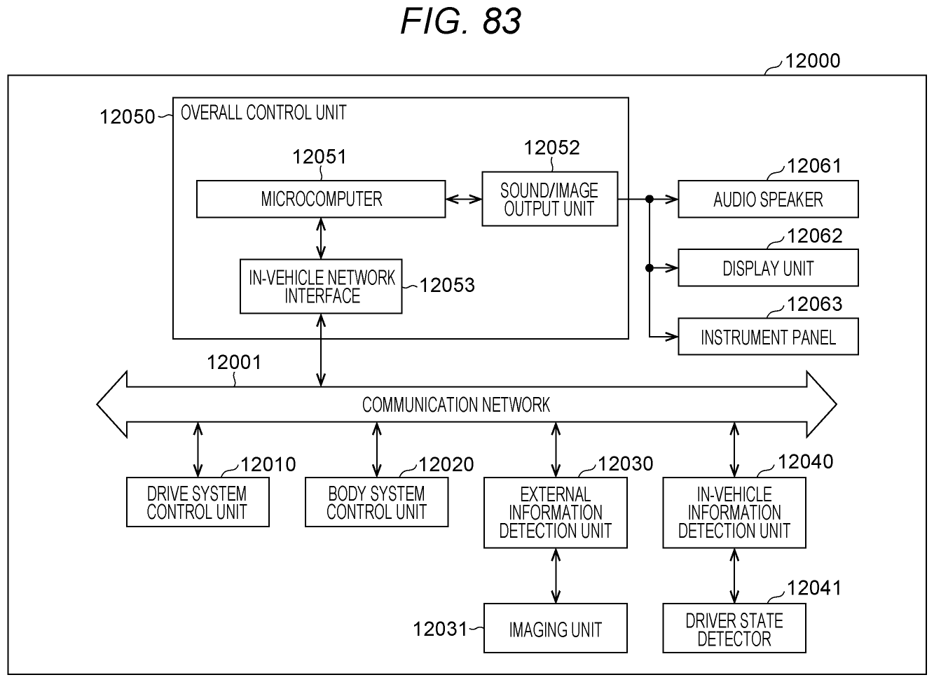

FIG. 83 is a block diagram schematically showing an example configuration of a vehicle control system that is an example of a mobile structure control system to which the technology according to the present disclosure can be applied.

A vehicle control system 12000 includes a plurality of electronic control units connected via a communication network 12001. In the example shown in FIG. 83, the vehicle control system 12000 includes a drive system control unit 12010, a body system control unit 12020, an external information detection unit 12030, an in-vehicle information detection unit 12040, and an overall control unit 12050. Further, a microcomputer 12051, a sound/image output unit 12052, and an in-vehicle network interface (I/F) 12053 are shown as the functional components of the overall control unit 12050.

The drive system control unit 12010 controls operations of the devices related to the drive system of the vehicle according to various programs. For example, the drive system control unit 12010 functions as control devices such as a driving force generation device for generating a driving force of the vehicle such as an internal combustion engine or a driving motor, a driving force transmission mechanism for transmitting the driving force to the wheels, a steering mechanism for adjusting the steering angle of the vehicle, and a braking device for generating a braking force of the vehicle.

The body system control unit 12020 controls operations of the various devices mounted on the vehicle body according to various programs. For example, the body system control unit 12020 functions as a keyless entry system, a smart key system, a power window device, or a control device for various lamps such as a headlamp, a backup lamp, a brake lamp, a turn signal lamp, a fog lamp, or the like. In this case, the body system control unit 12020 can receive radio waves transmitted from a portable device that substitutes for a key, or signals from various switches. The body system control unit 12020 receives inputs of these radio waves or signals, and controls the door lock device, the power window device, the lamps, and the like of the vehicle.

The external information detection unit 12030 detects information outside the vehicle equipped with the vehicle control system 12000. For example, an imaging unit 12031 is connected to the external information detection unit 12030. The external information detection unit 12030 causes the imaging unit 12031 to capture an image of the outside of the vehicle, and receives the captured image. On the basis of the received image, the external information detection unit 12030 may perform an object detection process for detecting a person, a vehicle, an obstacle, a sign, characters on the road surface, or the like, or perform a distance detection process.

The imaging unit 12031 is an optical sensor that receives light, and outputs an electrical signal corresponding to the amount of received light. The imaging unit 12031 can output an electrical signal as an image, or output an electrical signal as ranging information. Further, the light to be received by the imaging unit 12031 may be visible light, or may be invisible light such as infrared rays.

The in-vehicle information detection unit 12040 detects information about the inside of the vehicle. For example, a driver state detector 12041 that detects the state of the driver is connected to the in-vehicle information detection unit 12040. The driver state detector 12041 includes a camera that captures an image of the driver, for example, and, on the basis of detected information input from the driver state detector 12041, the in-vehicle information detection unit 12040 may calculate the degree of fatigue or the degree of concentration of the driver, or determine whether or not the driver is dozing off.

On the basis of the external/internal information acquired by the external information detection unit 12030 or the in-vehicle information detection unit 12040, the microcomputer 12051 can calculate the control target value of the driving force generation device, the steering mechanism, or the braking device, and output a control command to the drive system control unit 12010. For example, the microcomputer 12051 can perform cooperative control to achieve the functions of an advanced driver assistance system (ADAS), including vehicle collision avoidance or impact mitigation, follow-up running based on the distance between vehicles, vehicle velocity maintenance running, vehicle collision warning, vehicle lane deviation warning, or the like.

Further, the microcomputer 12051 can also perform cooperative control to conduct automatic driving or the like for autonomously running not depending on the operation of the driver, by controlling the driving force generation device, the steering mechanism, the braking device, or the like on the basis of information about the surroundings of the vehicle, the information having being acquired by the external information detection unit 12030 or the in-vehicle information detection unit 12040.

The microcomputer 12051 can also output a control command to the body system control unit 12020, on the basis of the external information acquired by the external information detection unit 12030. For example, the microcomputer 12051 controls the headlamp in accordance with the position of the leading vehicle or the oncoming vehicle detected by the external information detection unit 12030, and performs cooperative control to achieve an anti-glare effect by switching from a high beam to a low beam, or the like.

The sound/image output unit 12052 transmits an audio output signal and/or an image output signal to an output device that is capable of visually or audibly notifying the passenger(s) of the vehicle or the outside of the vehicle of information. In the example shown in FIG. 83, an audio speaker 12061, a display unit 12062, and an instrument panel 12063 are shown as output devices. The display unit 12062 may include an on-board display and/or a head-up display, for example.

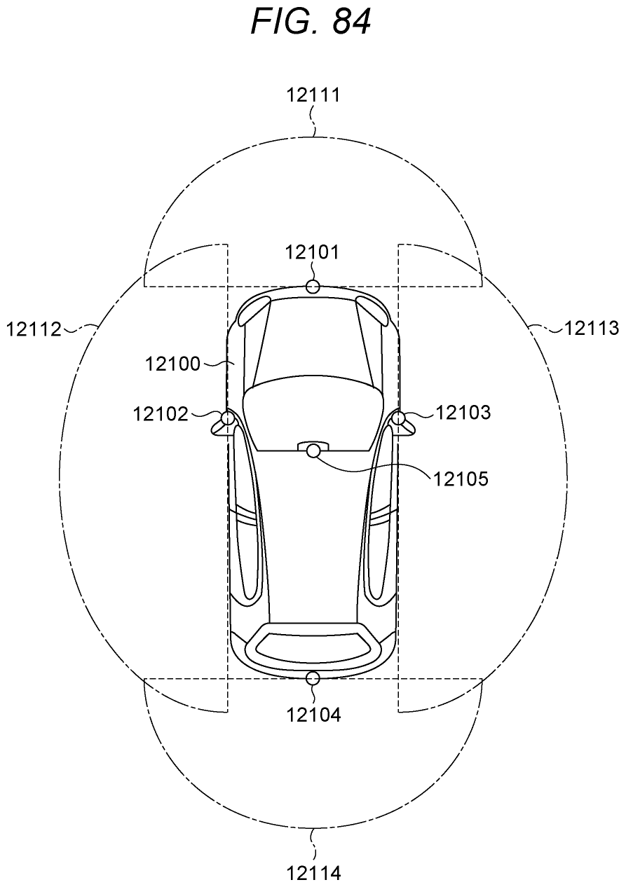

FIG. 84 is a diagram showing an example of installation positions of imaging units 12031.

In FIG. 84, a vehicle 12100 includes imaging units 12101, 12102, 12103, 12104, and 12105 as the imaging units 12031.

Imaging units 12101, 12102, 12103, 12104, and 12105 are provided at the following positions: the front end edge of a vehicle 12100, a side mirror, the rear bumper, a rear door, an upper portion of the front windshield inside the vehicle, and the like, for example. The imaging unit 12101 provided on the front end edge and the imaging unit 12105 provided on the upper portion of the front windshield inside the vehicle mainly capture images ahead of the vehicle 12100. The imaging units 12102 and 12103 provided on the side mirrors mainly capture images on the sides of the vehicle 12100. The imaging unit 12104 provided on the rear bumper or a rear door mainly captures images behind the vehicle 12100. The front images acquired by the imaging units 12101 and 12105 are mainly used for detection of a vehicle running in front of the vehicle 12100, a pedestrian, an obstacle, a traffic signal, a traffic sign, a lane, or the like.

Note that FIG. 84 shows an example of the imaging ranges of the imaging units 12101 to 12104. An imaging range 12111 indicates the imaging range of the imaging unit 12101 provided on the front end edge, imaging ranges 12112 and 12113 indicate the imaging ranges of the imaging units 12102 and 12103 provided on the respective side mirrors, and an imaging range 12114 indicates the imaging range of the imaging unit 12104 provided on the rear bumper or a rear door. For example, image data captured by the imaging units 12101 to 12104 are superimposed on one another, so that an overhead image of the vehicle 12100 viewed from above is obtained.

At least one of the imaging units 12101 to 12104 may have a function of acquiring distance information. For example, at least one of the imaging units 12101 to 12104 may be a stereo camera including a plurality of imaging elements, or may be imaging elements having pixels for phase difference detection.

For example, on the basis of distance information obtained from the imaging units 12101 to 12104, the microcomputer 12051 calculates the distances to the respective three-dimensional objects within the imaging ranges 12111 to 12114, and temporal changes in the distances (the velocities relative to the vehicle 12100). In this manner, the three-dimensional object that is the closest three-dimensional object on the traveling path of the vehicle 12100 and is traveling at a predetermined velocity (0 km/h or higher, for example) in substantially the same direction as the vehicle 12100 can be extracted as the vehicle running in front of the vehicle 12100. Further, the microcomputer 12051 can set beforehand an inter-vehicle distance to be maintained in front of the vehicle running in front of the vehicle 12100, and can perform automatic brake control (including follow-up stop control), automatic acceleration control (including follow-up start control), and the like. In this manner, it is possible to perform cooperative control to conduct automatic driving or the like to autonomously travel not depending on the operation of the driver.

For example, in accordance with the distance information obtained from the imaging units 12101 to 12104, the microcomputer 12051 can extract three-dimensional object data concerning three-dimensional objects under the categories of two-wheeled vehicles, regular vehicles, large vehicles, pedestrians, utility poles, and the like, and use the three-dimensional object data in automatically avoiding obstacles. For example, the microcomputer 12051 classifies the obstacles in the vicinity of the vehicle 12100 into obstacles visible to the driver of the vehicle 12100 and obstacles difficult to visually recognize. The microcomputer 12051 then determines collision risks indicating the risks of collision with the respective obstacles. If a collision risk is equal to or higher than a set value, and there is a possibility of collision, the microcomputer 12051 can output a warning to the driver via the audio speaker 12061 and the display unit 12062, or can perform driving support for avoiding collision by performing forced deceleration or avoiding steering via the drive system control unit 12010.

At least one of the imaging units 12101 to 12104 may be an infrared camera that detects infrared rays. For example, the microcomputer 12051 can recognize a pedestrian by determining whether or not a pedestrian exists in images captured by the imaging units 12101 to 12104. Such pedestrian recognition is carried out through a process of extracting feature points from the images captured by the imaging units 12101 to 12104 serving as infrared cameras, and a process of performing a pattern matching on the series of feature points indicating the outlines of objects and determining whether or not there is a pedestrian, for example. If the microcomputer 12051 determines that a pedestrian exists in the images captured by the imaging units 12101 to 12104, and recognizes a pedestrian, the sound/image output unit 12052 controls the display unit 12062 to display a rectangular contour line for emphasizing the recognized pedestrian in a superimposed manner. Further, the sound/image output unit 12052 may also control the display unit 12062 to display an icon or the like indicating the pedestrian at a desired position.

An example of a vehicle control system to which the technology (the present technology) according to the present disclosure may be applied has been described above. The technology according to the present disclosure can be applied to the imaging units 12031 and the like among the components described above, for example. Specifically, the solid-state imaging device 111 of the present disclosure can be applied to the imaging units 12031. As the technique according to the present disclosure is applied to the imaging units 12031, it is possible to improve the performance, the quality, and the like of the imaging units 12031.

Note that the present technology is not limited to the embodiments and examples uses (example applications) described above, and various modifications may be made to them without departing from the scope of the present technology.

Further, the advantageous effects described in this specification are merely examples, and the advantageous effects of the present technology are not limited to them and may include other effects.

The present technology may also be embodied in the configurations described below.

[1]

A solid-state imaging device including

a plurality of imaging pixels that is orderly arranged in accordance with a certain pattern,

in which

the imaging pixels include: at least a semiconductor substrate in which a photoelectric conversion unit is formed; and a filter that transmits certain light and is formed on a light incidence face side of the semiconductor substrate,

at least one of the plurality of the imaging pixels is replaced with a ranging pixel having a filter that transmits the certain light, to form at least one ranging pixel,

a partition wall is formed between the filter of the at least one ranging pixel and the filter adjacent to the filter of the at least one ranging pixel, and

the partition wall contains a material that is almost the same as a material of the filter of the at least one imaging pixel.

[2]

The solid-state imaging device according to [1], in which the partition wall is formed in such a manner as to surround the at least one ranging pixel.

[3]

The solid-state imaging device according to [1] or [2], in which the partition wall is formed between the filter of the imaging pixel and the filter adjacent to the filter of the imaging pixel, in such a manner as to surround the imaging pixel.

[4]

The solid-state imaging device according to [3], in which

a width of the partition wall that is formed between the ranging pixel and the imaging pixel in such a manner as to surround the at least one ranging pixel differs from

a width of the partition wall that is formed between two of the imaging pixels in such a manner as to surround the imaging pixel.

[5]

The solid-state imaging device according to [3], in which

a width of the partition wall that is formed between the ranging pixel and the imaging pixel in such a manner as to surround the at least one ranging pixel is almost the same as

a width of the partition wall that is formed between two of the imaging pixels in such a manner as to surround the imaging pixel.

[6]

The solid-state imaging device according to any one of [1] to [5], in which the partition wall includes a plurality of layers.

[7]

The solid-state imaging device according to [6], in which the partition wall includes a first organic film and a second organic film in order from a light incident side.

[8]

The solid-state imaging device according to [1], in which the first organic film is formed with a light-transmitting resin film.

[9]

The solid-state imaging device according to [8], in which the light-transmitting resin film is a resin film that transmits red light, blue light, green light, white light, cyan light, magenta light, or yellow light.

[10]

The solid-state imaging device according to any one of [7] to [9], in which the second organic film is formed with a light-absorbing resin film.

[11]

The solid-state imaging device according to [10], in which the light-absorbing resin film is a light-absorbing resin film containing a carbon black pigment or a titanium black pigment.

[12]

The solid-state imaging device according to any one of [1] to [11], further including a light blocking film formed on a side opposite from a light incident side of the partition wall.

[13]

The solid-state imaging device according to [12], in which the light blocking film is a metal film or an insulating film.

[14]

The solid-state imaging device according to [12] or [13], in which the light blocking film includes a fourth light blocking film and a second light blocking film in order from the light incident side.

[15]

The solid-state imaging device according to [14], in which the second light blocking film is formed to block light to be received by the ranging pixel.

[16]

The solid-state imaging device according to any one of [1] to [14], in which

the plurality of imaging pixels includes a pixel having a filter that transmits blue light, a pixel having a filter that transmits green light, and a pixel having a filter that transmits red light, and

the plurality of imaging pixels is orderly arranged in accordance with a Bayer array.

[17]

The solid-state imaging device according to [16], in which

the pixel having the filter that transmits blue light is replaced with the ranging pixel having the filter that transmits the certain light, to form the ranging pixel,

a partition wall is formed between the filter of the ranging pixel and four of the filters that transmit green light and are adjacent to the filter of the ranging pixel, in such a manner as to surround the ranging pixel, and

the partition wall contains a material that is almost the same as a material of the filter that transmits blue light.

[18]

The solid-state imaging device according to [16], in which

the pixel having the filter that transmits red light is replaced with the ranging pixel having the filter that transmits the certain light, to form the ranging pixel,

a partition wall is formed between the filter of the ranging pixel and four of the filters that transmit green light and are adjacent to the filter of the ranging pixel, in such a manner as to surround the ranging pixel, and

the partition wall contains a material that is almost the same as a material of the filter that transmits red light.

[19]

The solid-state imaging device according to [16], in which

the pixel having the filter that transmits green light is replaced with the ranging pixel having the filter that transmits the certain light, to form the ranging pixel,

a partition wall is formed between the filter of the ranging pixel and two of the filters that transmit blue light and are adjacent to the filter of the ranging pixel, and between the filter of the ranging pixel and two of the filters that transmit red light and are adjacent to the filter of the ranging pixel, in such a manner as to surround the ranging pixel, and

the partition wall contains a material that is almost the same as a material of the filter that transmits green light.

[20]

The solid-state imaging device according to any one of [1] to [19], in which the filter of the ranging pixel contains a material that transmits red light, blue light, green light, white light, cyan light, magenta light, or yellow light.

[21]

A solid-state imaging device including

a plurality of imaging pixels,

in which

the imaging pixels each include a photoelectric conversion unit formed in a semiconductor substrate, and a filter formed on a light incidence face side of the photoelectric conversion unit,

a ranging pixel is formed in at least one imaging pixel of the plurality of imaging pixels,

a partition wall is formed in at least part of a region between a filter of the ranging pixel and the filter of an imaging pixel adjacent to the ranging pixel, and

the partition wall contains a material forming the filter of one imaging pixel of the plurality of imaging pixels.

[22]

The solid-state imaging device according to [21], in which

the plurality of imaging pixels includes a first pixel, a second pixel, a third pixel, and a fourth pixel that are adjacent to one another in a first row, and a fifth pixel, a sixth pixel, a seventh pixel, and an eighth pixel that are adjacent to one another in a second row adjacent to the first row,

the first pixel is adjacent to the fifth pixel,

the filters of the first pixel and the third pixel include a filter that transmits light in a first wavelength band,

the filters of the second pixel, the fourth pixel, the fifth pixel, and the seventh pixel include a filter that transmits light in a second wavelength band,

the filter of the eighth pixel includes a filter that transmits light in a third wavelength band,

the ranging pixel is formed in the sixth pixel,

a partition wall is formed at least in part of a region between the filter of the sixth pixel and the filter of a pixel adjacent to the sixth pixel, and

the partition wall contains a material that forms the filter that transmits light in the third wavelength band.

[23]

The solid-state imaging device according to [22], in which the light in the first wavelength band is red light, the light in the second wavelength band is green light, and the light in the third wavelength band is blue light.

[24]

The solid-state imaging device according to any one of [21] to [23], in which the filter of the ranging pixel includes a different material from the partition wall or the filter of the imaging pixel adjacent to the ranging pixel.

[25]

The solid-state imaging device according to any one of [21] to [24], in which the partition wall is formed between the ranging pixel and the filter of the adjacent pixel, in such a manner as to surround at least part of the filter of the ranging pixel.

[26]

The solid-state imaging device according to any one of [21] to [25], further including an on-chip lens on the light incidence face side of the filter.

[27]

The solid-state imaging device according to [26], in which the filter of the ranging pixel contains one of the materials forming a filter, a transparent film, and the on-chip lens.

[28]

A solid-state imaging device including

a plurality of imaging pixels that is orderly arranged in accordance with a certain pattern,

in which

the imaging pixels include: at least a semiconductor substrate in which a photoelectric conversion unit is formed; and a filter that transmits certain light and is formed on a light incidence face side of the semiconductor substrate,

at least one of the plurality of the imaging pixels is replaced with a ranging pixel having the filter that transmits the certain light, to form at least one ranging pixel,

a partition wall is formed between the filter of the at least one ranging pixel and the filter adjacent to the filter of the at least one ranging pixel, and

the partition wall contains a light-absorbing material.

[29]

An electronic apparatus including the solid-state imaging device according to any one of [1] to [28].

### REFERENCE SIGNS LIST

1 (1-1, 1-2, 1-3, 1-4, 1-5, 1-6, 1000-1. 2000-1, 3000-1) Solid-state imaging device
2 Interlayer film (oxide film)
3 Planarizing film
4, 4-1, 4-2 Partition wall
5 Filter that transmits green light (imaging pixel)
6 Filter that transmits red light (imaging pixel)
7 Filter that transmits cyan light (ranging pixel)
8 Filter that transmits blue light (imaging pixel)
9, 9-1, 9-2, 9-3 Partition wall
101 First light blocking film
102 Second light blocking film
103 Second light blocking film
104 Third light blocking film
105 Fourth light blocking film
106 Fifth light blocking film
107 Sixth light blocking film

1. A solid-state imaging device comprising
a plurality of imaging pixels that is orderly arranged in accordance with a certain pattern,
wherein
the imaging pixels include: at least a semiconductor substrate in which a photoelectric conversion unit is formed; and a filter that transmits certain light and is formed on a light incidence face side of the semiconductor substrate,
at least one of the plurality of the imaging pixels is replaced with a ranging pixel having a filter that transmits the certain light, to form at least one ranging pixel,
a partition wall is formed between the filter of the at least one ranging pixel and the filter adjacent to the filter of the at least one ranging pixel, and
the partition wall contains a material that is almost the same as a material of the filter of the at least one imaging pixel replaced with the ranging pixel.

2. The solid-state imaging device according to claim 1, wherein the partition wall is formed in such a manner as to surround the at least one ranging pixel.

3. The solid-state imaging device according to claim 1, wherein the partition wall is formed between the filter of the imaging pixel and the filter adjacent to the filter of the imaging pixel, in such a manner as to surround the imaging pixel.

4. The solid-state imaging device according to claim 3, wherein
a width of the partition wall that is formed between the ranging pixel and the imaging pixel in such a manner as to surround the at least one ranging pixel differs from
a width of the partition wall that is formed between two of the imaging pixels in such a manner as to surround the imaging pixel.

5. The solid-state imaging device according to claim 3, wherein
a width of the partition wall that is formed between the ranging pixel and the imaging pixel in such a manner as to surround the at least one ranging pixel is almost the same as
a width of the partition wall that is formed between two of the imaging pixels in such a manner as to surround the imaging pixel.

6. The solid-state imaging device according to claim 1, wherein the partition wall includes a plurality of layers.

7. The solid-state imaging device according to claim 1, wherein the partition wall includes a first organic film and a second organic film in order from a light incident side.

8. The solid-state imaging device according to claim 7, wherein the first organic film is formed with a light-transmitting resin film.

9. The solid-state imaging device according to claim 8, wherein the light-transmitting resin film is a resin film that transmits red light, blue light, green light, white light, cyan light, magenta light, or yellow light.

10. The solid-state imaging device according to claim 7, wherein the second organic film is formed with a light-absorbing resin film.

11. The solid-state imaging device according to claim 10, wherein the light-absorbing resin film is a light-absorbing resin film containing a carbon black pigment or a titanium black pigment.

12. The solid-state imaging device according to claim 1, further comprising a light blocking film formed on a side opposite from a light incident side of the partition wall.

13. The solid-state imaging device according to claim 12, wherein the light blocking film is a metal film or an insulating film.

14. The solid-state imaging device according to claim 12, wherein the light blocking film includes a first light blocking film and a second light blocking film in order from the light incident side.

15. The solid-state imaging device according to claim 14, wherein the second light blocking film is formed to block light to be received by the ranging pixel.

16. The solid-state imaging device according to claim 1, wherein
the plurality of imaging pixels includes a pixel having a filter that transmits blue light, a pixel having a filter that transmits green light, and a pixel having a filter that transmits red light, and
the plurality of imaging pixels is orderly arranged in accordance with a Bayer array.

17. The solid-state imaging device according to claim 16, wherein
the pixel having the filter that transmits blue light is replaced with the ranging pixel having the filter that transmits the certain light, to form the ranging pixel,
a partition wall is formed between the filter of the ranging pixel and four of the filters that transmit green light and are adjacent to the filter of the ranging pixel, in such a manner as to surround the ranging pixel, and
the partition wall contains a material that is almost the same as a material of the filter that transmits blue light.

18. The solid-state imaging device according to claim 16, wherein
the pixel having the filter that transmits red light is replaced with the ranging pixel having the filter that transmits the certain light, to form the ranging pixel,
a partition wall is formed between the filter of the ranging pixel and four of the filters that transmit green light and are adjacent to the filter of the ranging pixel, in such a manner as to surround the ranging pixel, and
the partition wall contains a material that is almost the same as a material of the filter that transmits red light.

19. The solid-state imaging device according to claim 16, wherein
the pixel having the filter that transmits green light is replaced with the ranging pixel having the filter that transmits the certain light, to form the ranging pixel,
a partition wall is formed between the filter of the ranging pixel and two of the filters that transmit blue light and are adjacent to the filter of the ranging pixel, and between the filter of the ranging pixel and two of the filters that transmit red light and are adjacent to the filter of the ranging pixel, in such a manner as to surround the ranging pixel, and
the partition wall contains a material that is almost the same as a material of the filter that transmits green light.

20. The solid-state imaging device according to claim 1, wherein the filter of the ranging pixel contains a material that transmits red light, blue light, green light, white light, cyan light, magenta light, or yellow light.

21. A solid-state imaging device comprising
a plurality of imaging pixels,
wherein
the imaging pixels each include a photoelectric conversion unit formed in a semiconductor substrate, and a filter formed on a light incidence face side of the photoelectric conversion unit,
a ranging pixel is formed in at least one imaging pixel of the plurality of imaging pixels,
a partition wall is formed in at least part of a region between a filter of the ranging pixel and the filter of an imaging pixel adjacent to the ranging pixel, and
the partition wall contains a material forming the filter of one imaging pixel of the plurality of imaging pixels.

22. The solid-state imaging device according to claim 21, wherein
the plurality of imaging pixels includes a first pixel, a second pixel, a third pixel, and a fourth pixel that are adjacent to one another in a first row, and a fifth pixel, a sixth pixel, a seventh pixel, and an eighth pixel that are adjacent to one another in a second row adjacent to the first row,
the first pixel is adjacent to the fifth pixel,
the filters of the first pixel and the third pixel include a filter that transmits light in a first wavelength band,
the filters of the second pixel, the fourth pixel, the fifth pixel, and the seventh pixel include a filter that transmits light in a second wavelength band,
the filter of the eighth pixel includes a filter that transmits light in a third wavelength band,
the ranging pixel is formed in the sixth pixel,
a partition wall is formed at least in part of a region between the filter of the sixth pixel and the filter of a pixel adjacent to the sixth pixel, and
the partition wall contains a material that forms the filter that transmits light in the third wavelength band.

23. The solid-state imaging device according to claim 22, wherein the light in the first wavelength band is red light, the light in the second wavelength band is green light, and the light in the third wavelength band is blue light.

24. The solid-state imaging device according to claim 21, wherein the filter of the ranging pixel includes a different material from the partition wall or the filter of the imaging pixel adjacent to the ranging pixel.

25. The solid-state imaging device according to claim 21, wherein the partition wall is formed between the ranging pixel and the filter of the adjacent pixel, in such a manner as to surround at least part of the filter of the ranging pixel.

26. The solid-state imaging device according to claim 21, further comprising an on-chip lens on the light incidence face side of the filter.

27. The solid-state imaging device according to claim 26, wherein the filter of the ranging pixel contains one of materials forming a color filter, a transparent film, and the on-chip lens.

28. A solid-state imaging device comprising
a plurality of imaging pixels that is orderly arranged in accordance with a certain pattern,
wherein
the imaging pixels include: at least a semiconductor substrate in which a photoelectric conversion unit is formed; and a filter that transmits certain light and is formed on a light incidence face side of the semiconductor substrate,
at least one of the plurality of the imaging pixels is replaced with a ranging pixel having the filter that transmits the certain light, to form at least one ranging pixel,
a partition wall is formed between the filter of the at least one ranging pixel and the filter adjacent to the filter of the at least one ranging pixel, and
the partition wall contains a light-absorbing material.

29. An electronic apparatus comprising the solid-state imaging device according to claim 1.
